(19) United States
(12) Patent Application Publication
(10) Pub. No.: US 2013/0061929 A1
(43) Pub. Date: Mar. 14, 2013

(54) PHOTOELECTRIC CONVERSION ELEMENT, METHOD FOR PRODUCING PHOTOELECTRIC CONVERSION ELEMENT, AND SOLAR CELL

(71) Applicant: Akihiko ITAMI, Tokyo (JP)

(72) Inventor: Akihiko ITAMI, Tokyo (JP)

(73) Assignee: KONICA MINOLTA BUSINESS TECHNOLOGIES, INC., Tokyo (JP)

(21) Appl. No.: 13/604,029

(22) Filed: Sep. 5, 2012

(30) Foreign Application Priority Data
Sep. 12, 2011 (JP) 2011-198041

(51) Int. Cl. H01L 51/46

(52) U.S. Cl. 136/263

(57) ABSTRACT

A photoelectric conversion element, includes a substrate, a first electrode, a photoelectric conversion layer including semiconductors and sensitizing dyes, a positive bole transport layer including a solid positive hole transport substance, and a second electrode, wherein the solid positive hole transport substance contains a conductive polymer with a structure represented by the following Formula (1), and wherein the sensitizing dyes includes a compound with a structure represented by the following Formula (2) and at least one of compounds with respective structures represented by the following Formulas (4) to (9).

This application is based on Japanese Patent Application No. 2011 -198041 filed on Sep. 12,2011, in Japanese Patent Office, the entire content of which is hereby incorporated by reference

### BACKGROUND OF THE INVENTION

1. Technical Field

The present invention relates to a photoelectric conversion element having a function to covert light energy into electric energy, in particular, to a photoelectric conversion element which makes a hole transport material contain conductive polymers and employs organic dyes as sensitizing dyes.

2. Background Art

Photoelectric conversion elements represented by solar cells are elements to convert light energy into electrical energy in order to feed electrical power to devices, and investigations of development of photoelectric conversion elements using inorganic materials represented by silicon have been conventionally conducted. Such inorganic materials include single-crystal silicon, amorphous silicon, and indium copper selenide. In photoelectric conversion elements using an inorganic material, there have been produced productivity problems such that a purification process to form a high-purity inorganic material and a production process to produce a multilayer pn junction structure are required. Further, since rare metal such as indium is used, the problem of the stable supply system of raw materials has been produced.

On the other hand, photoelectric conversion elements using an organic material in which synthesis makes stable supply possible have also been investigated. For example, an organic photoelectric conversion element in which an electron-conductive (n-type) perylenetetracarboxylic acid and a positive hole-conductive (p-type) copper phthalocyanine are joined has been disclosed (for example, refer to Non-Patent Document 1). It was found out that in such an organic photoelectric conversion element, exciton diffusion length and a space-charge layer needed to be improved, and as a countermeasure therefor, a method has been proposed in which the area of a pn junction region formed using an n-type organic material and a p-type organic material is increased for efficient, photoelectric conversion. Specifically, a technique has been proposed in which an n-type electron-conductive material and a p-type positive hole-conductive polymer are combined in a film and thereby the pn-junction region is allowed to increase to carry out photoelectric conversion in the entire film (for example, refer to Non-Patent Document 2). Then, a technique has been proposed in which a conjugated polymer being a positive hole-conductive polymer and fullerene being an electron-conductive material are combined in a film.

However, since the above organic photoelectric conversion elements have exhibited smaller photoelectric conversion efficiency than those using inorganic materials, investigations to enhance photoelectric conversion efficiency have been conducted. As a technique to overcome this problem, attention has been paid to dye-sensitized type photoelectric conversion elements. Specifically, using porous titanium oxide, the semiconductor surface area is allowed to be larger to increase the adsorption amount of an organic sensitizing dye, and thereby photoelectric conversion efficiency is enhanced (for example, refer to Non-Patent Document 3). In this technique, an organic sensitizing dye having been adsorbed on the porous titanium oxide surface is photoexcited and then electrons are injected into titanium oxide by the dye to form dye cations. Then, due to the presence of these dye cations, in the element, via a positive hole transport layer having an. electrolytic solution in which an iodine-containing electrolyte is dissolved in an organic solvent, the cycle of transfer of electrons from the opposite electrode is repeated to realize enhancement of photoelectric conversion efficiency. Further, in this technique, titanium oxide used as a semiconductor was not highly purified and the visible tight region with the possibility of photoelectric conversion was expanded to enhance the capability of a dye-sensitized type photoelectric conversion element. On the other hand, since an electrolytic solution was used for the positive-hole transport layer, attention to prevent chemical species from being dispersed and lost due to liquid leakage was required.

For this problem, a technique relevant to a whole solid dye-sensitized type photoelectric conversion element has been proposed in which as a positive hole transport material, a solid material such as an amorphous organic positive hole transport material or copper iodide is used (for example, refer to Non-Patent Documents 4 and 5). There exists a conductive polymer represented by PEDOT (polyethylene dioxythiophene) as one of those expected to realize enhanced photoelectric conversion efficiency because of the structure thereof and then investigations thereon have been conducted (for example, refer to Patent Documents 1 and 2). For example, in Patent Document 1, disclosed is a technique by which polythiophene or the like as one of conductive polymers is used as a hole transport material, and a hole transport layer is formed on a layer containing semiconductor particles each to which a dye is adsorbed. Further in Patent Document 2, disclosed is a technique by which a coating solution containing polyethylene dioxythiophene as one of polythiophenes is coated on the first electrode to prepare a solar cell unit.

Incidentally, in a photoelectric conversion element, it is necessary to arrange a hole transport material also in semiconductor pores constituting a photoelectric conversion layer so that electron transfer can he conducted efficiently between the hole transport material and the sensitizing dye. Then, a technique has been studied such that a coating liquid containing a thiophene compound being a raw material of a poly thiophene is coated on a photoelectric conversion layer, and the thiophene compound is polymerized, thereby forming a positive hole transport layer of the poly thiophene (for example, refer to Non-patent Document 6). Non-patent Document 6 discloses that a liquid containing a thiophene compound is coated on a photoelectric conversion layer, and then followed by light irradiation to cause a polymerization reaction, whereby a positive hole transport substances of the poly thiophene are arranged in semiconductor pores.

Further, a technique is studied to form a positive hole transport layer by forming poly-thiophene through thermal polymerization (for example, refer to Non-patent Documents 7 and 8), Accordingly, it becomes possible to advance a polymerization reaction in the semiconductor pores and to form a positive hole transport layer with a durability. In this way, a technique to form a positive hole transport layer of poly-thiophene by thermal polymerization has been established. However, even if a positive hole transport layer is produced by this method, photoelectric conversion efficiency with a high level cannot be acquired.

Patent Document 1: Unexamined Japanese Patent Application Publication No. 2000-106223

Patent Document 2: Unexamined Japanese Patent Application Publication No. 2011 -009419

Non-Patent Document 1: C. W. Tang: Applied Physics Letters. 48, 183 (1986)

Non-Patent Document 2: G. YU, J. Gao, J. C. Humelen, F, Wudland, and A. J. Heeger: Science, 270, 1789 (1996)

Non-Patent Document 3: B. O'Regan and M. Gratzel, Nature, 353, 737 (1991)

Non-Patent Document 4: J. Xia, N. Masaki, M, Lira-Cantu, Y, Kim, K. Jiang, and S. Yanagida: Journal of the American Chemical Society, 130, 1258 (2008)

Non-Patent Document 5: J. K. Koh, J. Kim, B. Kim, J. H. KIM, E. Kim; Advances Materials, XX, 1-6(2011)

Non-Patent Document 6: X. Riu, W. Zhang, S. Uchida, L. Chai, B. Liu, S. Ramakrishna: Advances Materials, 22, E1-E6 (2010)

SUMMARY OF THE INVENTION

An object of the present invention is to provide a photoelectric conversion element which can exhibit high photoelectric conversion efficiency stably for a photoelectric conversion element which employs conductive polymers, such as a polythiophene compound, for a positive hole transportation substance.

The present inventor found out that the above-mentioned problems can be solved by any one of the below-mentioned constitutions. That is, according to Item 1 of the present invention, a photoelectric conversion element includes at least a substrate, a first electrode, a photoelectric conversion layer containing semiconductors and sensitizing dyes, a positive, hole transport layer containing a solid positive hole transport substance, and a second electrode, wherein the solid positive hole transport substance contained in tine positive hole transport layer is a conductive polymer with a structure represented by the following Formula (1), and the sensitizing dyes contained in the photoelectric conversion layer includes a compound with a structure represented by the following Formula (2) and at least one of compounds with respective structures represented by the following formulas (4) to (9) respectively.

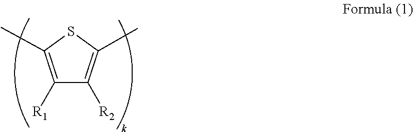

In Formula (1), each of R₁ and R₂ represents a hydrogen atom, or a substituted or unsubstituted alkyl group, alkoxy group, alkenyl group, or aryl group, R₁ and R₂ may be identical to each other, or may be different from each other, R₁ and R₂ may link to each other so as to form a ring structure, and k represents a natural number.

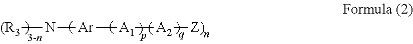

In Formula (2), n represents an integer of 1 or more and 3 or less, Ar represents an aromatic group, and R₃ represents a hydrogen atom, a halogen atom, a substituted or unsubstituted alkyl group. alkoxy group, alkenyl group, alkynyl group, aryl group, amino group, cyano group, or heterocycle group. When n is 1, two R₃s be different from each other, and R₃ may link to other substituent group so as to form a ring structure. Each of A₁ and A₂ is a single bond, divalent saturated or unsaturated hydrocarbon group, or a substituted or unsubstituted alkylene group, allylene group or heterocycle group, and each of p and q is an integer of 0 or more and 6 or less, 2 represents an organic group containing at least one hydroxy group or acidic group, and when n is 2 or more, a plurality of A₁, A₂, and Z may be different from each other.

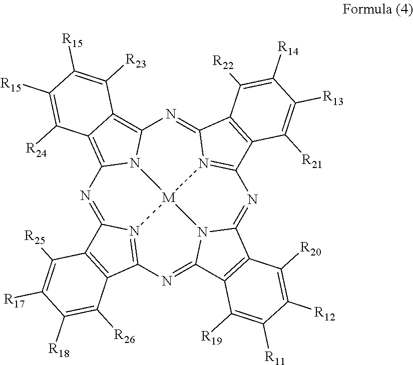

In Formula (4), each of R₁₁ to R₂₆ represents independently a hydrogen atom, a halogen atom, or a substituted or unsubstituted alkyl group, alkoxy group, aryl group, or phenoxy group, and an acidic group is included in at least one position on R₁₁ to R₂₆.Further, M represents two hydrogen atoms or a divalent, trivalent, or tetravalent metal atom that may include a substituent group.

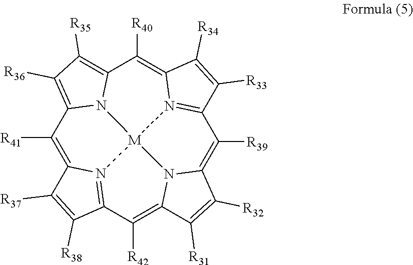

In Formula (5), each of R₃₁ to R₄₂ represents independently a hydrogen atom, a halogen atom, or a substituted or unsubstituted alkyl group, alkenyl group, alkynyl group, aryl group, amino group, heterocycle group, or group forming a ring-shaped structure or ring-fused structure directly or via other bonded atom, and an acidic group is included in at least one position on R₃₅ to R₄₂. Further, M represents two hydrogen atoms or a divalent, trivalent, or tetravalent metal atom that may include a substituent group.

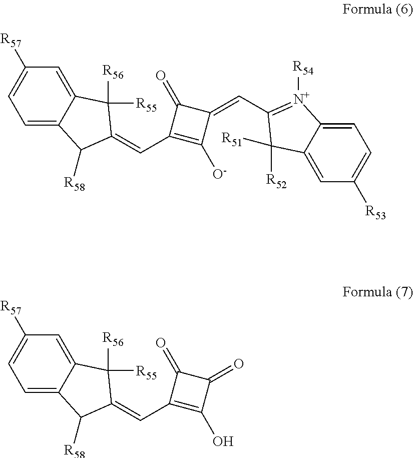

Each of R₅₃ and R₅₄ in Formula (6), or each of R₅₇ and R₅₈ in both Formulas (6) and (7) represents independently a hydrogen atom, a halogen atom, or a substituted or unsubstituted alkyl group, alkenyl group, alkynyl group, aryl group, or heterocycle group, and an acidic group is included in at least one position on the above section. Further, each of R₅₁ and R₅₂ in Formula (6), or each of R₅₅ and R₅₆ in both Formulas (6) and (7) represents an alky; group with the same number of carbons or the different number of carbons, an aryl group, or an alkyl group-substituted aryl group.

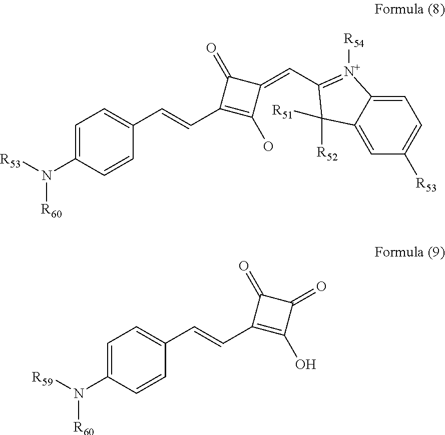

Each of R₅₁, R₅₂, R₅₃, and R₅₄ in Formula (8) represents independently a hydrogen atom, a halogen atom, or a substituted or unsubstituted alkyl group, alkenyl group, alkynyl group, aryl group, or heterocycle group, and an acidic group is included on R₅₃. Each of R₅₉ and R₆₀ in both Formulas (8) and (9) represents independently a substituted or unsubstituted alkyl group, alkenyl group, alkynyl group, aryl group, or heterocycle group, and R₅₉ and R₆₀ may link to each other so as to form a ring-shape structure.

According to Item 2 of the present invention, in photoelectric conversion element according to Item 1, the sensitizing dye with the structure represented by the following Formula (2) is a compound

represented by the following Formula (3).

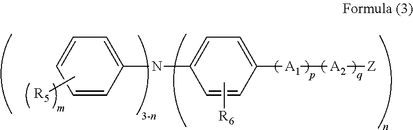

In Formula (3), m represents an integer of 1 or more and 5 or less, and n represents an integer of 1 or 2. R₅ and R₆ each represents a hydrogen atom, a halogen atom, a substituted or unsubstituted alkyl group, alkoxy group, alkenyl group, alkynyl group, aryl group, amino group, cyano group, or heterocycle group, and may link to each other so as to form a ring structure. Each of A₁ and A₂ represents a heterocycle group containing a sulfur atom, and each of p and q is an integer of 0 or more and 6 or less. Z represents an organic group attaining at least one hydroxy group or acidic group, and when m is 2, A₁, A₂, and Z maybe different from each other.

According to Item 3 of the present invention, in photoelectric conversion element according to Item 2, in the sensitizing dye with the structure represented by the above-mentioned Formula (3), at least one of R₅, A₁, and A₂ includes a straight chain, alkyl structure with six or more carbon atoms.

According to item 4 of the present invention, in photoelectric conversion element according to Item 2 or 3, in the sensitizing dye with, the structure represented by the above-mentioned Formula (3), n is 2.

According to Item 5 of the present invention, in photoelectric conversion element according to any one of Items 1 to 4, the conductive polymer with the structure represented by the above-mentioned Formula (1) is a copolymer composed of at least two or more kinds of polymerizable monomers.

According to Item 6 of the present invention, in photoelectric conversion element according to any one of Items 1 to 5, the photoelectric conversion layer containing the sensitizing dye has a thickness of 10 μm or less.

According to Item 7 of the present invention, in photoelectric conversion element according to any one of Items 1 to 6, the solid positive hole transport substance contained in the positive hole transport layer is produced by thermal polymerization of the conductive polymer with the structure represented by the above-mentioned Formula (1).

According to Item 8 of the present invention in photoelectric conversion element according to any one of Items 1 to 7, a treatment temperature at the time of the thermal polymerization is 50° C. or more and 82° C. or less.

According to Item 9 of the present invention, a method for producing a photoelectric conversion element that includes at least a substrate, a first electrode, a photoelectric conversion layer containing semiconductors and sensitizing dyes, a positive hole transport layer containing a solid positive hole transport substance, and a second electrode, wherein the solid positive hole transport substance contained in the positive hole transport layer is a conductive polymer with a structure represented by the following Formula (1), and the sensitizing dyes contained in the photoelectric conversion layer includes a compound with a structure represented by the following Formula (2) and at least one of compounds with respective structures represented by the following Formulas (4) to (9) respectively.

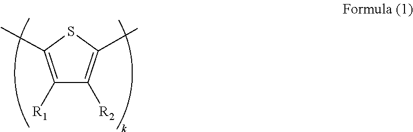

In Formula (1), each of R₁ and R₂ represents a hydrogen atom, or a substituted or unsubstituted alkyl group, alkoxy group, alkenyl group, or aryl group, R₁ and R₂ may be identical to each other, or may be different from each other, R₁ and R₂ may link to each other so as to form a ring structure, and k represents a natural number.

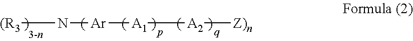

In Formula (2), n represents an integer of 1 or more and 3 or less, Ar represents an aromatic group, and R₃ represents a hydrogen atom, a halogen atom, a substituted or unsubstituted alkyl group, alkoxy group, alkenyl group, alkynyl group, aryl group, amino group, cyano group, or heterocycle group. When n is 1, two R₃s be different from each other, and R₃ may link to other substituent group so as to form a ring structure. Each of A₁ and A₂ is a single bond, divalent saturated or unsaturated hydrocarbon group, or a substituted or unsubstituted alkylene group, alkylene group or heterocycle group, and each of p and q is an integer of 0 or more and 6 or less. Z represents an organic group containing at least one hydroxy group or acidic group, and when n is 2 or more, a plurality of A₁, A₂, and Z may be different from each other.

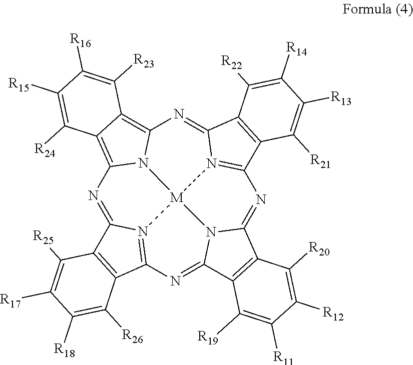

In Formula (4), each of R₁₁ to R₂₆ represents independently a hydrogen atom, a halogen atom, or a substituted or unsubstituted alkyl group, alkoxy group, aryl group, or phenoxy group, and an acidic group is included in at least one position on R₁₁ to R₂₆. Further, M represents two hydrogen atoms or a divalent, bivalent, or tetravalent metal atom that may include a substituent group.

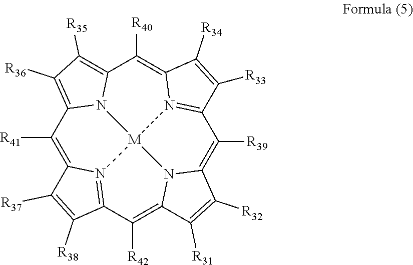

In Formula (5), each of R₃₁ to R₄₂ represents independently a hydrogen atom, a halogen atom, or a substituted or unsubstituted alkyl group, alkenyl group, alkynyl group, aryl group, amino group, heterocycle group, or group forming a ring-shaped structure or ring-fused structure directly or via other bonded atom, and an acidic group is included in at least one position on R₃₁ to R₄₂. Further, M represents two hydrogen atoms or a divalent, trivalent, or tetravalent metal atom that may include a substituent group.

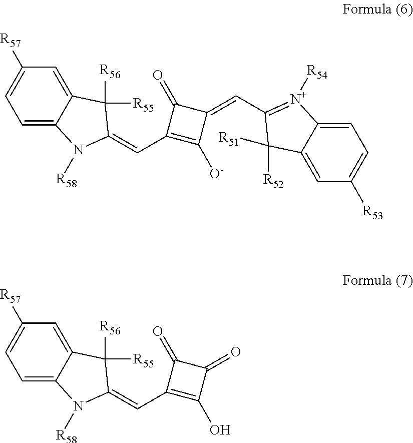

Each of R₅₃ and R₅₄ in Formula (6), or each of R₅₇ and R₅₈ in both Formulas (6) and (7) represents independently a hydrogen atom, a halogen atom, or a substituted or unsubstituted alkyl group, alkenyl group, alkynyl group, aryl group, or heterocycle group, and an acidic group is included in at least one position on the above section. Each of R₅₁ and R₅₂ in Formula (6), or each of R₅₅ and R₅₆ in both Formulas (6) and (7) represents an alkyl group with the same number of carbons or the different number of carbons, an aryl group, or an alkyl group-substituted aryl group.

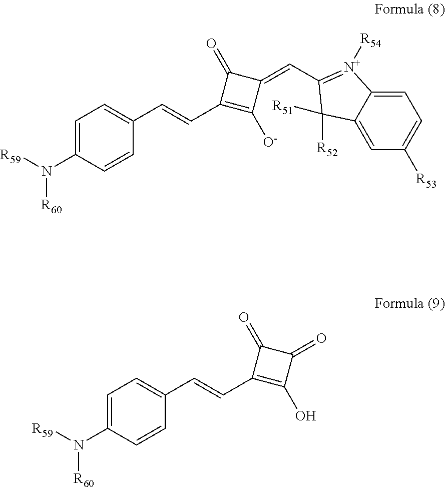

Each of R₅₁, R₅₂, R₅₃, and R₅₄ in Formula (8) represents independently a hydrogen atom, a halogen atom, or a substituted or unsubstituted alkyl group, alkenyl group, alkynyl group, aryl group, or heterocycle group, and an acidic group is included on R₅₃. Each of R₅₉ and R₅₀ in both Formulas (8) and (9) represents independently a substituted or unsubstituted alkyl group, alkenyl group, alkynyl group, aryl group, or heterocycle group, and R₅₉ and R₆₀ may link to each other so as to form a ring-shape structure.

According to Item 10 of the present invention, in photoelectric conversion element according to Item 9, the sensitizing dye with the structure represented by the following Formula (2) is a compound represented by the following Formula (3).

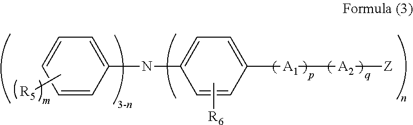

In Formula (3), m represents an integer of 1 or more and 5 or less, and n represents an integer of 1 or 2. R₅ and R₆ each represents a hydrogen atom, a halogen atom, a substituted or unsubstituted alkyl group, alkoxy group, alkenyl group, alkynyl group, aryl group, amino group, cyano group, or heterocycle group, and may link to each other so as to form a ring structure. Each of A₁ and A₂ represents a heterocycle group containing a sulfur atom, and each of p and q is an integer of 0 or more and 6 or less. Z represents an organic group containing at least one hydroxy group or acidic group, and when m is 2, A₁, A₂, and Z may be different from each other.

According to Item 11 of the present invention, in photoelectric conversion element according to Item 10, in the sensitizing dye with the structure represented by the above-mentioned Formula (3), at least one of R₅, A₁, and A₂ includes a straight chain alkyl structure with six or more carbon atoms.

According to Item 12 of the present invention, in photoelectric conversion element according to Item 10 or 11, in the sensitizing dye with the structure represented by the above-mentioned Formula (3), n is 2.

According to Item 13 of the present invention, in photoelectric conversion element according to any one of Items 10 to 11, the conductive polymer with the structure represented by the above-mentioned Formula (1) is a copolymer composed of at least two or more kinds of polymerizable monomers.

According to Item 14 of the present invention, in photoelectric conversion element according to any one of Items 9 to 13, the photoelectric conversion layer containing the sensitizing dye has a thickness of 10 μm or less.

According to Item 15 of the present invention, in photoelectric conversion element according to any one of Items 9 to 14, the solid positive hole transport substance contained in the positive hole transport layer is produced by thermal polymerization of the conductive polymer with the structure represented by the above-mentioned Formula (1).

According to Item 16 of the present invention, in photoelectric conversion element according to Item 15, a treatment temperature at the time of the thermal polymerization is 50° C. or more and 82° C. or less.

According to Item 17 of the present invention, a solar battery includes the photoelectric conversion element according to any one of Items 1 to 8 or the photoelectric conversion element produced by the method according to any one of Items 9 to 13.

In the present invention, conductive polymers including a poly-thiophene structure in a main chain structure is used as a positive hole transport, material and a specific amine compound and a specific organic dye compound are used in combination as sensitizing dyes, whereby it becomes possible to provide a photoelectric conversion element which exhibits a high level photoelectric conversion efficiency stably.

### BRIEF DESCRIPTION OF THE DRAWINGS

FIG. 1 is a schematic cross-sectional view showing one example of a photoelectric conversion element according to the present invention.

FIGS. 2a and 2b each is a schematic diagram sowing a relationship between the numeral values of “shape coefficient” and the shape of “voltage-current characteristic graph”.

### DETAILED DESCRIPTION OF THE PREFERRED EMBODIMENT

The present invention relates to a photoelectric conversion element to covert light energy into electric energy, in particular, to a photoelectric conversion element which employs conductive polymers including a sulfur heterocyclic structure as a main chain structure as a positive hole transport material, and uses a specific amine compound and a specific organic dye compound in combination in sensitizing dyes.

Hereafter, the present invention will be described in detail.

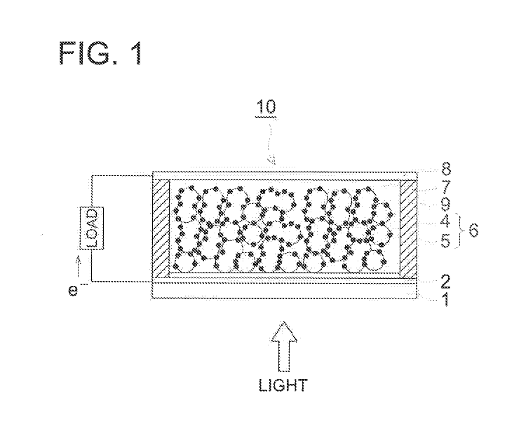

Initially, the structure of a photoelectric conversion element according to the present invention will be described with reference to FIG. 1. FIG. 1 is a schematic cross-sectional view showing one example of the structure of the photoelectric conversion element according to the present invention.

The photoelectric conversion element 10 shown in FIG. 1 includes a substrate 1, a first electrode 2, a photoelectric conversion layer 6, a positive hole transport layer, a second electrode 8, aid a partition wall 9. As shown by the arrow in the figure, light is allowed to enter the photoelectric conversion layer 6 from the side where the substrate 1 and the first electrode 2 are arranged Further, the photoelectric conversion layer 6 contains a semiconductor 5 and a sensitizing dye 4, and in the present invention, the compound represented by Formula (2) and at least one of the compounds represented by Formulas (4) to (9) are used for the sensitizing dye. Furthermore, the positive hole transport layer 7 contains a conductive polymer which includes a sulfur heterocyclic structure represented by Formula (1) as a main chain structure.

The photoelectric conversion element 10 carries out photoelectric conversion based on the following procedures to function as a cell. Namely, (1) light is irradiated to the first electrode 2, and then a sensitizing dye contained in the photoelectric conversion layer 6 absorbs the light and emits electrons. At this moment, the sensitizing dye becomes an oxide. (2) Electrons having been emitted from the sensitizing dye move to a semiconductor in the photoelectric conversion layer 6 and farther move to the first electrode 2 from the semiconductor. (3) Elections having moved to the first electrode 2 travel to the second electrode 8 serving as the opposite electrode, and reduces a positive hole transport, material at the second electrode 8. (4) The above sensitizing dye oxide receives electrons from the reduced positive hole transport material and returns to the original state (the sensitizing dye). (5) (1) to (4) described above are repeated, whereby electrons are repetitively moved from the first electrode 2 to the second electrode 8, thereby allowing electricity to flow.

In this manner, in the photoelectric conversion element 10 shown in FIG. 1, light irradiation makes a sensitizing dye in an excited state so as to emit electrons. Successively, the emitted electrons flow through a semiconductor, arrive at the first electrode 2, and then flow out to the outside. On the other hand, the sensitizing dye having become an oxide ate having emitted electrons receives electrons fed from the second electrode 8 through the positive hole transport layer, and then returns to the original state. The above mechanism allows electrons to move, whereby the photoelectric conversion element 10 functions as a cell.

The present invention solves the above-mentioned problems by the photoelectric conversion element which includes a positive hole transport layer containing a. conductive polymer with a structure represented by Formula (1) and a photoelectric conversion layer containing a compound with a structure represented by Formula (2) and at least one of compounds with respective structure represented by Formula (4) to (9).

In the conventional technology, it has been difficult to fabricate photoelectric conversion elements capable of achieving high photoelectric conversion efficiency even with positive hole transport layers of a polythiophene compound produced via a thermal polymerization method. The reasons of the above difficulty are considered as follows. That is, conductive polymers, such as a polythiophene compound, used as a hole transport material, absorb the light in a visible light region (from 400 nm to 700 nm). This visible light absorption causes light loss, which further leads to cause charge loss. Further, the above consideration is continued as follows. That is, due to the above charge loss, electrons tend to move reversely between, sensitizing dyes and a positive hole transport layer, and the reverse movement makes an open voltage to drop greatly, thereby lowering photoelectric conversion efficiency.

Under the above circumstances, the present inventor conceived the following theories. That is, in a photoelectric conversion element which employs a conductive polymer including a sulfur heterocyclic structure such as a polythiophene compound in a main chain structure, if the light adsorption performance of sensitizing dyes is made stronger than the conductive polymer, charge loss may not occur in a positive hole transport layer, and electrons may not move reversely between a photoelectric conversion, layer and a positive hole transport layer. Then, present inventor found out that by use of a compound with the structure represented by Formula (2) and at least one of impounds with respective structure represented by Formula (4) to (9) in combination, high photoelectric inversion efficiency may be acquired in the photoelectric conversion element which employs the conductive polymer. The reasons of the above improvement are presumed as Mows. That is, by combination of two or more kinds of compounds, the excitation level of dye compounds is made broad due to an intermolecular interaction between dye compounds, which results in that hole injection to a solid hole transport material is advanced.

Hereafter, description will be given in detail for a positive hole transport layer and photoelectric conversion layer which constitute a photoelectric conversion element according to the present invention.

First, a positive hole transport layer constituting a photoelectric conversion element according to the present invention will be described. The positive hole transport layer 7 provided in the photoelectric conversion element 10 shown in FIG. 1 allows positive holes to move toward the second electrode 8 from sensitizing dyes becoming in an excited state after having discharged electros via light absorption. At this time, by making the positive holes to move, the sensitizing dyes are reduced. In other words, the positive hole transport layer 7 receives electrons from the second electrode 8 and then provides the received electrons to the sensitizing dyes in the excited state, whereby the positive hole transport layer 7 conducts an action to return the sensitizing dyes to the state before light irradiation.

The photoelectric conversion element according to the present invention employs “conductive polymer” being a solid material for the hole transport material and does not cause liquid leakage which is a problem in photoelectric conversion elements that employ an electrolyte. Further, since the conductive polymer has a structure in which charge tends to easily move, the conductive polymer can supply electrons efficiently and stably from the second electrode to the sensitizing dye in an exciting state. In the present invention, the conductive polymer which includes a sulfur heterocyclic structure represented by the following formula (1) as a main chain structure is employed for a hole transport material.

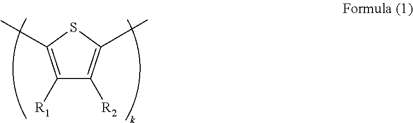

In Formula (1), each of R₁ and R₂ represents a hydrogen atom, or a substituted or unsubstituted alkyl group, alkoxy group, alkenyl group, or aryl group, R₁ and R₂ may he identical to each other, or may be different from each other, and R₁ and R₂ may link to each other so as to form a ring structure.

The conductive polymer which includes a sulfur heterocyclic structure expressed with, the general Formula (1) as a main chain structure can be formed, for example, by use of compound shown below. In the following formula, Y represents a halogen atom. First, there is a compound with a single sulfur heterocyclic structure.

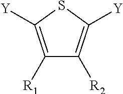

Further, it may be also possible to produce the conductive polymer which includes the sulfur heterocyclic structure represented by Formula (1) as a main chain structure by use of compounds each of which is shown below and includes two or more sulfur heterocyclic structures. In the following formulas, each of R₇, R₈, R₉, R₁₀, and R represents a hydrogen atom, or a substituted or unsubstituted alkyl group, alkoxy group, alkenyl group, or aryl group as same as the above R₁ and R₂, and they may be identical to each other, or may be different from each other. In R₇ and R₈, and in R₉ and R₁₀, respective groups represented by R may link to each other so as to form a ring structure as with R₁ and R₂.

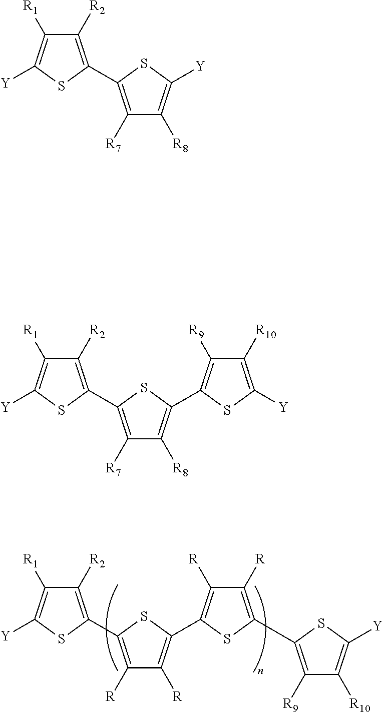

Specific examples of me compounds which can produce the conductive polymer including the hereafter the sulfur heterocyclic structure represented by Formula (1) as a main chain structure are shown below. However the compounds which can produce the conductive polymer including the hereafter the sulfur heterocyclic structure represented by Formula (1) are not limited to those shown below. In the formulas, Y represents a halogen atom and, specifically, is any one of a chlorine atom Cl, a bromine atom Br, and an iodine-atom I.

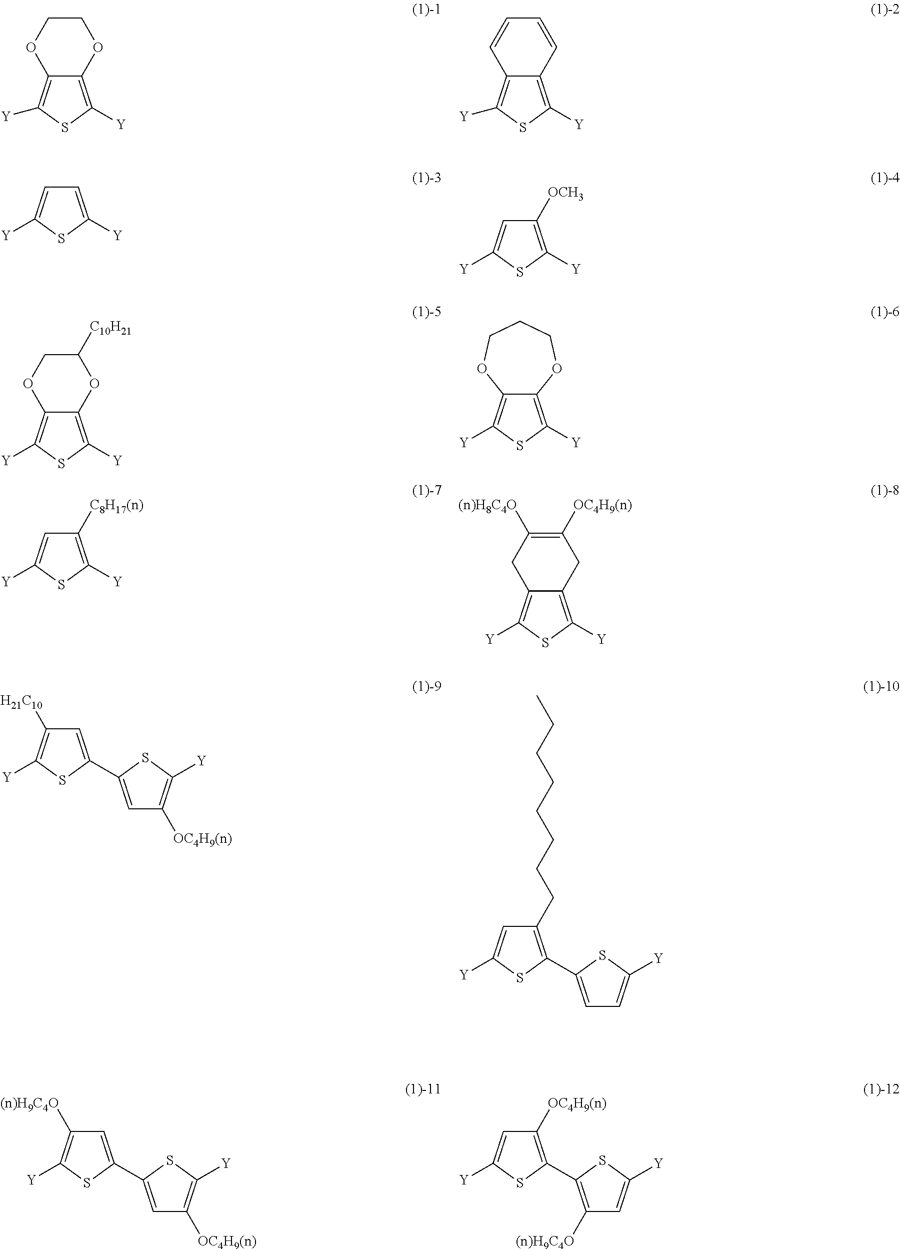

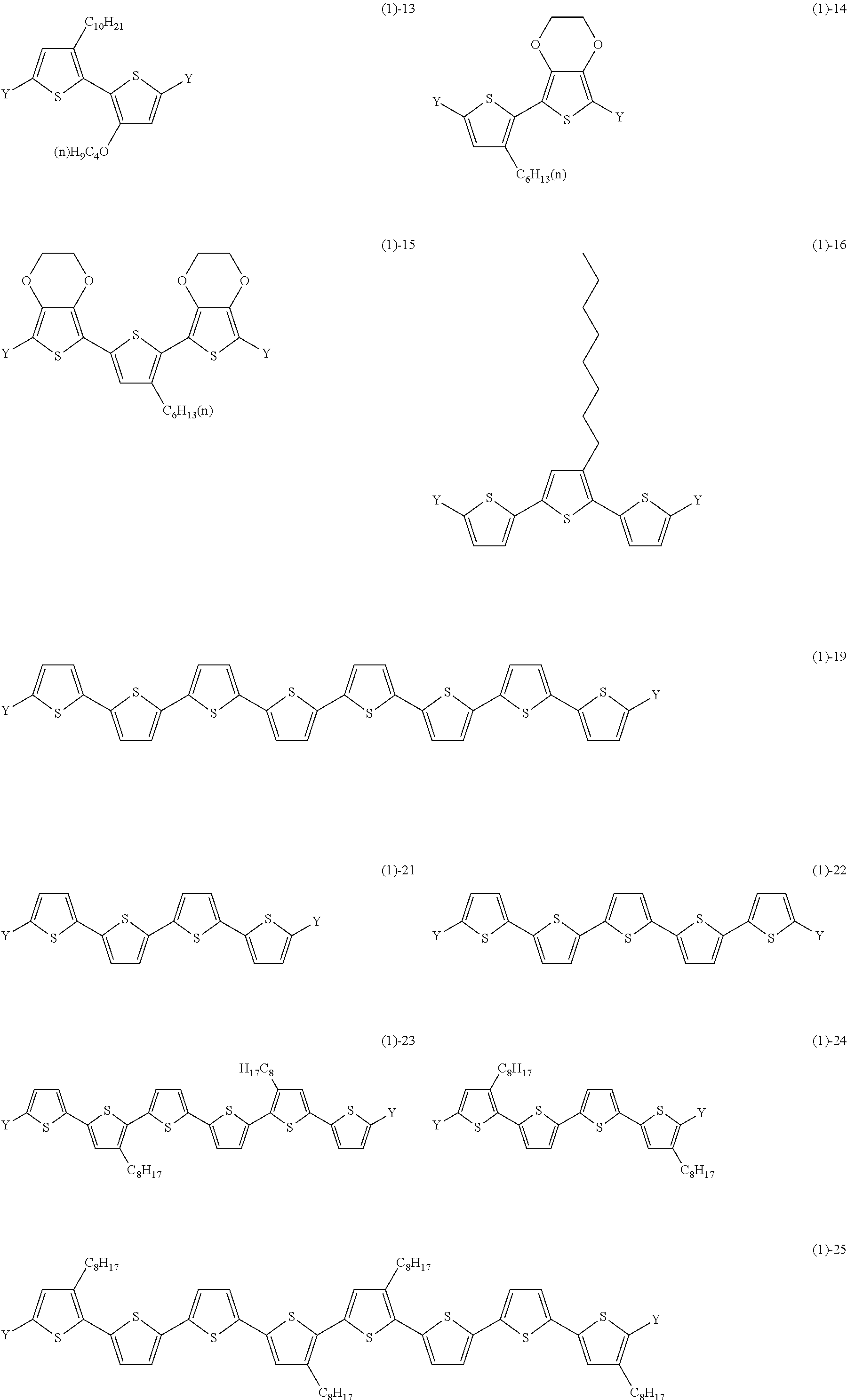

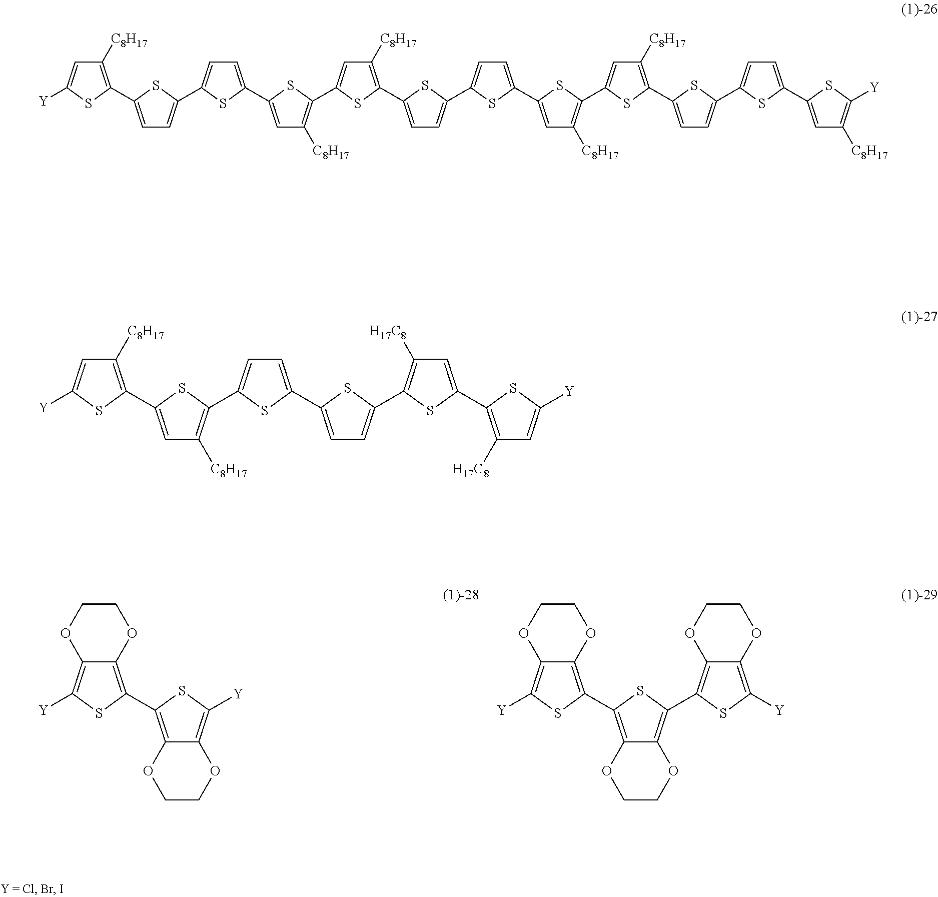

A polymer which includes a sulfur heterocyclic structure represented by Formula (1) in a main chain structures forms a conjugate type main chain structure in which a double bond and a single bond are arranged alternately, and has a structure in which a charge tends to move. Further, with the existence of a side chain structure, a polymer molecule takes easily a crystalline structure, which contributes to an improvement in photoelectric conversion efficiency. That is, a side chain structure exists as apart which exhibits an intermolecular interaction in a molecular structure, whereby a conductive polymer is encouraged to form a regular arrangement, which leads to form a stable positive hole transport layer not likely to cause segmental movement by heat. As a result, it may be considered that, even if being influenced by heat and the like, the segmental, movement of molecular chains is more strongly refrained by the intermolecular interaction, thereby forming an environment to refrain the charge recombination between semiconductors represented by titanium oxide and a positive hole transport layer and obtaining high photoelectric conversion efficiency.

### (Method for Polymerizing a Conductive Polymer)

The polymerization method is not restricted specifically. For example, known polymerization methods, such as a method described in Japanese Unexamined Patent Publication No. 2000-106223 official report may be employed. Specific examples of the polymerization methods include chemical polymerization methods which use polymerization catalysts; electrolytic polymerization methods which employ at least an action electrode and a counter electrode and cause a reaction by applying a voltage between the both electrodes; and photopolymerization methods which employ only light irradiation, or a combination of polymerization catalysts, heating, electrolysis, and the like. Among them, a polymerizing method using an electrolytic polymerization method is desirable, and a photopolymerization method which combines an. electrolytic polymerization method and light irradiation is more desirable. By use, in combination, of an electrolytic polymerization method and a photopolymerization method which causes polymerization by light irradiation, a polymer layer can be precisely formed on the surface of titanium oxides. In the case where a polymer is formed by an electrolytic polymerization method the synthesis of a polymer leads to formation of the above-mentioned solid positive hole transport layer as it is. That is, the electrolytic polymerization methods are performed in the following ways. Generally, a mixture which contains a monomer which constitutes a polymer, a support electrolyte, and a solvent, further additives if needed is used.

Specifically, a monomer represented by Formula (2) or a multimer of the monomer, and other monomers are dissolved in a suitable solvent, followed by addition of a support electrolyte, thereby producing an electrolytic polymerization solution.

Herein, as long as a solvent is capable of dissolving the support electrolyte and the monomer or its multimer, the solvent is not limited specifically. However, it maybe preferable to use an organic solvent with a relatively wide potential window. Specific examples of the organic solvents include polar solvents such as tetrahydrofuran (THF), butyleneoxide, chloroform, cyclohexanone, chlorobenzene, acetone, and various alcohols; and aprotic solvents such as dimethylformamide (DMF), acetonitrile, dimethoxyethane, dimethyl sulfoxide, hexamethylphosphoric triamide, propylene carbonate, dichloromethane, o-dichlorobenzene, and methylene chloride. Further, water and other organic solvents may be added to the above-mentioned solvents if needed, so that the above-mentioned solvents may be used as a mixed solvent The above-mentioned solvents may be used independently, or may be used in the form of a mixture of two or more kinds of solvents. In the case of a mixture of two or more kinds of solvents, a mixture sol vent of chlorobenzene and acetonitrile may be preferably used.

Support electrolytes capable of ionizing are used and not limited specifically. A support electrolyte which has a high solubility for a solvent and do not undergo easily oxidation and reduction, is used preferably. Specific examples of the support electrolytes include salts, such as lithium. perchlorate (LiClO₄), lithium tetrafluoroborate, tetrabutyl perchlorate ammonium, Li[(CF₃SO₂)₂N], (n-C₄H₉)₄NBF₄, (n-C₄H₉)₄ NPF₄, a p-toluenesulfonic acid salt and a dodecylbenzenesulfonic acid salt. Further, the polymer electrolyte disclosed in Japanese Unexamined Patent Publication. No. 2000-106223 official report (for example, PA-1 to PA-10 in the official report) may be used as the support electrolyte. Furthermore, the above-mentioned support electrolyte may be used independently, or may be used in the form of a mixture of two or more kinds.

Examples of the additives which can be added to the solid positive hole transport layer include various additives, i.e., acceptor doping substances, such as N(PhBr)₃SbCl₆, NOPF₆, SbCl₅, I₂, Br₂, HClO₄, (n-C4H9)₄ClO₄, trifluoroacetic acid, 4-dodecylbenzenesulfonic acid, 1-naphthalenesulfonic acid, FeCl₃, AuCl₃, NOSbF₆, AsF₅, NOBF₄, LiBF₄H1-3[PMo₁₂O₄₀], 7,7,8,8-tetracyanoquinodimethane (TCNQ); binder resins difficult to trap hole; and coatability improving agents. The above-mentioned additives may be used independently, or may be used in the form of a mixture of two or more kinds.

Moreover, in the present invention, the conductive polymer which includes the sulfur heterocyclic structure represented by Formula (1) in a main chain structure may be formed by thermal polymerization. That is, at the time of formation of the polymer represented by Formula (1), a polymerization reaction is advanced by removing Y (halogen atom) in the compound structure used as a raw material. This polymerization reaction can be efficiently perforated by the thermal polymerization method. Since the polymerization reaction can be fully performed by the thermal polymerization without leaving unreacted compounds, the thermal polymerization method is desirable in the point to form a positive hole transport layer excellent in durability.

In the present invention, the conductive polymer which includes the sulfur heterocyclic structure represented by Formula (1) in a main chain structure may be formed by thermal polymerization, and a treatment temperature at the time of performance of thermal polymerization is desirable, for example, 50° C. or more and 80° C. or less.

The positive hole transport layer which contains the conductive polymer which includes the sulfur heterocyclic structure represented by Formula (1) in a main chain structure, as a solid positive hole transport substance can be produced by known methods. Specifically, according to a desirable method, a solution which contains the above-mentioned compound, polymerization catalyst and a polymerization rate adjusting agent, and the like is prepared, the prepared solution is coated on a photoelectric conversion layer or the layer is immersed in the solution, and then a positive hole transport layer is formed by a thermal polymerization reaction. The conditions of the thermal polymerization reaction may differ depending on respective kinds and ratios of the above-mentioned compounds used to form a polymer, polymerization catalysts, and polymerization rate adjusting agents, and the layer thickness to be formed However, as mentioned above, the treatment temperature is preferably 50° C. or more and 80° C. or less, the time to conduct the heating treatment is preferably from 1 minute to 24 hours.

In this way, by formation of the positive hole transport layer via the polymerization reaction with heating after the coating of the solution containing the above-mentioned compounds onto the photoelectric conversion layer, the positive hole transport layer can be formed so as to secure a sufficient contact area for the photoelectric conversion layer with the complicated sectional shape.

Next, the photoelectric conversion layer which constitutes the photoelectric conversion element according to the present invention will be explained. The photoelectric conversion element 10 shown in FIG. 1 includes the photoelectric conversion layer 6 to convert light energies, such as sunlight into electric energy. The photoelectric conversion layer 6 is disposed to neighbor on the first electrode 2. The photoelectric conversion layer 6 includes the semiconductors to which sensitizing dyes are made to adsorb. At the position to receive light having passed through the first electrode 2, electrons are transferred between the photoelectric conversion layer 6 and the first electrode 2.

The conversion of the light energy to the electric energy in the photoelectric conversion layer is performed by the following procedures. First, light having passed through the first electrode advances into the photoelectric conversion layer, and then the advanced light collides with the semiconductors. The light having collided with the semiconductors causes scattered reflection in the arbitrary directions and diffuses in the photoelectric conversion layer. Successively, the diffused light comes in contact with the sensitizing dyes, thereby generating electrons and positive holes (hole). Subsequently, the generated electrons move toward the first electrode. In such a mechanism, the photoelectric conversion layer is configured to convent light energy into electric energy.

The thickness of the photoelectric conversion layer is not limited specifically. However, the thickness is preferably about 0.1 μm to 50 μm, more preferably about 0.5 μm to 25 μm, and especially preferably about 1 μm to 10 μm. the thickness of the photoelectric conversion layer 6 almost conforms to the thickness of the semiconductor contained in the photoelectric conversion layer 6. From the viewpoint of realization of the miniaturization of the elements and the reduction of a manufacturing cost, it may be preferable to employ the semiconductor in the form of a layer.

The sensitizing aye used in the photoelectric conversion element according to the present invention will be explained. The sensitizing dyes constituting the photoelectric conversion element according to the present invention includes a compound with a structure represented by the following Formula (2) and at least one of compounds with respective structures represented by the following Formulas (4) to (9) respectively.

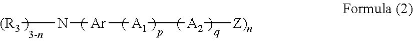

In Formula (2), n represents an integer of 1 or more and 3 or less, Ar represents an aromatic group, and R₃ represents a hydrogen atom, a halogen atom, a substituted or unsubstituted alkyl group, alkoxy group, alkenyl group, alkynyl group, aryl group, amino group, cyano group, or heterocycle group. When n is 1, two R₃s be different from each other, and R₃ may link to other substituent group so as to form a ring structure. Each of A₁ and A₂ is a single bond, divalent saturated or unsaturated hydrocarbon group, or a substituted or unsubstituted alkylene group, allylene group or heterocycle group, and each of p and q is an integer of 0 or more and 6 or less. Z represents an organic group containing at least one hydroxy group or acidic group, and when n is 2 or more, a plurality of A₁, A₂, and Z may be different from each other.

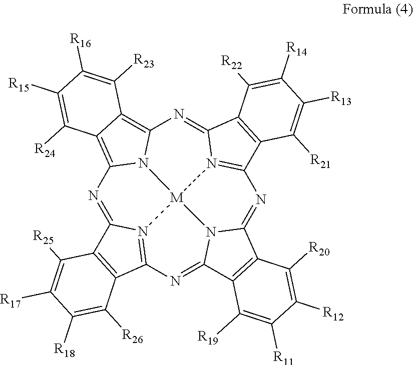

In Formula (4), each of R₁₁ to R₂₆represents independently a hydrogen atom, a halogen atom, or a substituted or unsubstituted alkyl group, alkoxy group, aryl group, or phenoxy group, and an acidic group is included in at least one position on R₁₁ to R₃₅. Further, M represents two hydrogen atoms or a divalent, trivalent, or tetravalent metal atom that may include a substituent group.

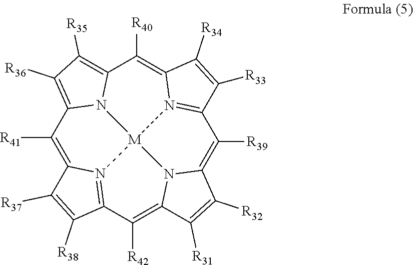

In Formula (5), each of R₃₁ to R₄₂ represents independently a hydrogen atom, a halogen atom, or a substituted or unsubstituted alkyl group, alkenyl group, alkynyl group, aryl group, amino group, heterocycle group, or group forming a ring-shaped structure or ring-fused structure directly or via. other bonded atom, and. an acidic group is included in at least one position on R₃₁ to R₄₂. Further, M represents two hydrogen atoms or a divalent, trivalent, or tetravalent metal atom that may include a substituent group.

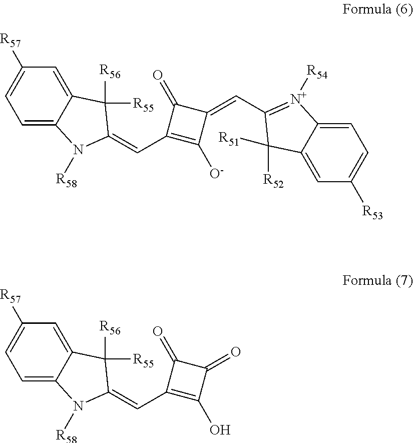

Each of R₅₃ and R₅₄ in Formula (6), or each of R₅₇ and R₅₈ in both Formulas (6) and (7) represents independently a hydrogen atom, a halogen atom, or a substituted or unsubstituted alkyl group, alkenyl group, alkynyl group, aryl group, or heterocycle group, and an acidic group is included in at least one position on the above section. Each of R₅₁ and R₅₂ in Formula (6), or each of R₅₅ and R₅₆ in both Formulas (6) and (7) represents an alkyl group with the same number of carbons or the different number of carbons, an aryl group, or an alkyl group-substituted aryl group.

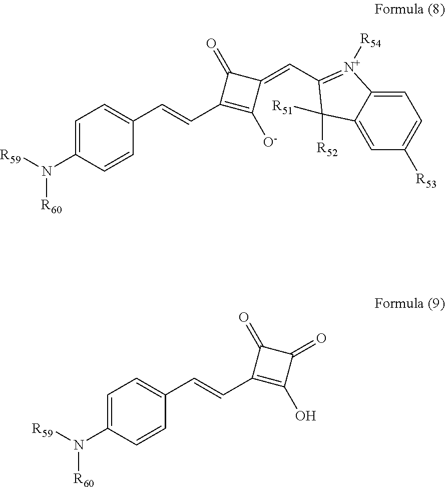

Each of R₅₁, R₅₂, R₅₃, and R₅₄ in Formula (8) represents independently a hydrogen atom, a halogen atom, or a substituted or unsubstituted alkyl group, alkenyl group, alkynyl group, aryl group, or heterocycle group, and an acidic group is included on R₅₃. Each of R₅₉ and R₆₀ in both Formulas (8) and (9) represents independently a substituted or unsubstituted alkyl group, alkenyl group, alkynyl group, aryl group, or heterocycle group, and R₅₉ and R₆₀ may link to each other so as to form a ring-shape structure.

In the present invention, a compound with the structure represented by Formula (2) and at least one of compounds with respective structures represented by Formulas (4) to (9) are used for sensitizing dyes, whereby in a photoelectric conversion element in which conductive polymers including a sulfur heterocyclic structure in a main chain structure is used as a positive hole transportation substance, the photoelectric conversion efficiency can be improved. The reasons for this improvement may be presumed as follows. That, is, the compound with the structure represented by Formula (2) conducts charge formation with an amount to cover sufficiently the charge loss caused by absorption of visual light via polythiophene. In addition, an intermolecular interaction due to combination use of at least one of compounds with respective structures represented by Formulas (4) to (9) may contribute to the improvement. That is, by combination use of two or more kinds of organic dye compounds different in structure, the excitation level of dye compounds is made broad due to occurrence of an intermolecular interaction between organic dye compounds, which results in that hole injection to the conductive polymer is advanced so as to contribute to improve the photoelectric conversion efficiency.

Moreover, in the conventional technology, when the positive hole transport layer containing a conductive polymer is formed by the light irradiation method, due to the reason of the remaining of the non-reacted compounds, it becomes difficult to secure the thermal stability of the photoelectric conversion element. As a result, at the time, of production of the photoelectric conversion element or after production of the photoelectric conversion element heat deterioration arises and photoelectric conversion efficiency is made to decrease. In contrast, in the present invention, in addition to form a positive, hole transportation substance by use of a conductive polymer including a sulfur heterocyclic structure represented by Formula (1) in a main chain structure, a compound which is represented by Formula (2) and deemed as being thermally stable and at least one of compounds represented by Formula (4) to (9) are used in combination as sensitizing dye, whereby it become possible to develop a photoelectric conversion element secured in thermal stability.

Thus, in the present invention, it is considered to cover charge formation loss components due to light absorption of a positive hole transportation substance by use of sensitizing dyes having a light absorption performance stronger than poly thiophene, thereby avoiding reverse movement of charge between sensitizing dyes and a positive hole transport layer. Further, it is considered to make a photoelectric conversion element thermally stable. As a result of repetition of studies, it is found out to use a compound with the structure represented by Formula (2) as sensitizing dyes to be used for a photoelectric conversion element which employs conductive polymers for a positive hole transportation substance. Further, by combination use of the compound represented by Formula (2) and at least one of compounds represented by Formula (4) to (9), it becomes possible to realize to cover charge loss due to visible light absorption of polythiophene compound and to attain stability for heat, thereby acquiring high photoelectric conversion efficiency.

In this connection, the content ratio of the compound with the structure represented by Formula (2) to at least one of the compounds with the respective structures represented, by Formulas (4) to (9) is not limited specifically. However, the content ratio may be preferably 1:10 to 10:1 in mole ratio, and more preferably 1:3 to 10:1.

Hereafter, specific examples of the compounds with the structure represented by Formula (2) are shown. However, the compounds represented by Formal a (2) which can be used in the present invention are not limited to these examples.

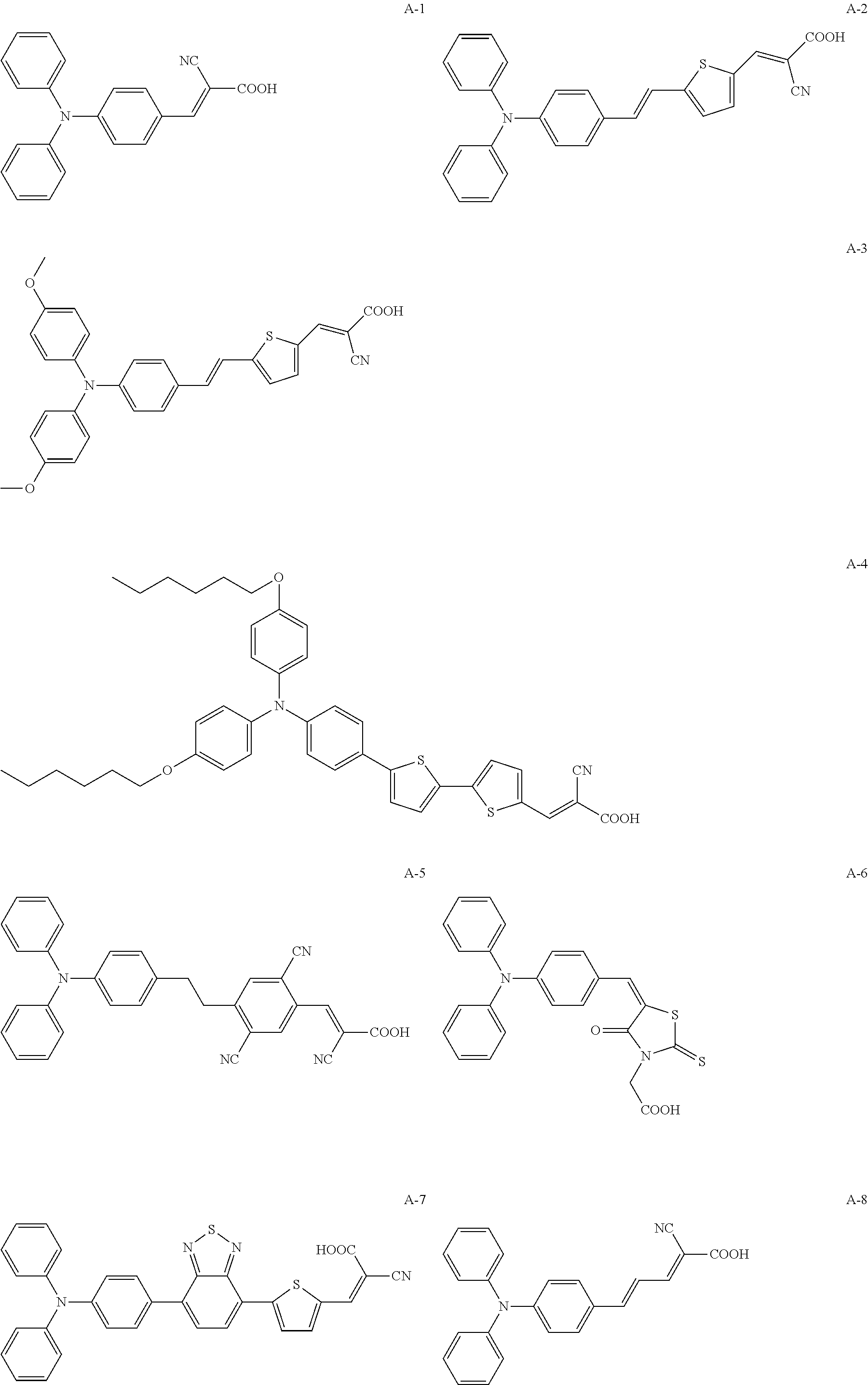

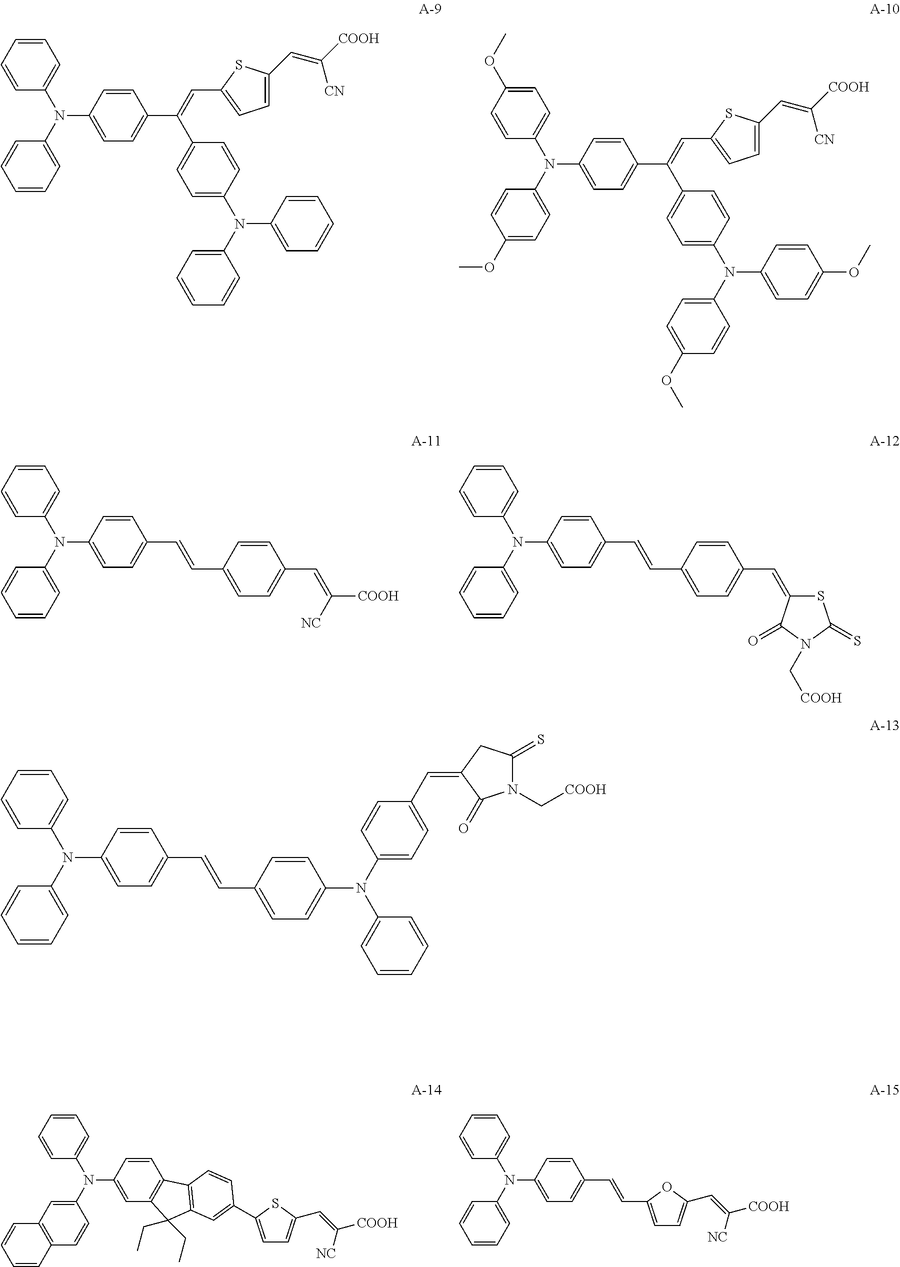

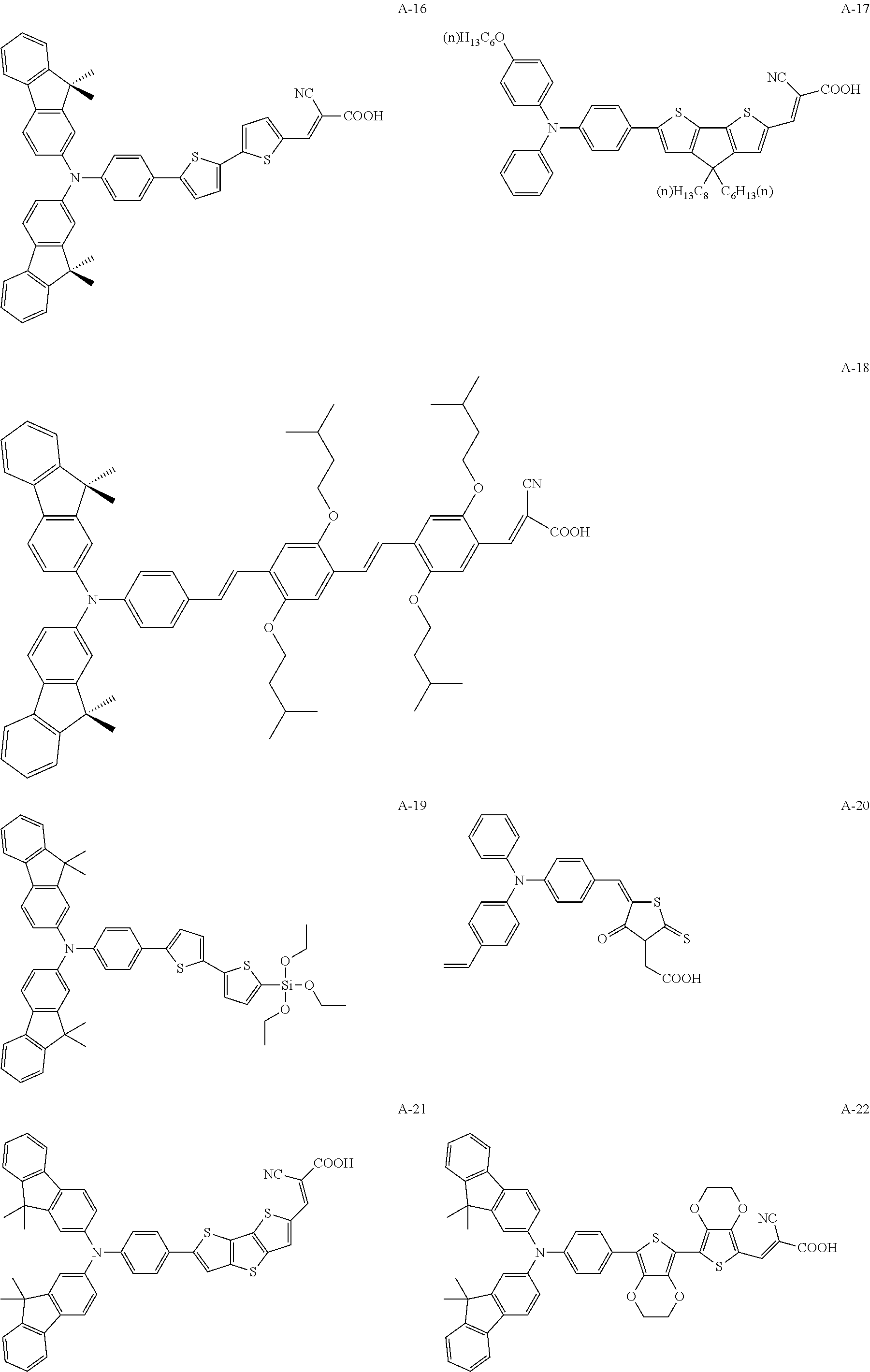

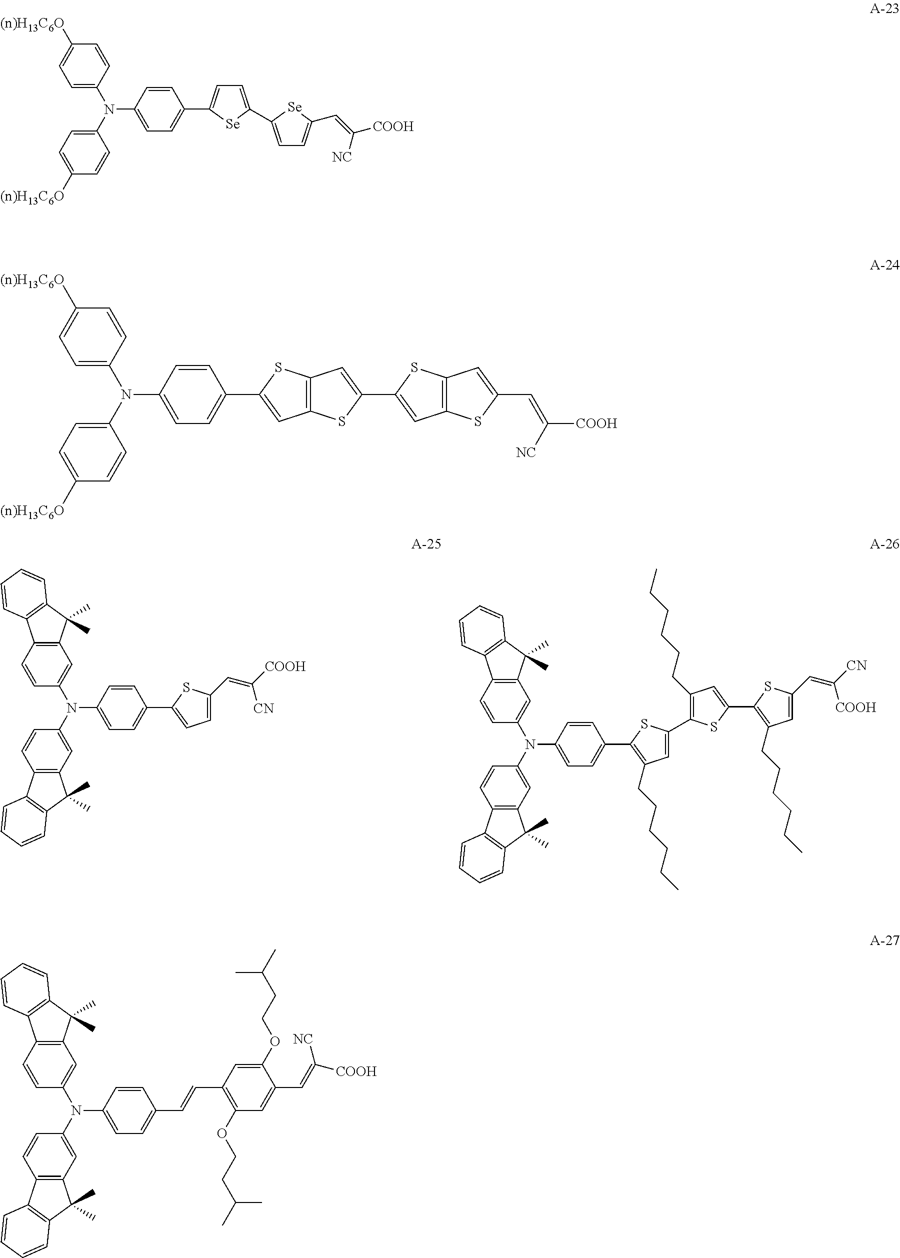

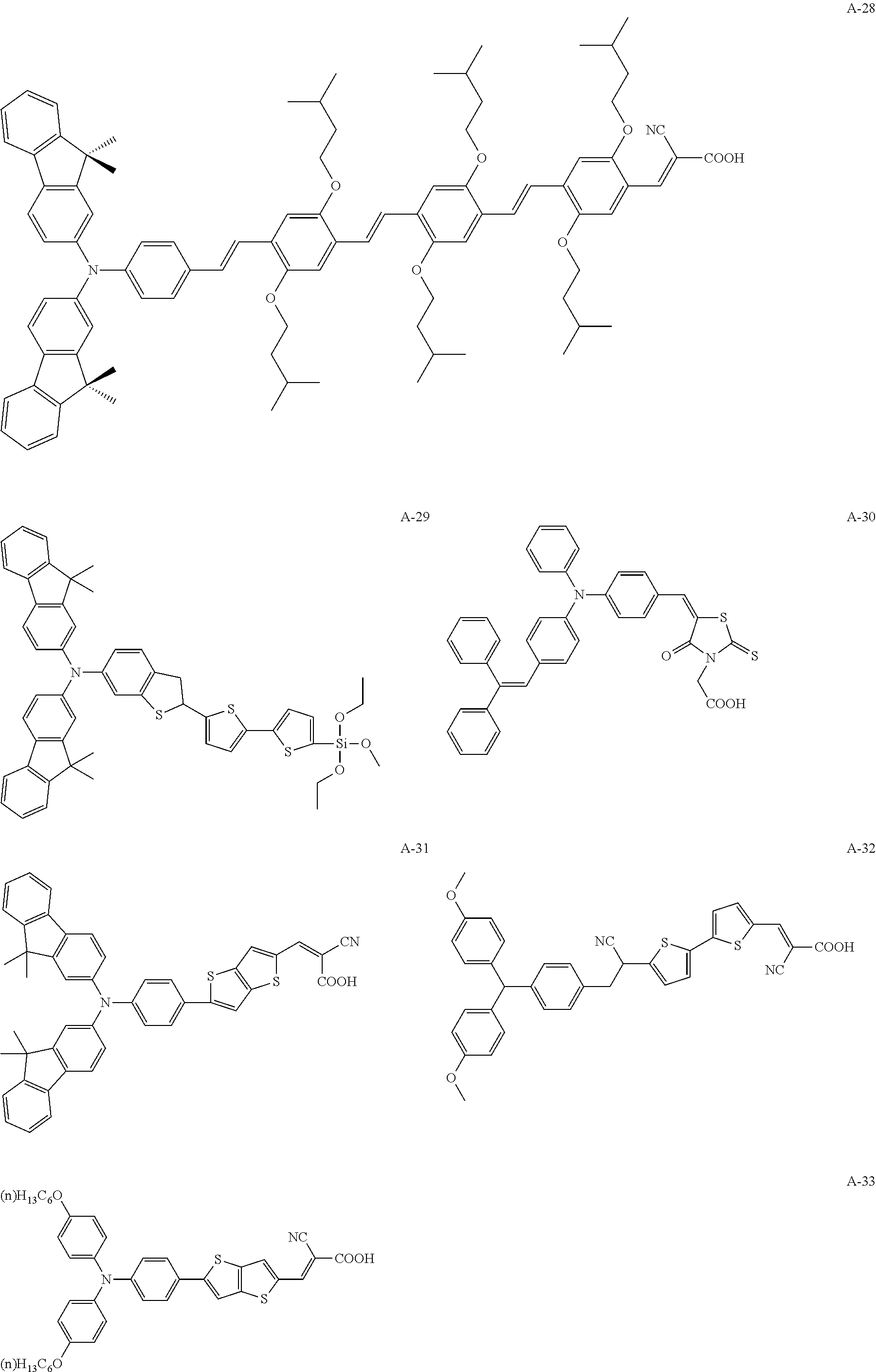

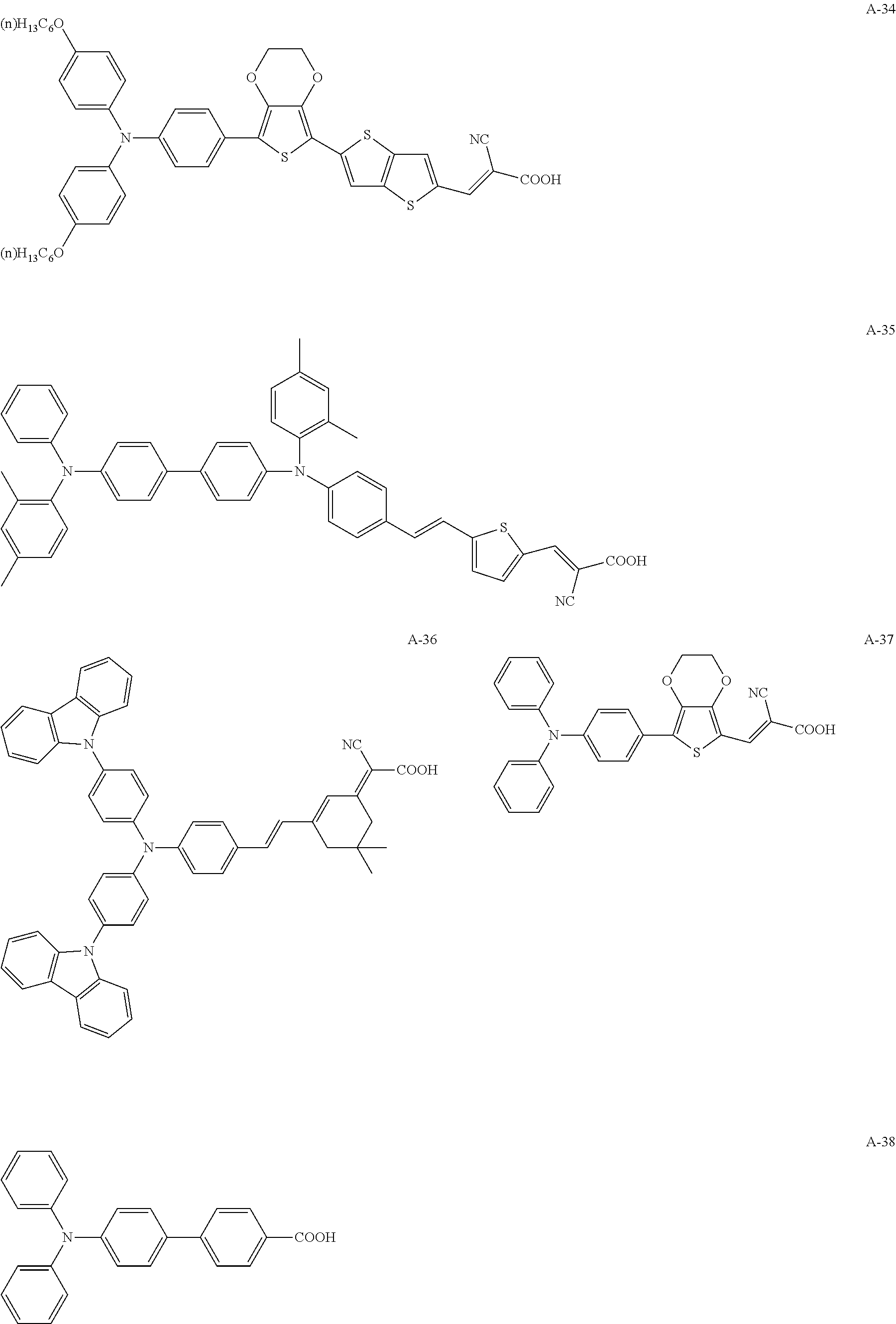

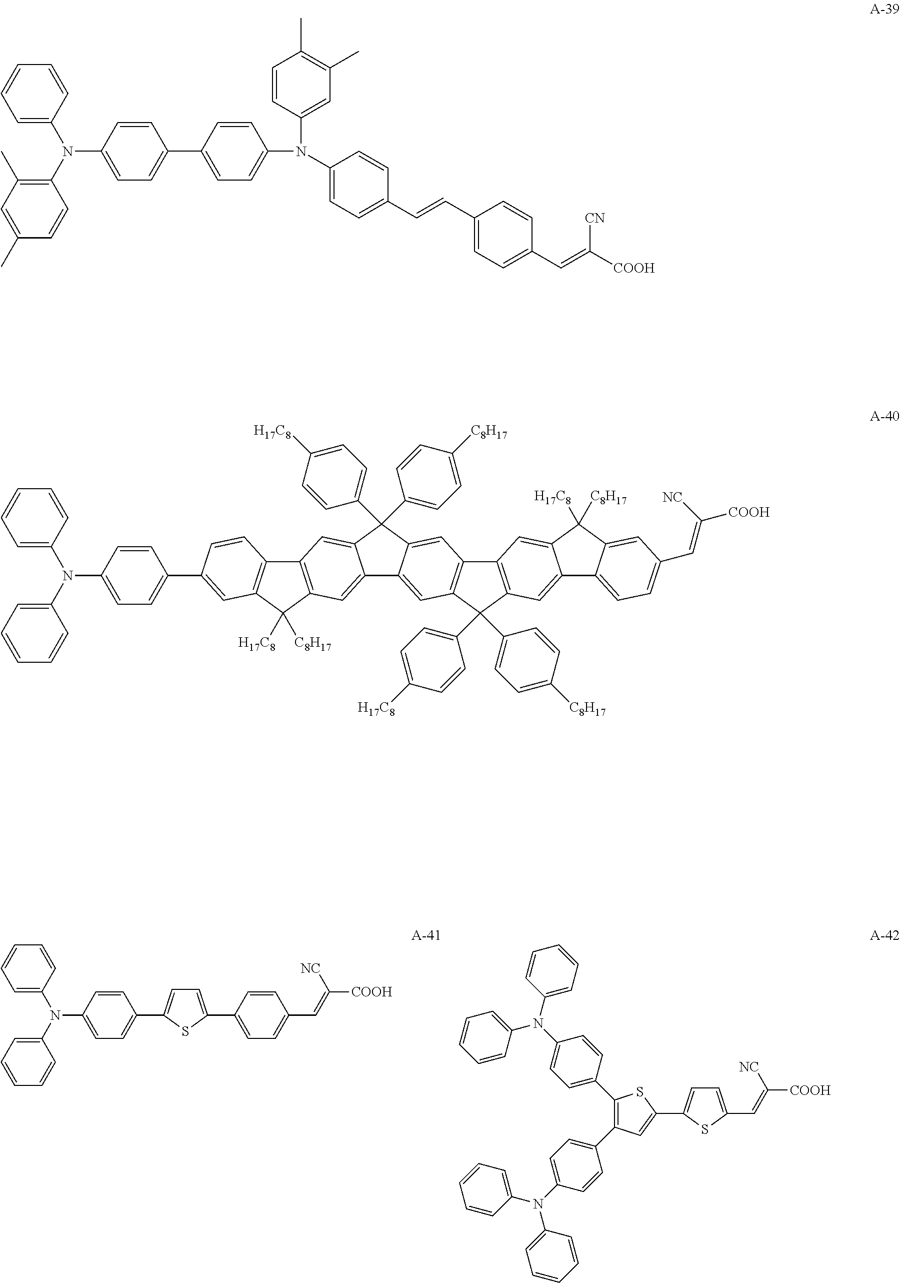

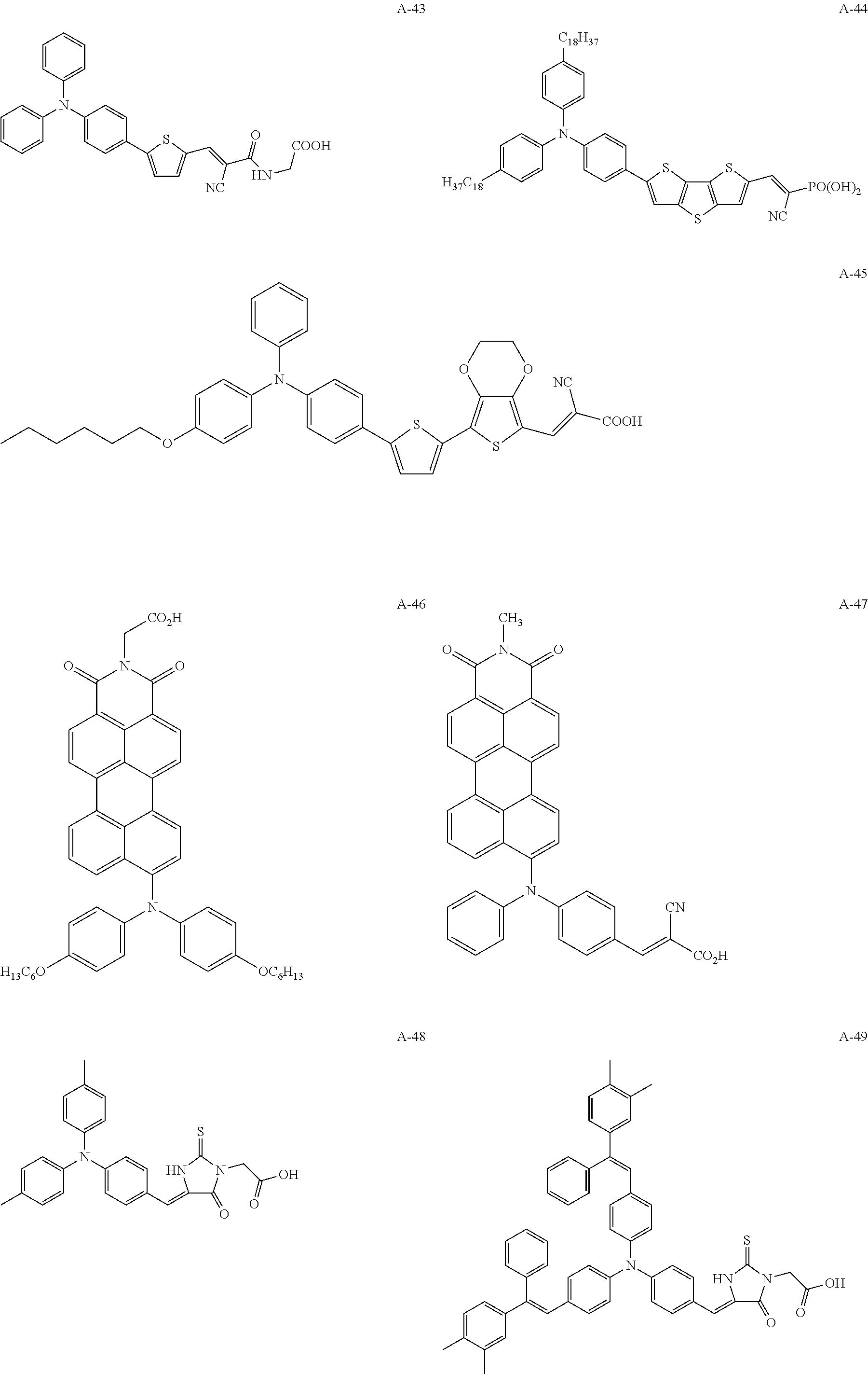

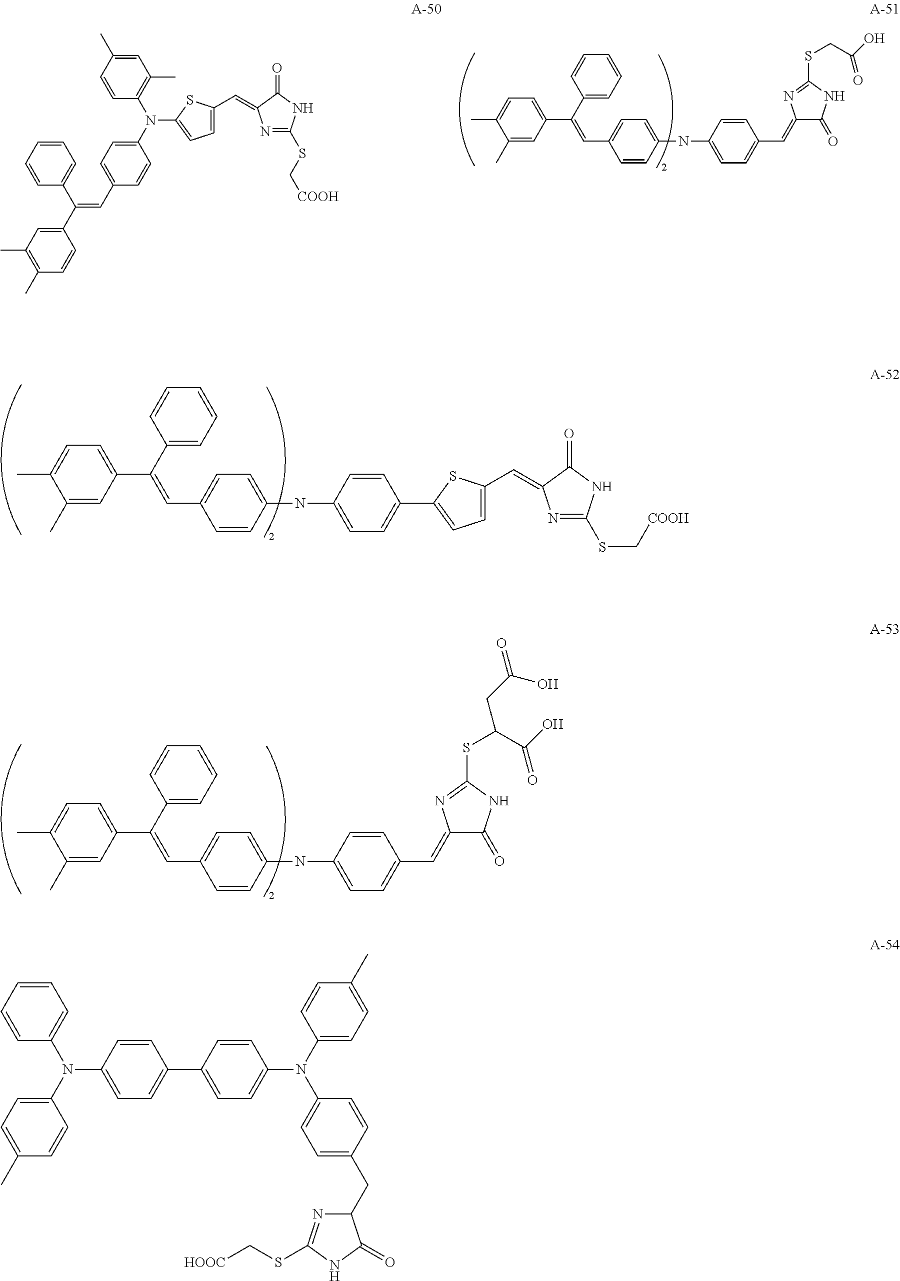

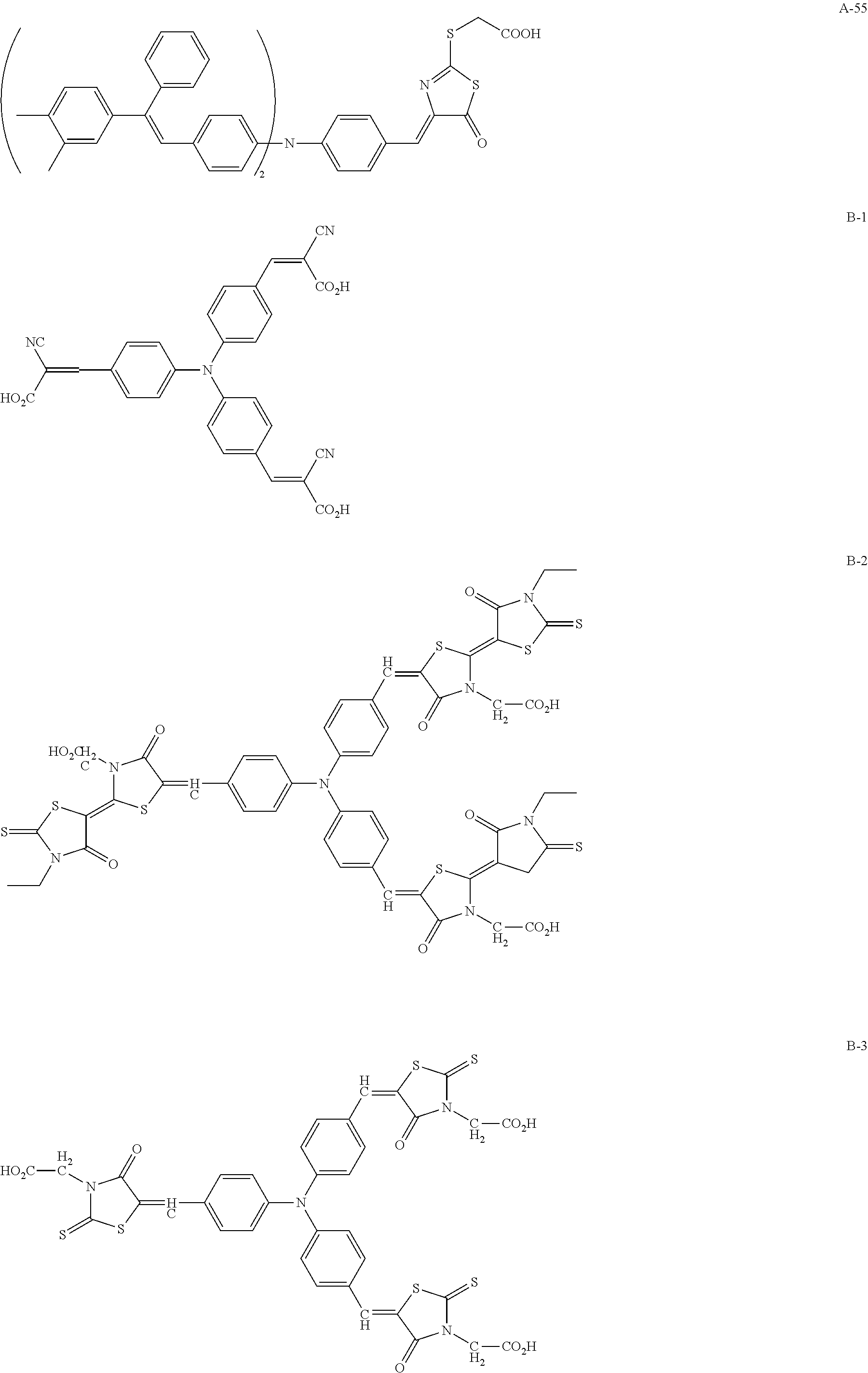

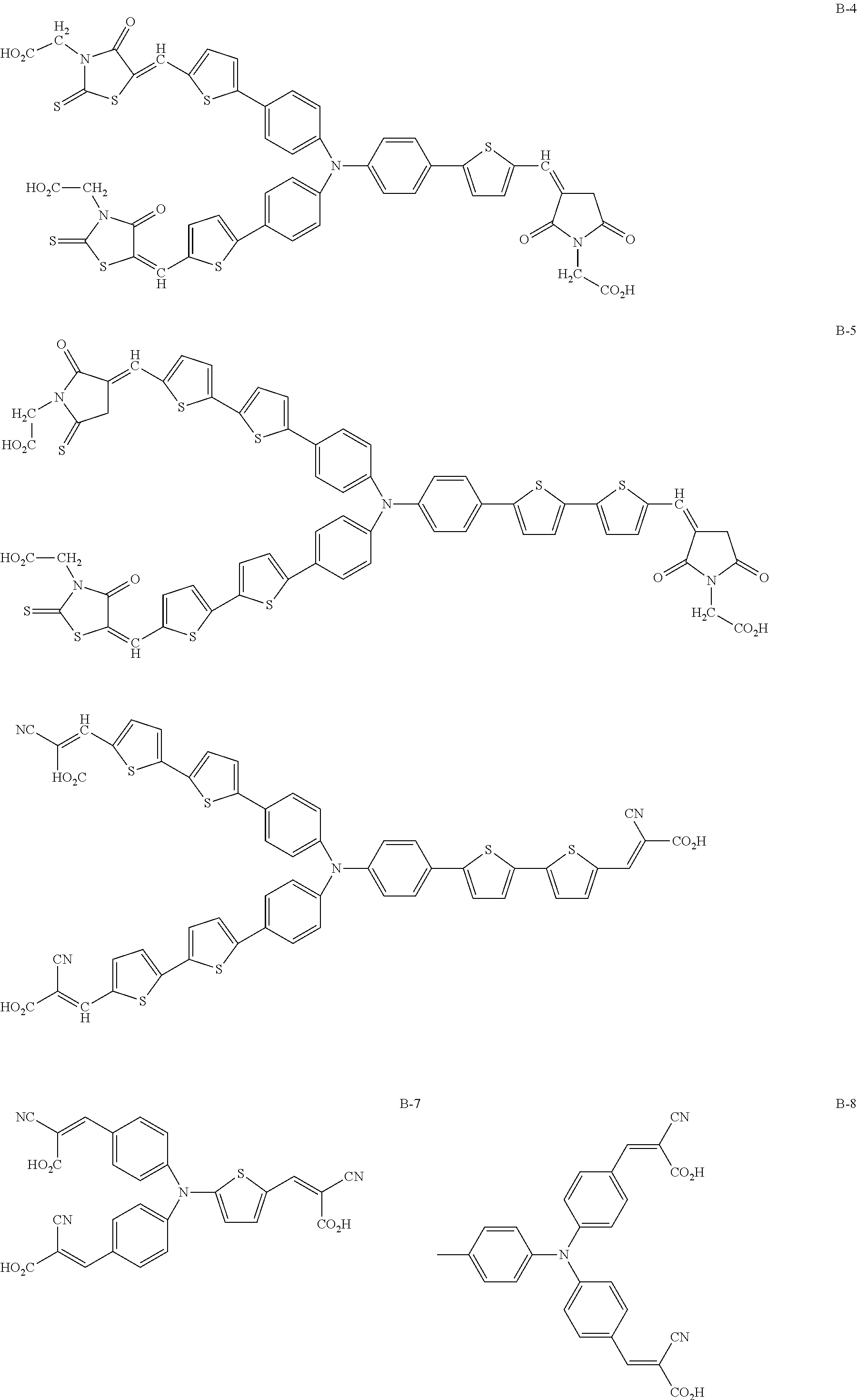

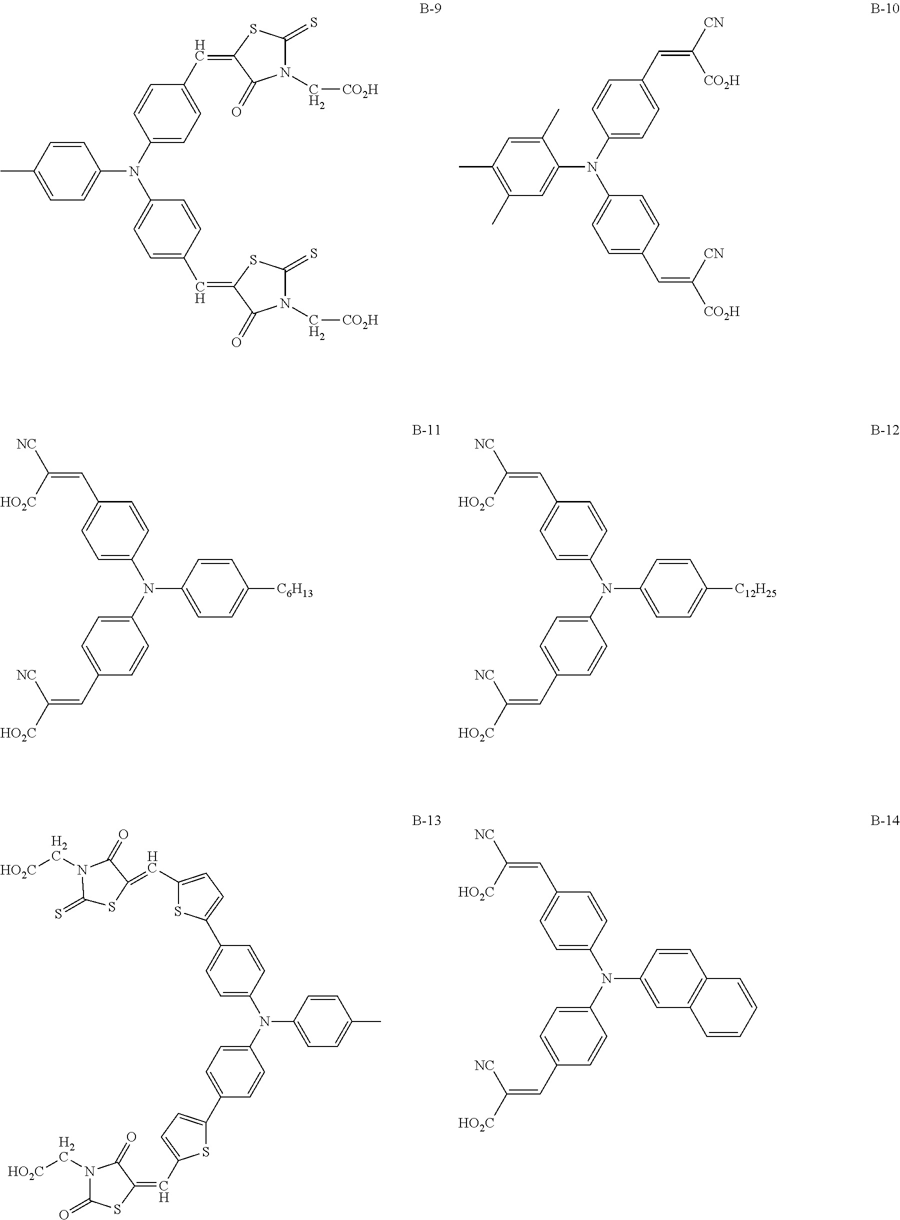

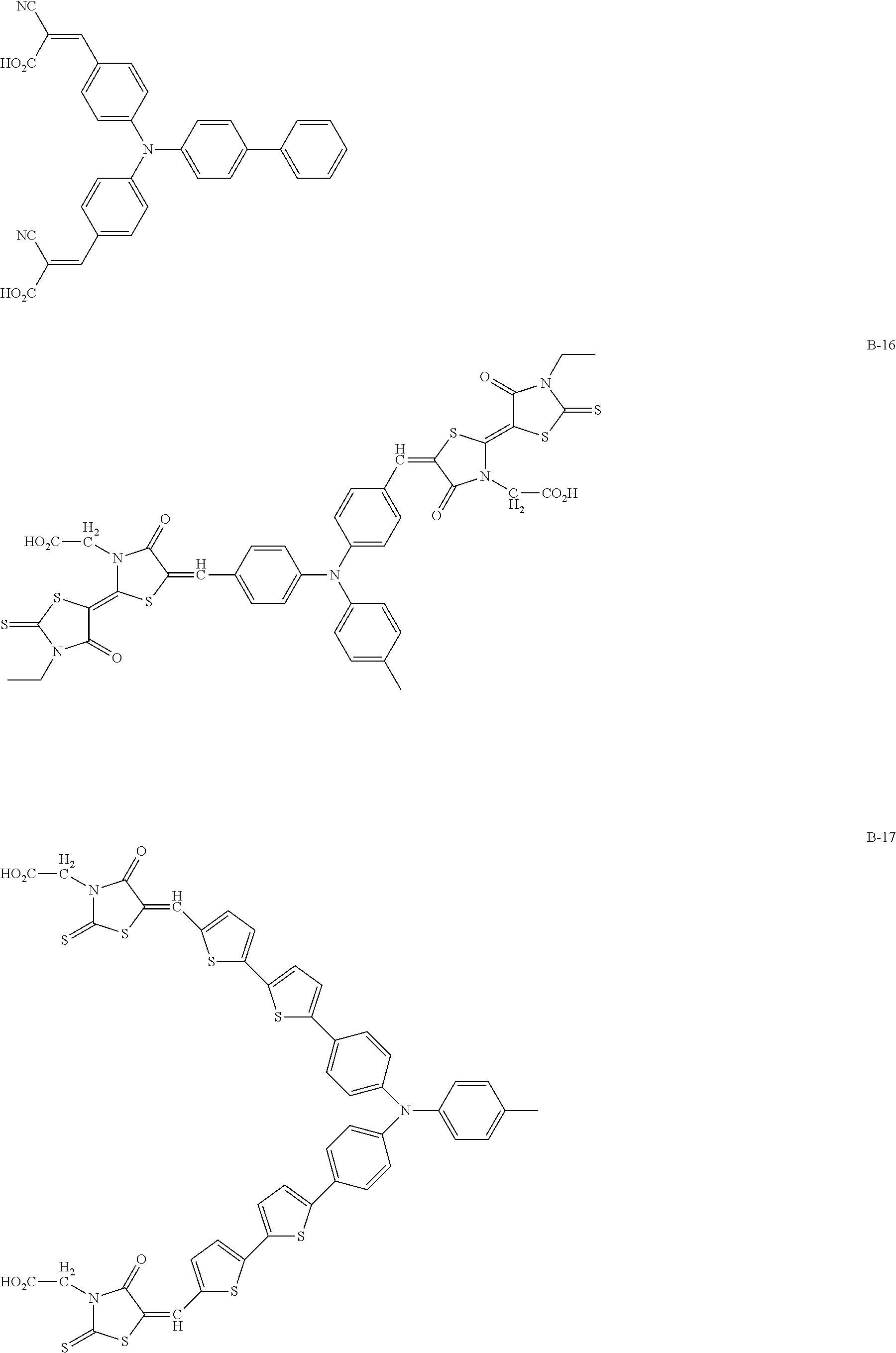 [SMILES: N#C/C(=C/c1ccc(N(c2ccc(/C=C(\C#N)C(=O)O)cc2)c2ccc(-c3ccccc3)cc2)cc1)C(=O)O ; CCN1C(=O)/C(=c2\sc(=Cc3ccc(N(c4ccc(C)cc4)c4ccc(/C=c5/s/c(=C6/SC(=S)N(CC)C6=O)n(CC(=O)O)c5=O)cc4)cc3)c(=O)n2CC(=O)O)SC1=S ; Cc1ccc(N(c2ccc(-c3ccc(-c4ccc(/C=C5\SC(=S)N(CC(=O)O)C5=O)s4)s3)cc2)c2ccc(-c3ccc(-c4ccc(/C=C5/SC(=S)N(CC(=O)O)C5=O)s4)s3)cc2)cc1]

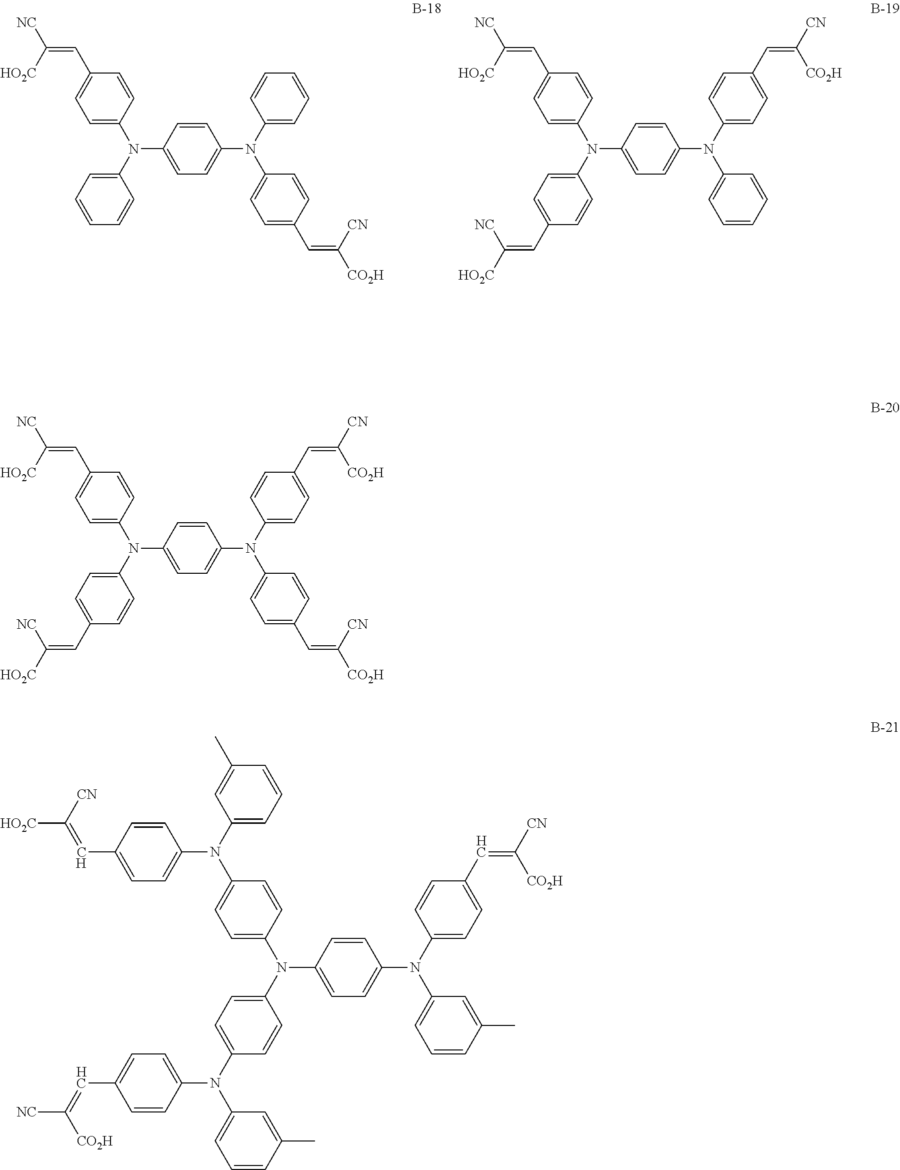 [SMILES: N#C/C(=C/c1ccc(N(c2ccccc2)c2ccc(N(c3ccccc3)c3ccc(/C=C(\C#N)C(=O)O)cc3)cc2)cc1)C(=O)O ; N#C/C(=C/c1ccc(N(c2ccccc2)c2ccc(N(c3ccc(/C=C(/C#N)C(=O)O)cc3)c3ccc(/C=C(\C#N)C(=O)O)cc3)cc2)cc1)C(=O)O ; N#C/C(=C/c1ccc(N(c2ccc(/C=C(\C#N)C(=O)O)cc2)c2ccc(N(c3ccc(/C=C(/C#N)C(=O)O)cc3)c3ccc(/C=C(\C#N)C(=O)O)cc3)cc2)cc1)C(=O)O ; Cc1cccc(N(c2ccc(/C=C(/C#N)C(=O)O)cc2)c2ccc(N(c3ccc(N(c4ccc(/C=C(/C#N)C(=O)O)cc4)c4cccc(C)c4)cc3)c3ccc(N(c4ccc(/C=C(\C#N)C(=O)O)cc4)c4cccc(C)c4)cc3)cc2)c1]

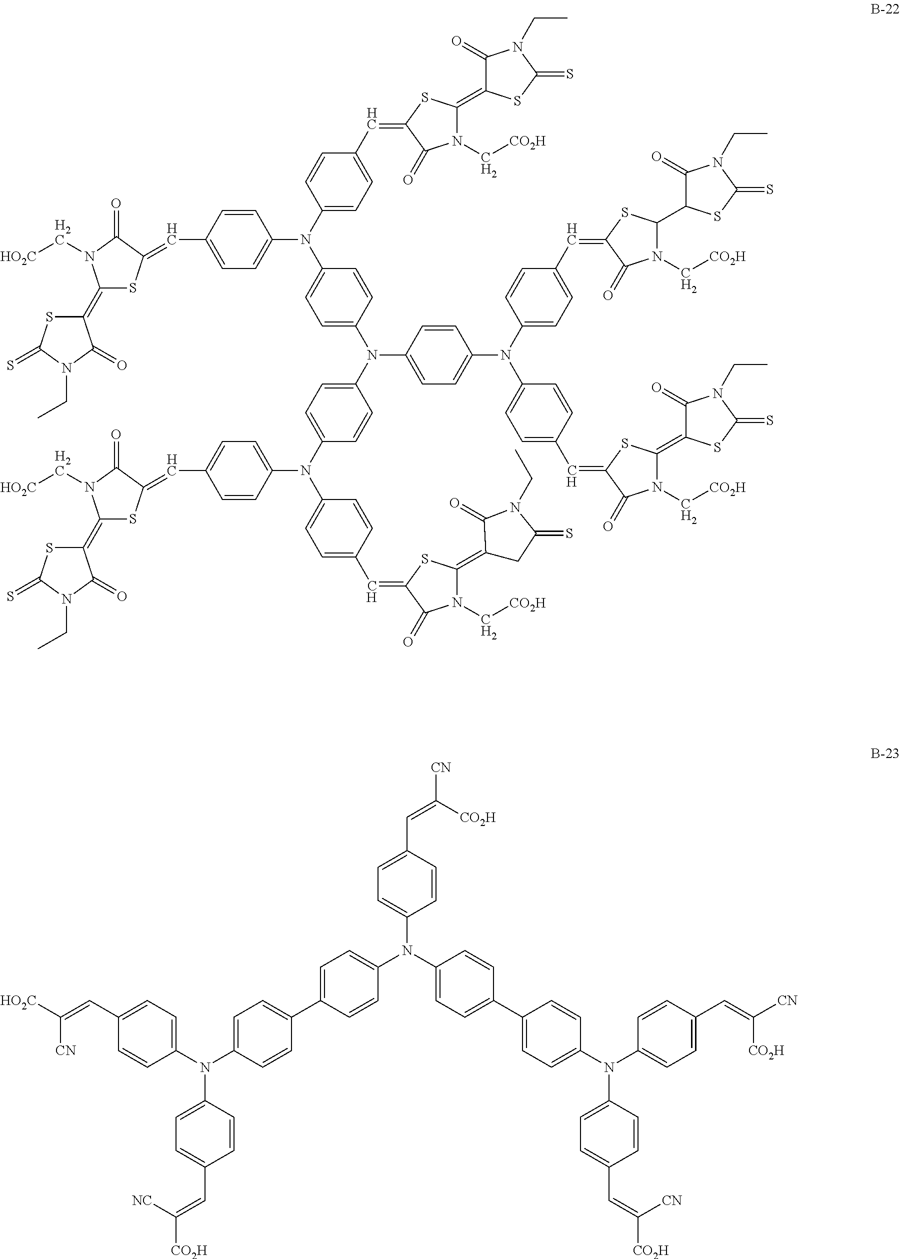

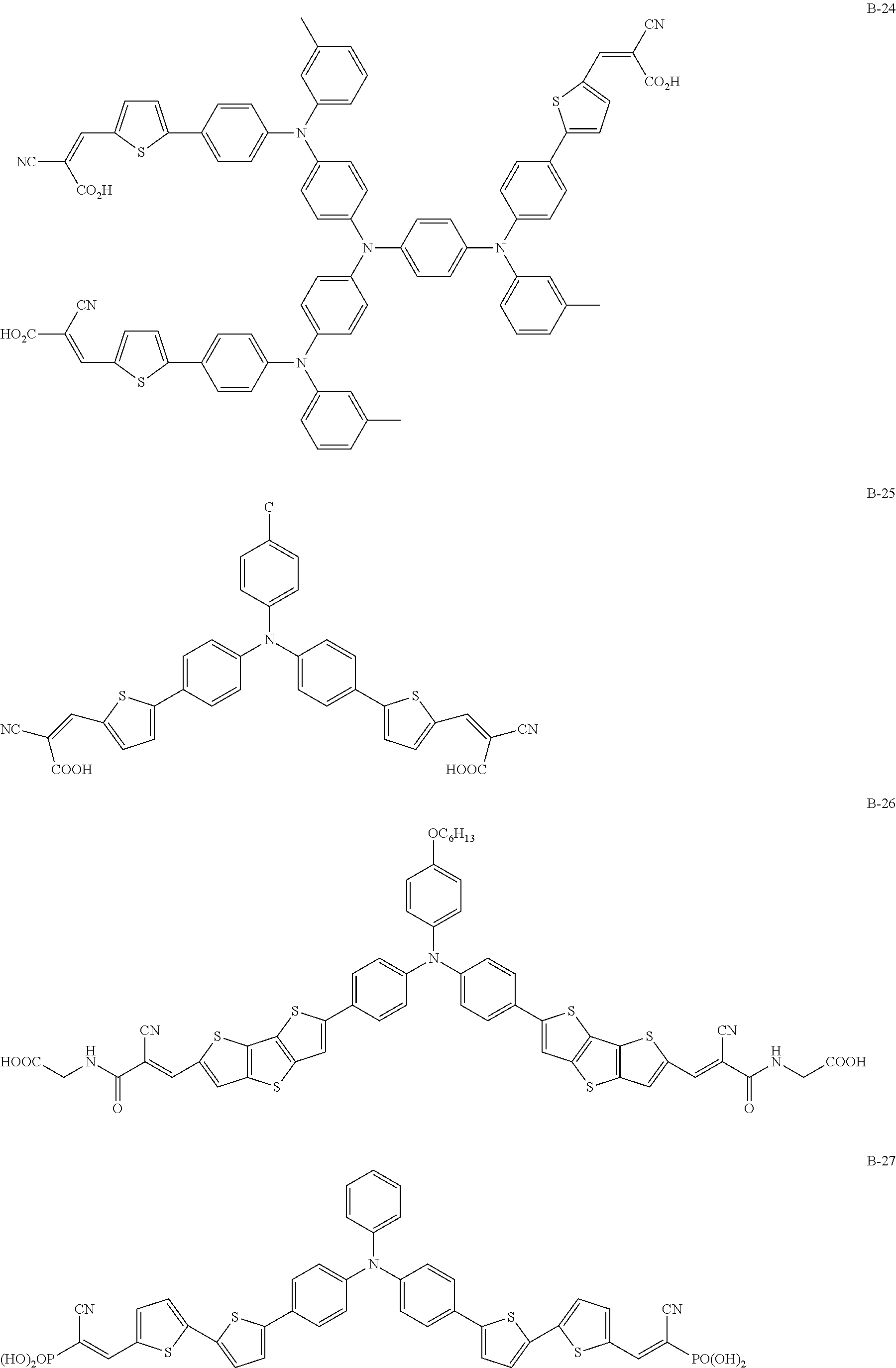

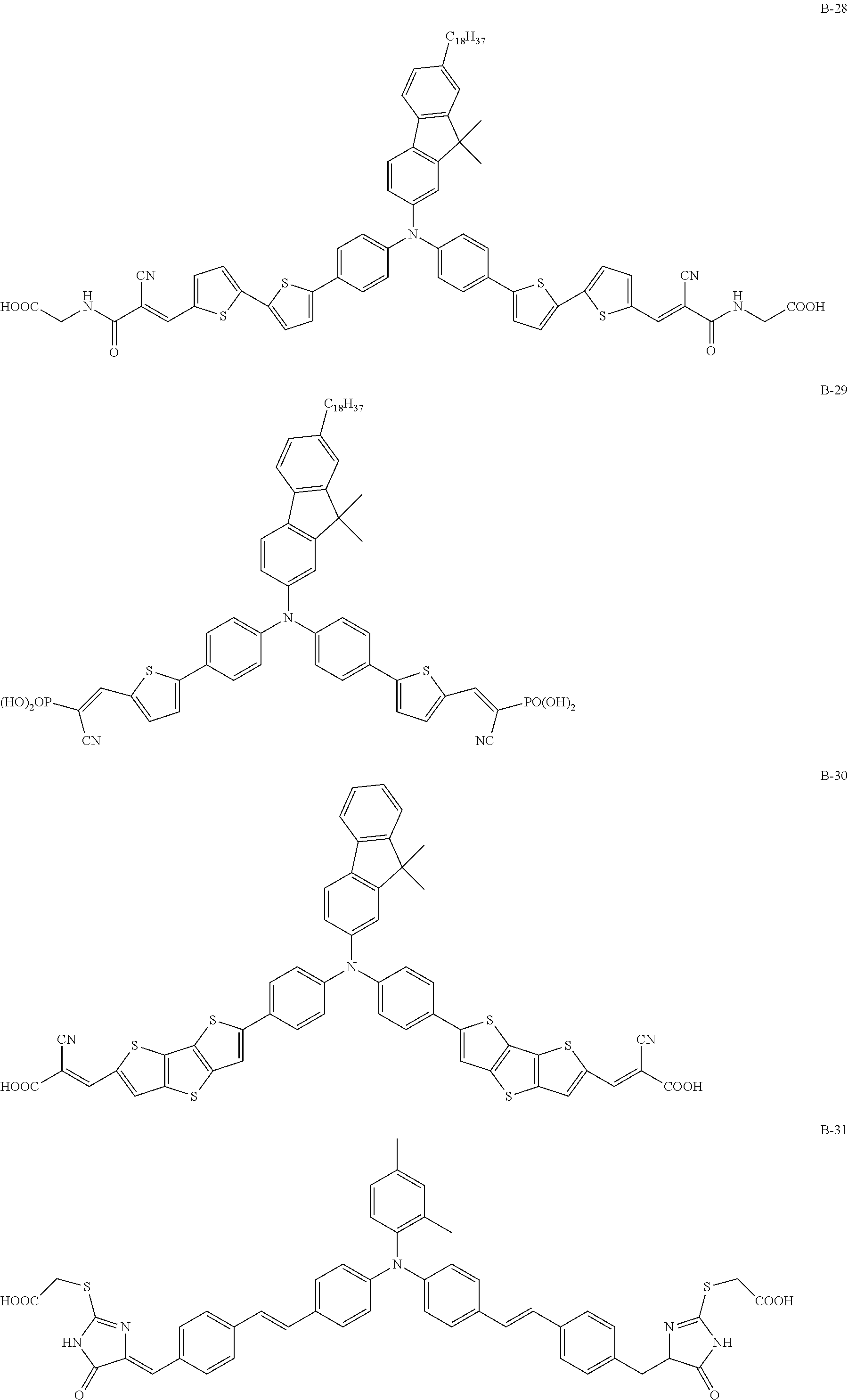

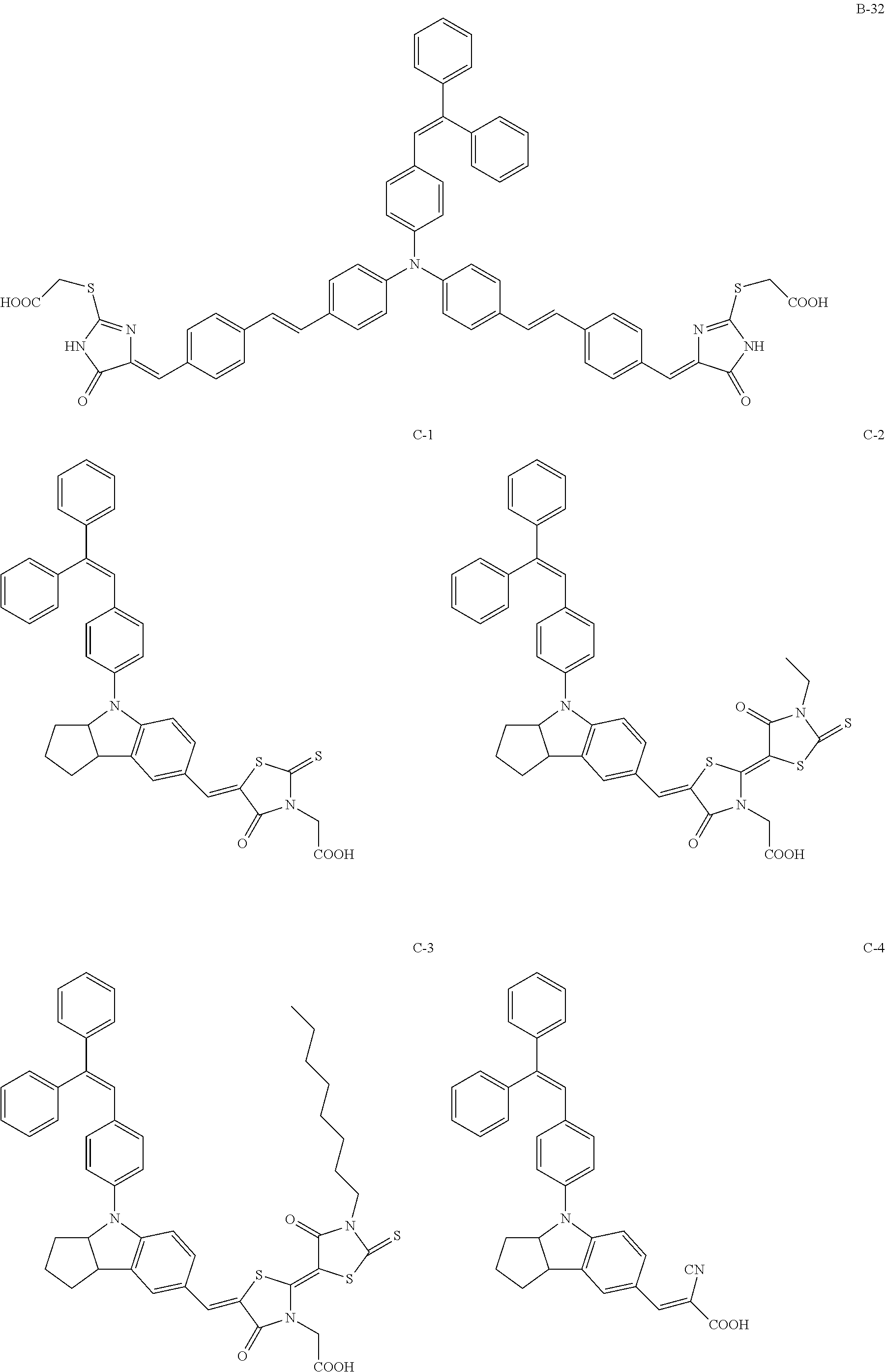

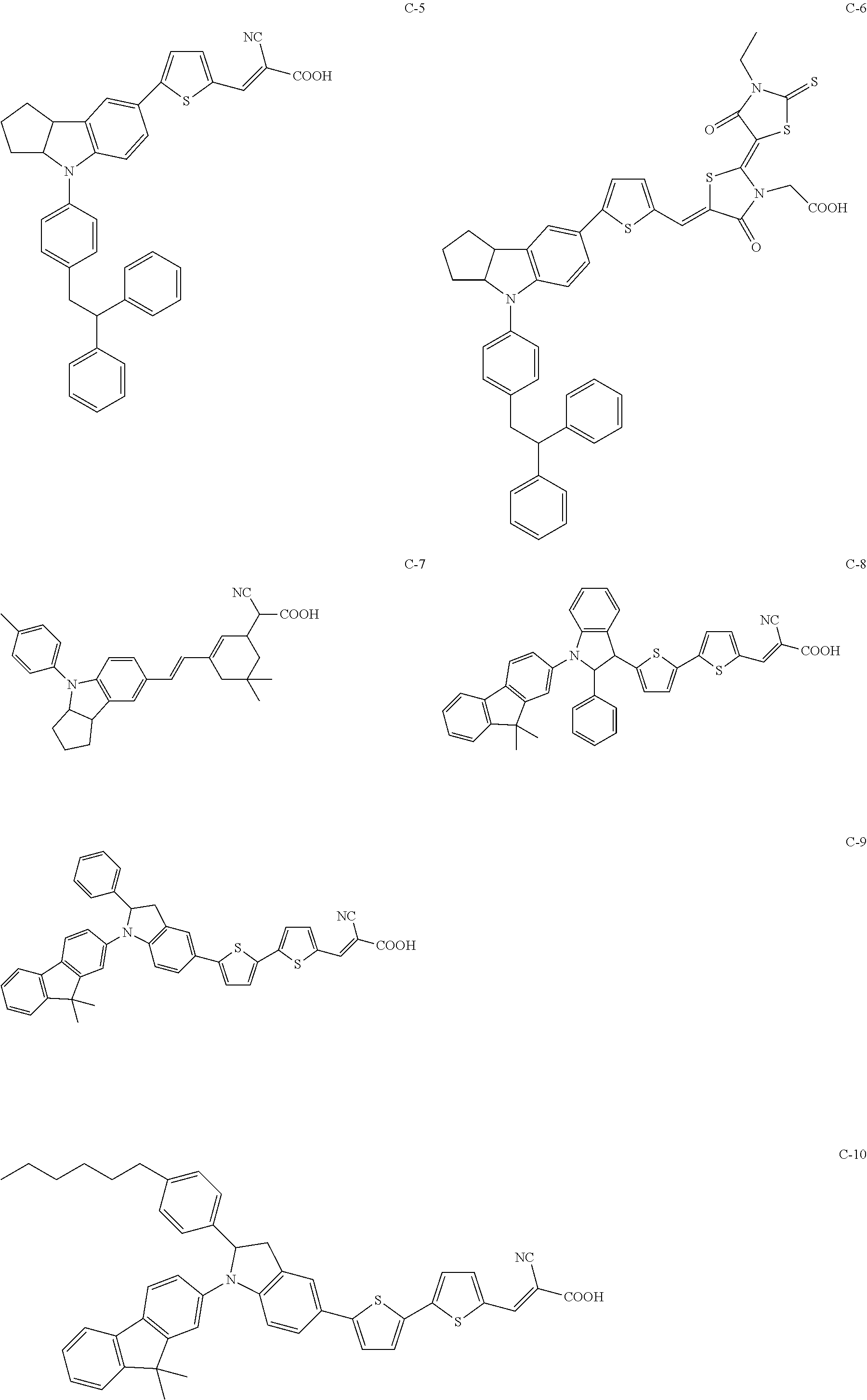

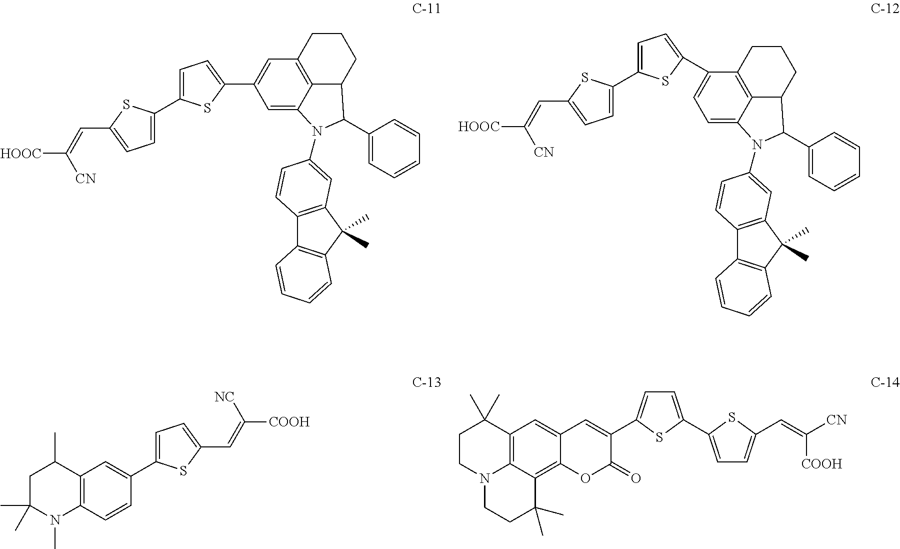

In the present invention, among the compounds represented by Formula (2), it is desirable to employ compounds with the mixture represented by Formula (3) where each of Ar and R3 in the structure is a phenyl group, as the sensitizing dye also.

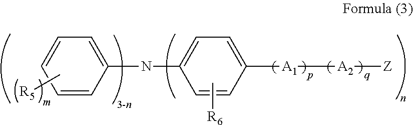

In Formula (3), m represents an integer of 1 or more and 5 or less, and n represents an integer of 1 or 2. R₅ and R₆ each represents a hydrogen atom, a halogen atom, a substituted or unsubstituted alkyl group, alkoxy group, alkenyl group, alkynyl group, aryl group, amino group, cyano group, or heterocycle group, and may link to each other so as to form a ring structure.

Further, each of A₁ and A₂ represents a heterocycle group containing a sulfur atom, and each of p and q is an integer of 0 or more and 6 or less. Z represents an organic group containing at least one hydroxy group or acidic group, and when m is 2, A₁, A₂, and Z may be different from each other.

The compound with the structure represented by Formula (3) is generally called a triphenylamine compound, and includes a part where three phenyl groups combine with a single nitrogen atom in the molecular structure. The exemplary compounds with the structure represented by Formula (3) correspond to the above-mentioned compounds of A-1 to A-52 and B-1 to B-32.

The compound with the structure represented by Formula (2), and the compound with the structure represented by Formula (3) used as the sensitizing dye in the present invention are used by being made to adsorb to the semiconductor mentioned later in the photoelectric conversion layer, The photoelectric conversion layer in which the above compounds are made to adsorb to the semiconductor conduct to transfer electrons for the first electrode and convert light energies into electric energy.

That is, light having passed through the first electrode advances into the photoelectric conversion layer, and then the advanced light collides with the semiconductors. The light having collided with the semiconductors causes scattered reflection in the arbitrary directions and diffuses In the photoelectric conversion layer. Successively, the diffused light comes in contact with the sensitizing dyes, thereby generating electrons and positive holes (hole). Subsequently, the generated electrons move toward the first electrode. In such a mechanism, the photoelectric conversion layer is configured to convert light energy into electric energy.

The sensitizing dye generates electrons and a positive hole (hole) by reception of light, thereby substantially converting light energy into electric energy in the photoelectric conversion layer. That is, the region where the sensitizing dyes exist in the photoelectric conversion layer is a place which functions as a light receiving region which generates electrons and positive holes. The sensitizing dyes are made to adsorb on and bond with the outer surface of She semiconductor or the inner surface of pores of the semiconductor, and sensitizing dye. The electrons generated in the sensitizing dye by reception of light move to the semiconductor with which the sensitizing dyes bond, and further move from the semiconductor to the first electrode.

Next, the compounds represented by Formula (4) to (9) employed as the sensitizing dye in the present invention together with the compounds with the structure represented by Formula (2) or Formula (3) will be explained.

First, the compound represented by Formula (4) will be explained. The compound represented by Formula (4) is generally called a “phthalocyanine compound”.

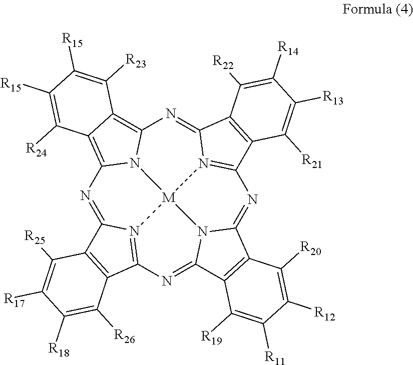

In Formula (4), each of R₁₁ to R₂₆ represents independently a hydrogen atom, a halogen atom, a substituted or unsubstituted alkyl group, alkoxy group, aryl group, or phenoxy group, and an acidic group is included in at least one position on R₁₁ to R₂₆. Further, in Formula (4), M represents two hydrogen atoms or a divalent, trivalent, or tetravalent metal atom that may include a substituent group, Examples of the metal atoms represented by M include magnesium (Mg), zinc (Zn), calcium (Ca), gallium (Ga), titanium (Ti), ruthenium (Ru), copper (Cu), and silicon (Si).

Hereafter, specific examples of the phthalocyanine compound of the compound represented by Formula (4) which can be used in the present invention are shown. However, the phthalocyanine compound which can be used in the present invention should not be limited to the following examples.

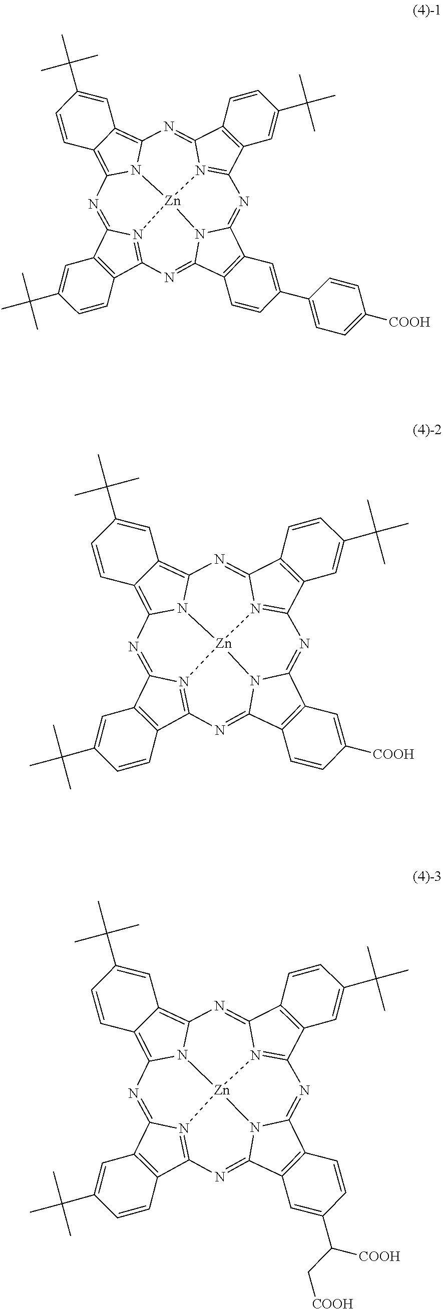

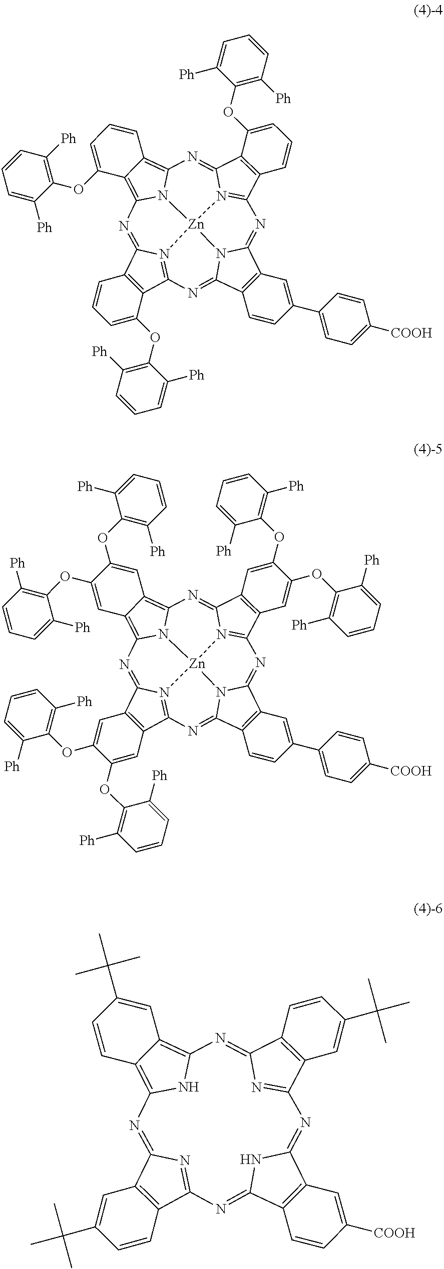

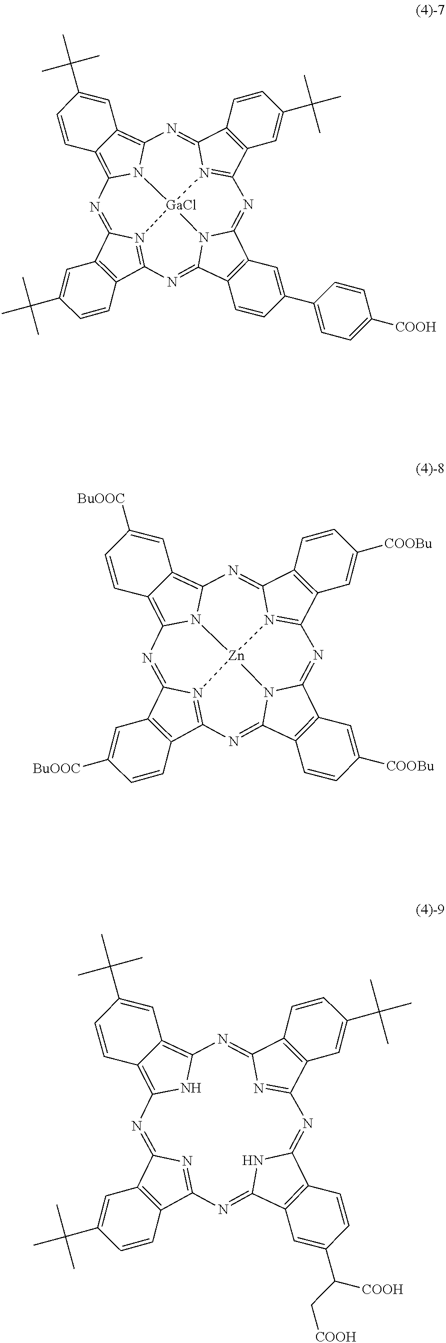

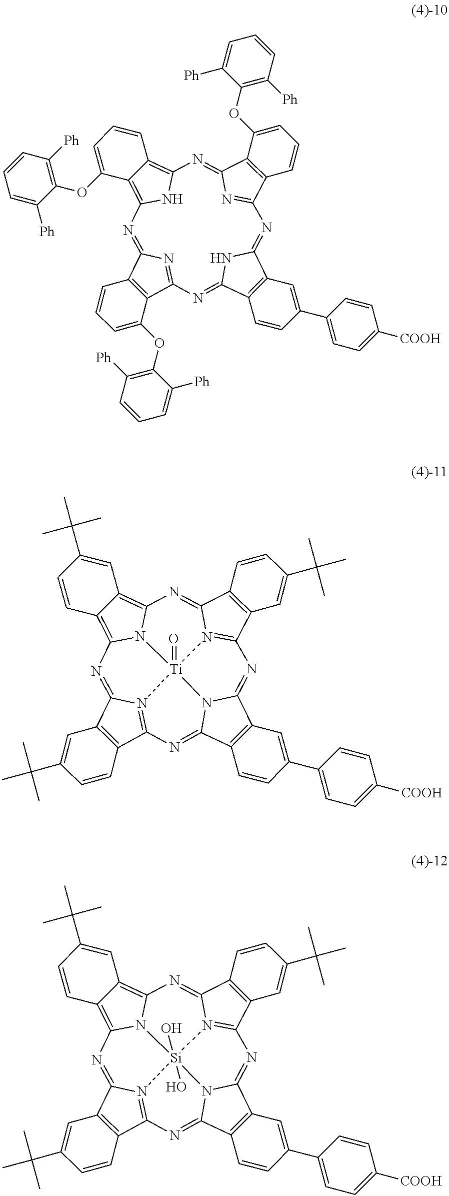

Next, the compound represented by Formula (5) will be explained. The compound represented by Formula (5) is generally called a “porphyrin compound”.

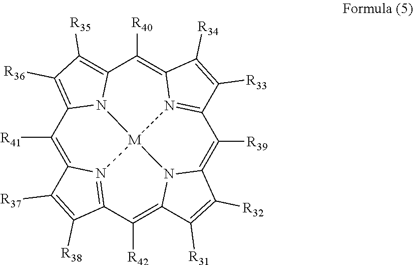

In Formula (5), each of R₃₁ to R₄₂ represents independently a hydrogen atom, a halogen atom, or a substituted or unsubstituted alkyl group, alkenyl group, alkynyl group, aryl group, amino .group, heterocycle group, or group forming a ring-shaped structure or ring-fused structure directly or via other bonded atom, and an acidic group is included in at least one position on R₃₁ to R₄₂. Further, in Formula (5), M represents two hydrogen atoms or a divalent, trivalent, or tetravalent metal atom that may include a substituent group. Specific examples of the metal atoms represented by M include the above-mentioned metal atoms described in the compounds represented by Formula (4).

Hereafter, specific examples of the porphyrin compound represented by Formula (5) which can be used in the present invention are shown. However, the porphyrin compound which can be used in the present Invention should not be limited to the following examples.

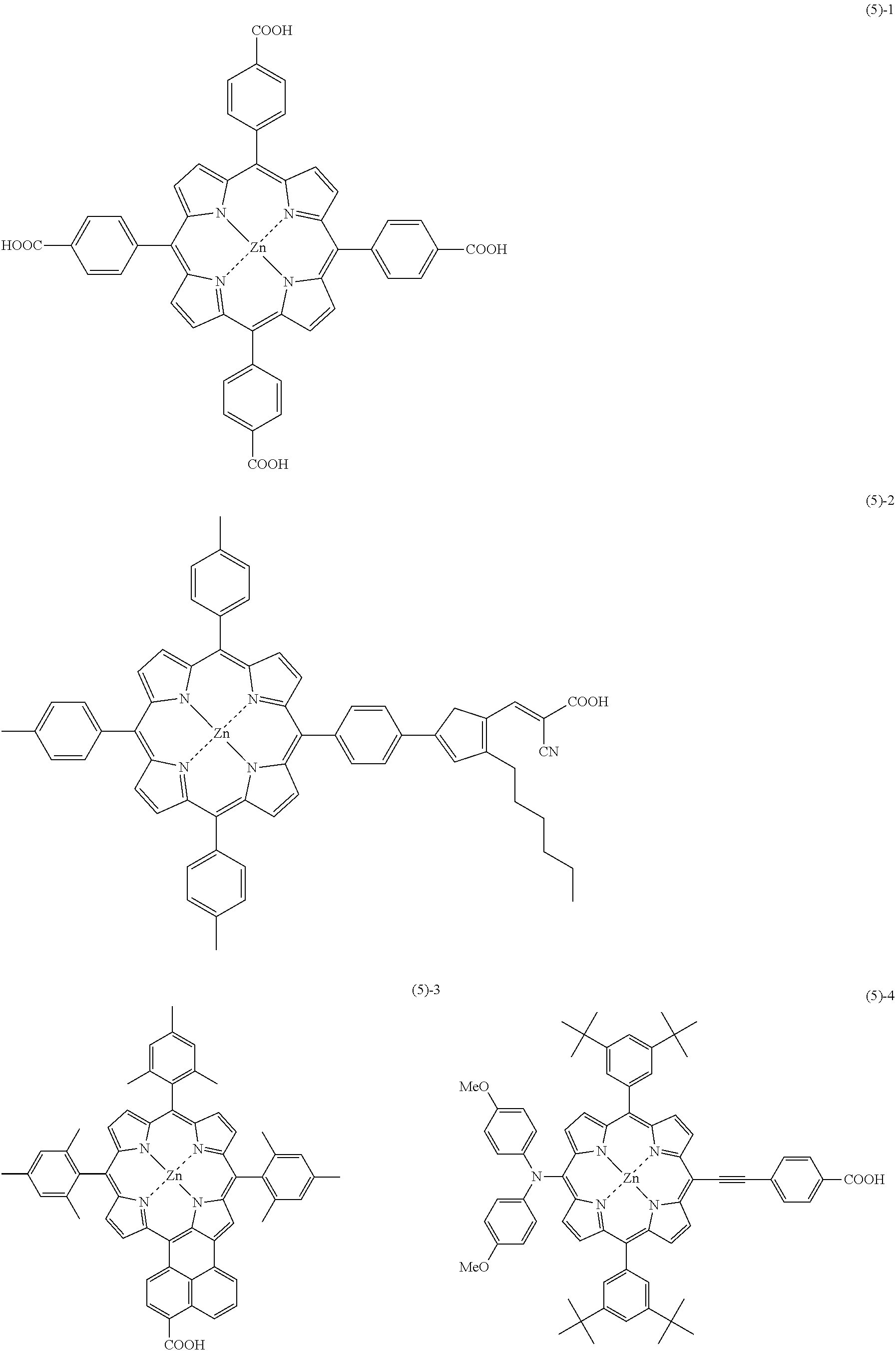

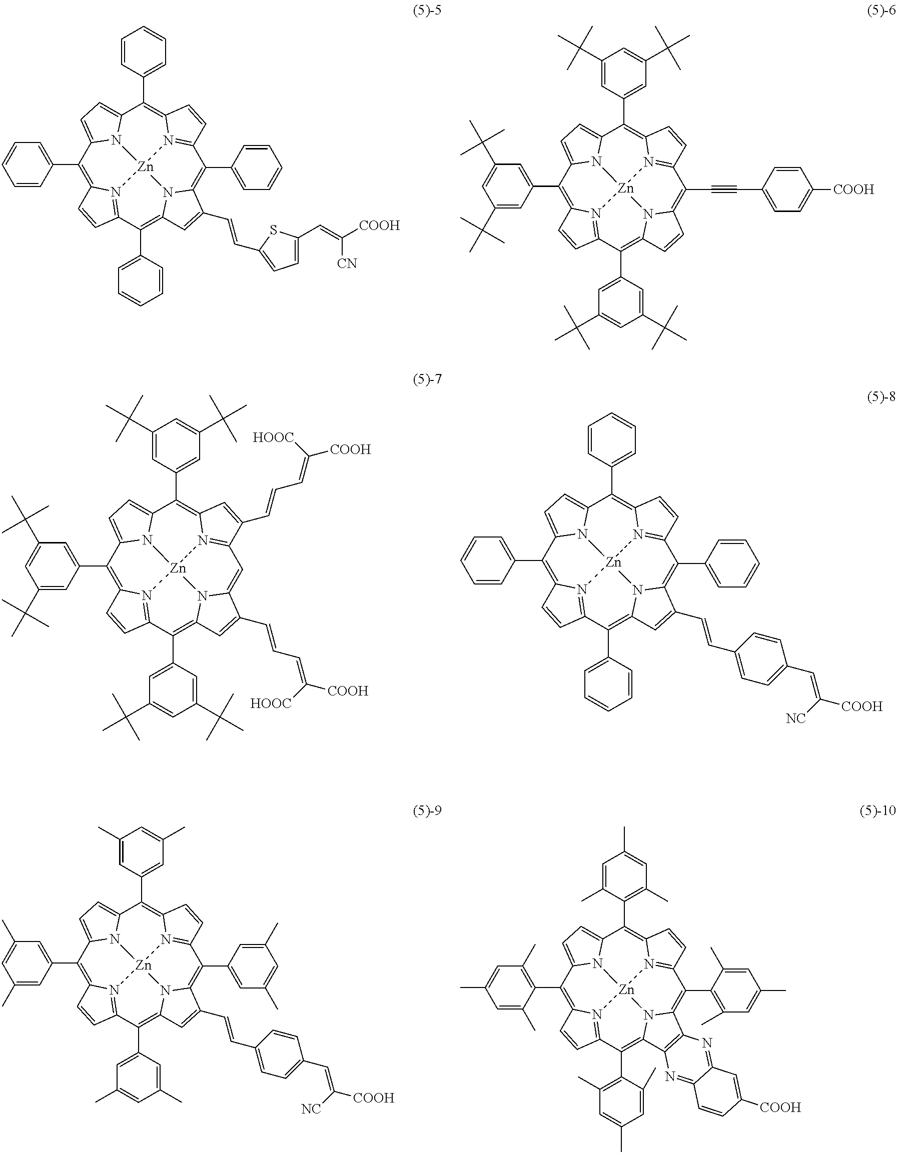

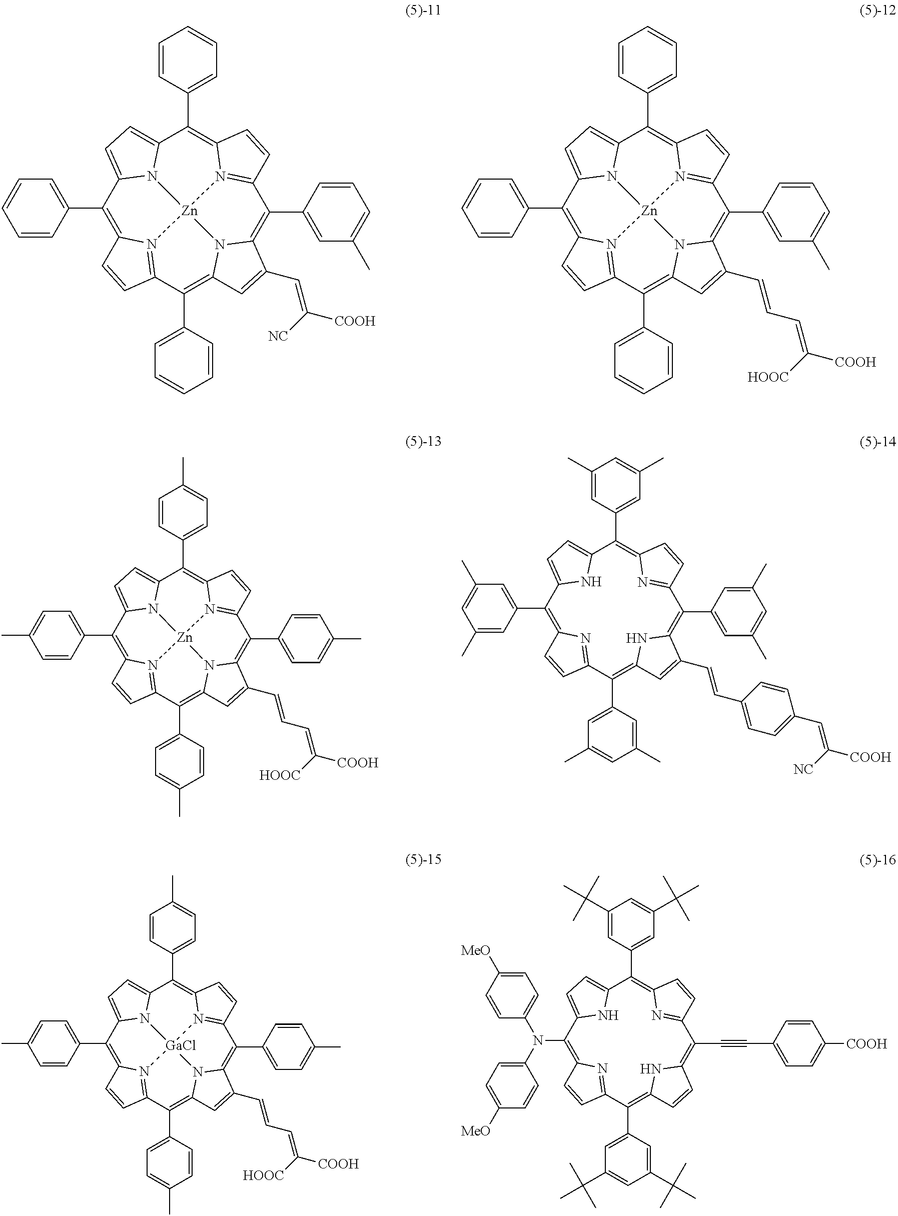

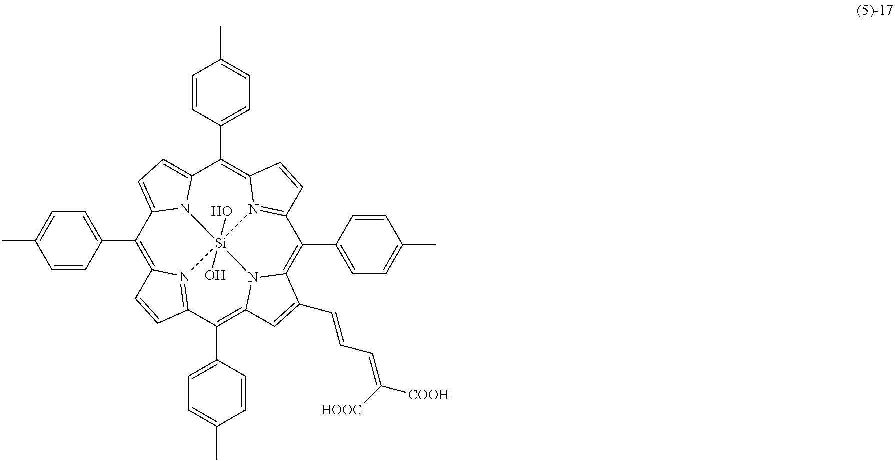

Next, the compound represented by Formulas (6) and (7) will be explained. The compound represented by Formula (6) and the below-mentioned compound represented by Formula (8) are generally called a “squarylium compound”.

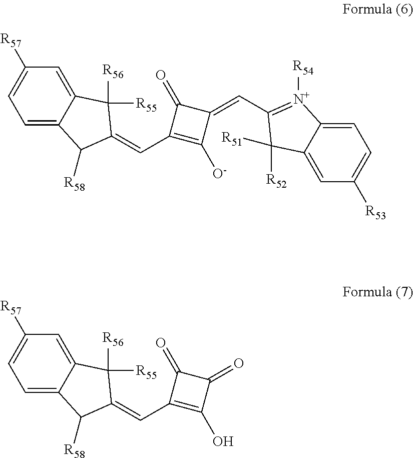

Each of R₅₃ and R₅₄ in Formula (6), or each of R₅₇ and R₅₈ both Formulas (6) and (7) represents independently a hydrogen atom, a halogen atom, or a substituted or unsubstituted alkyl group, alkenyl group, alkynyl group, aryl group, or heterocycle group, and an acidic group is included in at least one position on the above section. Further, each of R₅₁ and R₅₂ in Formula (6), or each of R₅₅ and R₅₆ both Formulas (6) and (7) represents an alkyl group with the same number of carbons or the different number of carbons, an aryl group, or an alkyl group-substituted aryl group.

Hereafter, specific examples of the compounds represented by Formula (6) and (7) which can be used in the present invention are shown. However, the compounds which can be used in the present invention should not be limited to the following examples.

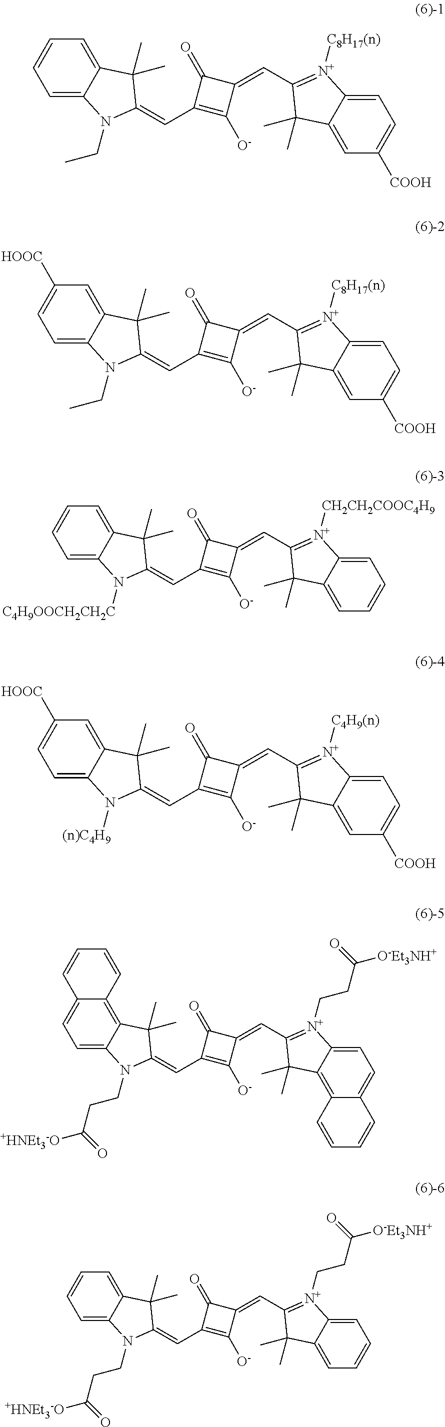

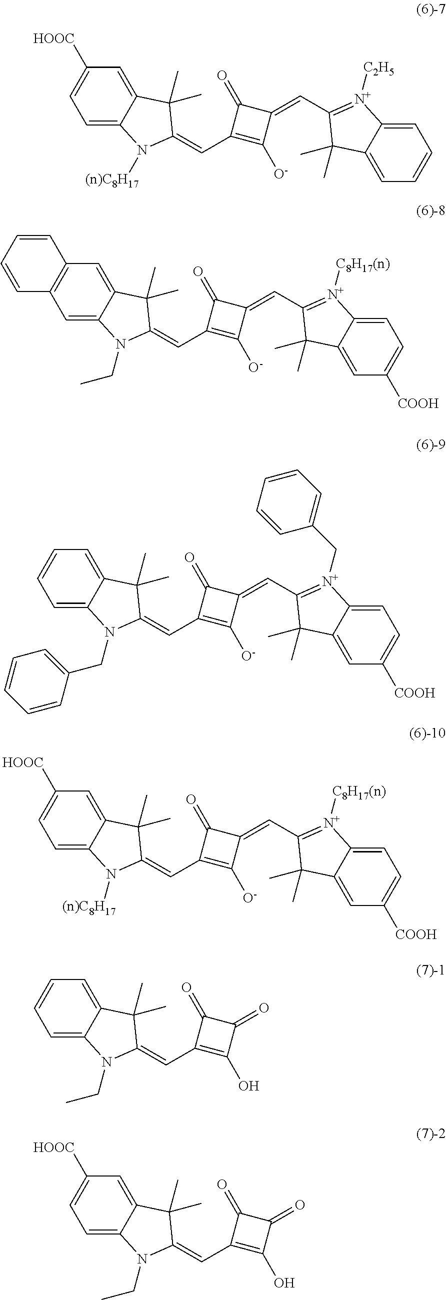

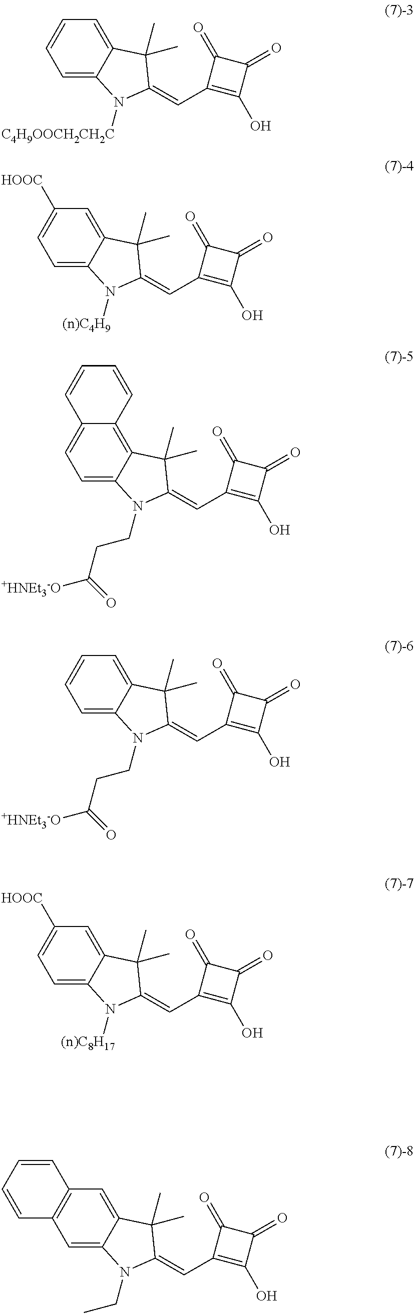

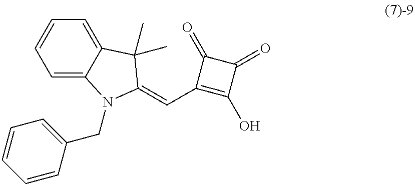 [SMILES: CC1(C)/C(=C\c2c(O)c(=O)c2=O)N(Cc2ccccc2)c2ccccc21]

Next, the compound represented by Formulas (8) and (9) will be explained. The above-mentioned compound represented by Formula (8) is generally called a “squarylium compound”.

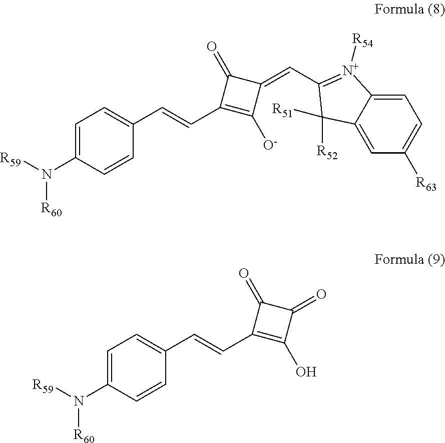

Each of R₅₁, R₅₂, R₅₃, and R₅₄ in Formula (8) and Each of R₅₇ and R₅₈ in both Formulas (8) and (9) represents independently a hydrogen atom, a halogen atom, or a substituted or unsubstituted alkyl group, alkenyl group, alkynyl group, aryl group, or heterocycle group, and an acidic group is included, on R₅₃. Each of R₅₉ and R₆₀ in both Formulas (8) and (9) represents independently a substituted or unsubstituted alkyl group, alkenyl group, alkynyl group, aryl group, or heterocycle group, and R₅₉ and R₆₀ may link to each other so as to form a ring-shape structure.

Hereafter, specific examples of the compounds represented by Formula (8) and (9) which can be used in the present invention are shown. However, the compounds which can be used in the present invention should not be limited to the following examples.

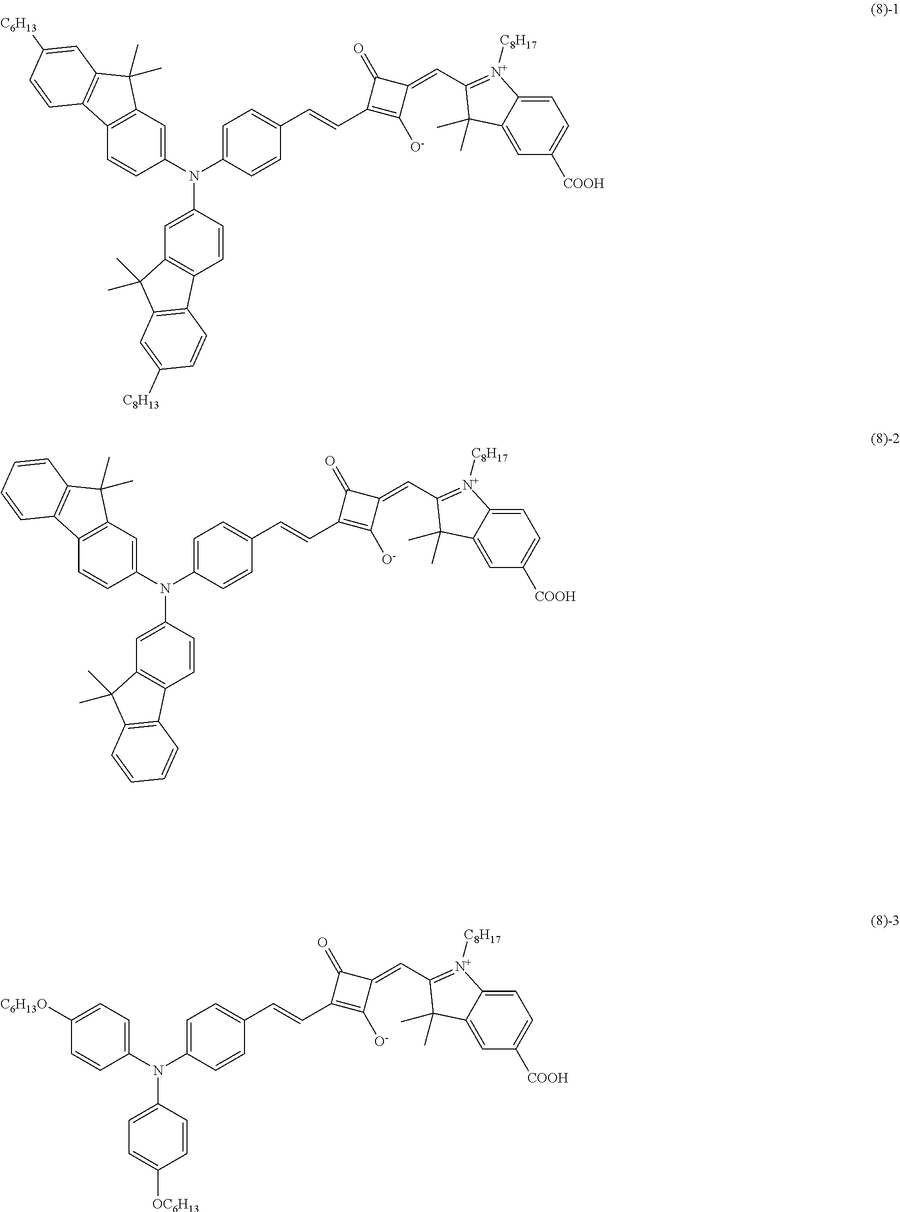

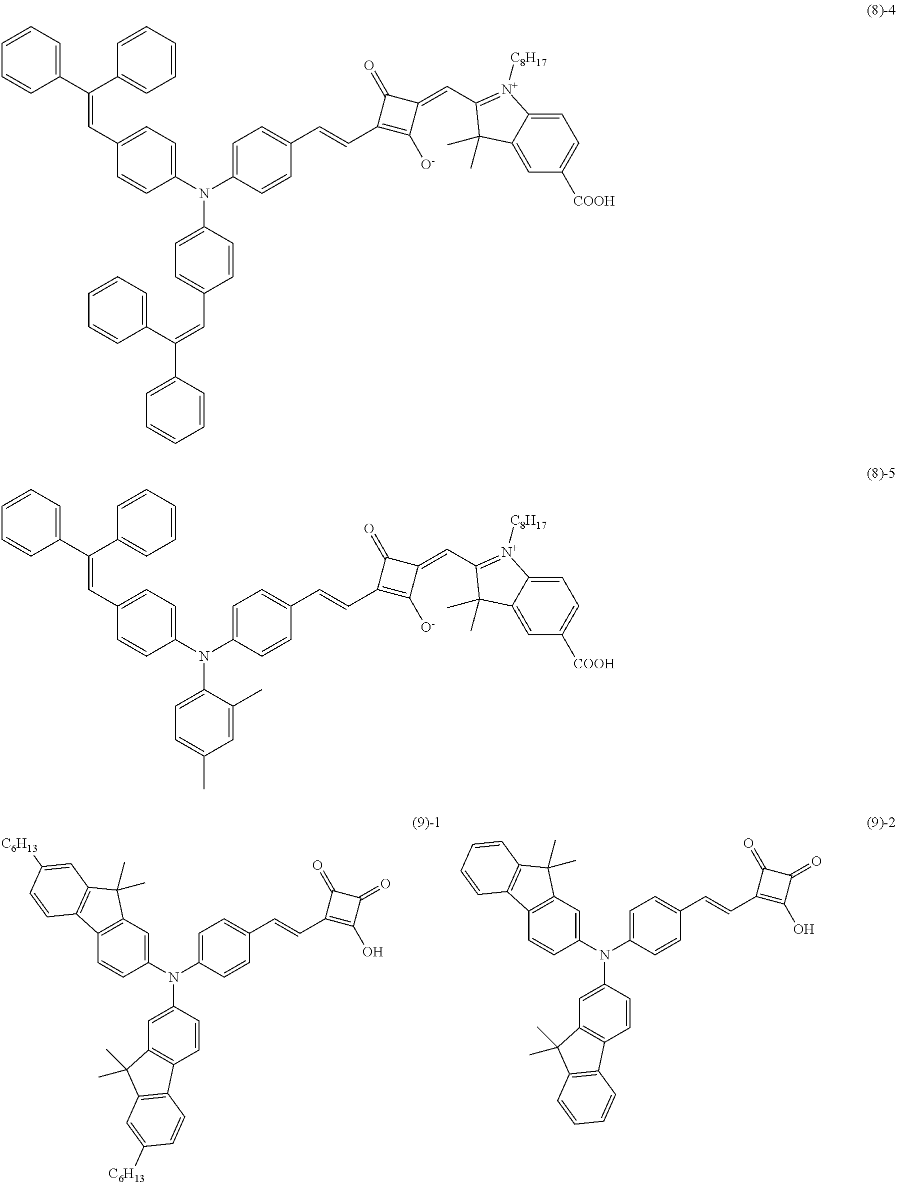

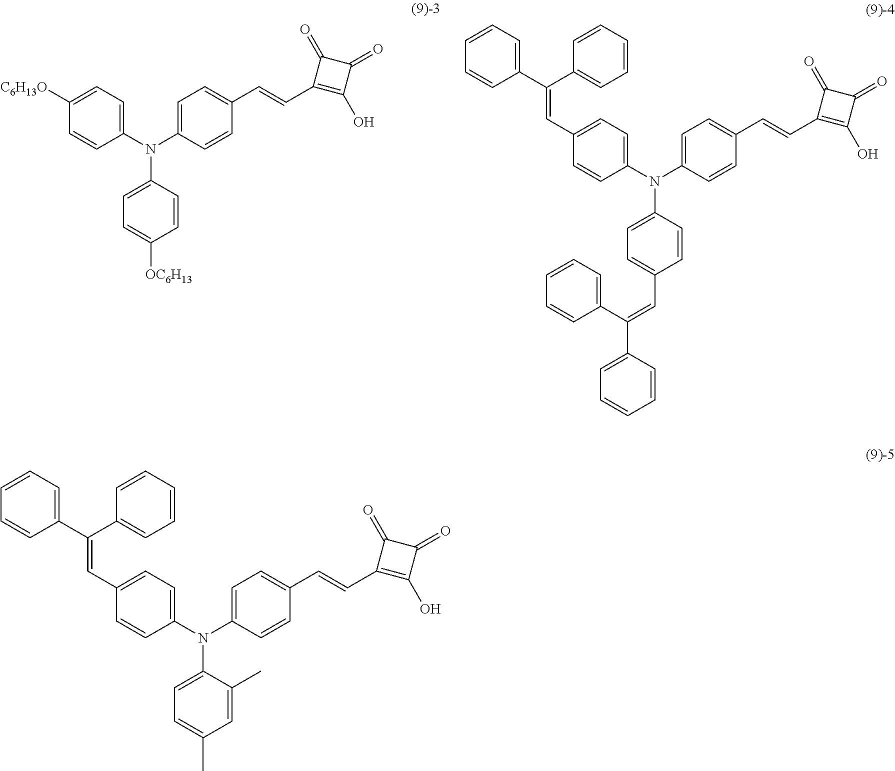

Next, the semiconductor which constitutes a photoelectric conversion layer will be explained. The photoelectric inversion layer which constitutes the photoelectric conversion element according to the present invention has a structure in which the compound represented by Formula (2) and used as the sensitizing dye is made to adsorb onto the semiconductor. The adsorption formed between the sensitizing dye and the semiconductor is performed, for example, a physical action such as intermolecular attractive force, electrostatic attraction, and the like, or chemical bonds, such as a covalent bond, a coordinate bond.

As the semiconductor 5 used, in the photoelectric conversion layer 6, a single body such as silicon or germanium, a compound having an atom belonging to group 3 (group 3A) to group 5 (group 5A) and group 13 (group 38) to group 15 (group 5B) in the periodic table of the elements, a metal chalcogenide, or a metal nitride is usable. Herein, the metal chalcogenide refers to a compound formed from an atom belonging to group 16 (group 6B) of the periodic table of the elements such as an oxygen atom or sulfur atom referred to as a chalcogen element and a metallic atom, falling under the category of a metal oxide, a metal sulfide, a metal selenide, and a metal telluride.

Specific examples of the metal chalcogenide include, for example, the following compounds: (1) Metal oxides, TiO, TiO₂, Ti₂O₃, SnO₂, Fe₂O₃, WO₃, ZnO, and Nb₂O₅; (2) Metal sulfides, CdS, ZnS, PbS, Bi₂S₃, and CuInS₂; (3) Metal selenides and metal tellurides, CdSe, PbSe, CuInSe₂, and CdTe. Of the above metal chalcogenides, TiO₂, SnO₂, Fe₂O₃, WO₃, ZnO, Nb₂O₅, CdS, and PbSe are preferably used. Of these, TiO₂ and Nb₂O₅ are more preferable and TiO₂ is specifically preferable. Titanium dioxide is specifically preferable because of having excellent electron transportability as well as enhanced sensitivity to light, resulting in direct generation of electrons via reception of light by titanium dioxide itself which makes it possible to expect enhanced photoelectric conversion efficiency. Further, since titanium dioxide has a stable crystal structure, degradation over time tends not to occur even with light irradiation under a severe ambience, and thereby a predetermined performance can be stably expressed over a long term.

The crystal structure of titanium dioxide includes an anatase type and a rutile type. In semiconductor materials for dye-sensitized solar cells, usable is any of a material mainly having an anatase type crystal structure, a material mainly having a rutile type crystal structure, and a material mainly having a mixture of both types. Of these, titanium dioxide having an anatase type crystal structure realizes efficient election transportability. Further, in the case of mixed use of an anatase type and a rutile type, the mixture ratio of the anatase type and the rutile type is not specifically limited and the ratio may fall within the range of the anatase type: the rutile type=95:5 to 5:95 and the ratio of 80:30 to 20:80 is preferable.

As metal nitrides usable for semiconductors, for example, Ti₃N₄ is representative, and further metal phosphides such as GaP and InP and compounds such as GaAs are employable as semiconductors.

As the semiconductor used for the photoelectric conversion layer 6, any of the above compounds is usable alone and also a plurality thereof are usable in combination. Specific examples in combination of a plurality of these compounds include, for example, a form in which TiO₂ is mixed with Ti₃N₄ at 20% by mass and a complex of ZnO and SnO₂ disclosed in J. Chem. Soc., Chem. Commun, 15 (1999). When a metal oxide or a metal sulfide is combined with a compound other that the above oxide or sulfide, the content of the compound is preferably at most 30% by mass.

As the semiconductor used for the photoelectric conversion layer 6, those surface-treated with an organic base are usable. In the surface treatment of the semiconductor, a method to immerse a semiconductor in a liquid tank containing an organic base is mainly employed, and when the organic base is liquid, it is used as is, and in the case of solid, a solution in which the solid is dissolved in an organic solvent is used. The organic base used in surface treatment includes, for example, diarylamine, triarylamine, pyridine, 4-tert-butylpyridine, polyvinylpyridine, quinoline, and amidine. Of these, pyridine, 4-t-butylpyridine, and polyvinylpyridine are preferable.

From the viewpoint of facilitation of irregular reflection and diffusion of collided light to enhance photoelectric conversion efficiency, the surface of a semiconductor material preferably has a plurality of fine holes (pores). Titanium dioxide described above is expected to exhibit enhanced photoelectric conversion efficiency because of having pores on the surface. Pores of a semiconductor material can be defined, for example, by the ratio of the area of holes occupied per area of the semiconductor particle surface referred to as porosity. Namely, a semiconductor material having appropriate porosity facilitates irregular reflection and diffusion of light, and also the adsorption area of a sensitizing dye adsorbed to the outer surface of the semiconductor material and to the inner surface of pores increases with an increase in the surface area due to the pores. Thereby, the photoelectric inversion efficiency is further enhanced. The porosity of the semiconductor is not specifically limited, but for example, in the case of titanium dioxide, the porosity is preferably 5% to 90%, more preferably 15% to 80%, specifically preferably 25% to 70%.

The average particle diameter of the semiconductor 5 is not specifically limited. However, commonly, the diameter is preferably 1 nm to 1 μm, more preferably 5 nm to 50 nm. When the average particle diameter of the semiconductor material is allowed to fall within the range, the uniformity of the semiconductor material is easy to increase in formation of a sol liquid and then due to the enhanced uniformity, the specific surface area of the semiconductor material becomes uniform. Thereby, a sensitizing dye is adsorbed on each semiconductor material at an equal level to contribute to enhancing power generation efficiency.

Next, on top of the first electrode, a photoelectric conversion layer 6 is formed using a semiconductor material. The photoelectric conversion layer 6 can be formed for example, in the case of a particle-shaped, semiconductor, by coating or spraying the semiconductor onto a substrate on which a first electrode has been formed. Further, in the case of a film semiconductor, formation can be carried out by bonding the semiconductor to a substrate on which a first electrode has been formed. As one of the preferred aspects in formation of the photoelectric conversion layer 6, a forming method in which semiconductor particles are fired is cited. When semiconductor particles are fired to form a photoelectric conversion layer 6, sensitizing treatment for the semiconductor is preferably carried out after firing, especially, before water is adsorbed to the semiconductor after firing. A method to form a photoelectric conversion layer 6 by firing semiconductor particles is described below.

The method for forming a photoelectric conversion layer 6 by firing semiconductor particles is performed, for example, via the following steps: (1) Preparation of a coating liquid which contains semiconductor particles; (2) Coating of the coating liquid containing semiconductor particles and firing treatment; and (3) Adsorption treatment of a sensitizing dye to a semiconductor. Hereafter, these are described.

(1) Preparation of a Coating Liquid Containing Semiconductor Particles

This step is one in which semiconductor particles are placed into a well-known solvent and dispersed to prepare a coating liquid. The concentration of semiconductor particles in the coating liquid is, for example, preferably 0.1% by mass to 70% by mass, more preferably 0.1% by mass to 30% by mass. The semiconductor particles preferably have relatively small particle diameter, for example, those having an average primary particle diameter of 1 nm to 5000 nm are preferably used, more preferably 2 nm to 100 nm.

The solvent for dispersion of semiconductor particles is not specifically limited as long as the semiconductor particles can be dispersed without aggregation, including water, an organic solvent and a liquid mixture of water aid an organic solvent. Specific examples of the organic solvent include, for example, alcohols such as methanol or ethanol, ketones such as acetone, methyl ethyl ketone, or acetylacetone, and hydrocarbons such as n-hexane or cyclohexane.

In the coating liquid, a well-known surfactant, or viscosity adjuster can be added as appropriate. Specific examples of the viscosity adjuster include polyols such as polyethylene glycol as representative ones

(2) Coating of the Coating Liquid Containing Semiconductor Particles and Filing Treatment

In this step, the coating liquid having been formed by dispersing semiconductor particles in a solvent is coated on the substrate on which a first electrode is formed, followed by drying to form a semiconductor particle layer. Then, firing treatment is carried out in air or under nitrogen gas atmosphere to fix a semiconductor 5 on the substrate in a layered manner. The semiconductor 5 having been formed in a layered manner is also referred to as a semiconductor layer. In a semiconductor particle layer formed on a substrate via coating, the bonding force to the substrate and the bonding force among semiconductor particles are weak. However, firing treatment enhances the bonding force to the substrate or the bonding force among semiconductor panicles to form a strong layer having durability. The thickness of a semiconductor layer formed by firing treatment is preferably at least 10 nm, more preferably 500 nm to 30 μm.

The semiconductor layer forms a strong porous structure via firing treatment Then, a positive hole transport material is allowed to be present in voids constituting the porous structure to enhance photoelectric conversion efficiency. In this manner, a semiconductor layer having a porous structure has large actual surface area compared with apparent surface area, which is highly effective for enhancement of performances including photoelectric conversion efficiency. The porosity of the semiconductor layer is, for example, preferably 1% by volume to 90% by volume, more preferably 10% by volume to 80% by volume, specifically preferably 20% by volume to 70% by volume. Voids formed to the semiconductor layer have penetrating properties in the layer thickness direction and porosity can be determined using a common method. A representative determination member for porosity includes, for example, commercially available mercury porosimeter “Shimadzu PORESIZER 9220 (produced by Shimadzu Corp.).”

From the viewpoint of forming a porous structure having porosity, the temperature of firing treatment is preferably in the temperature range of less than 1000° C., more preferably 200° C. to 800° C., specifically preferably 300° C. to 800° C. When a semiconductor layer fired on a resin substrate is formed, it is unnecessary to forcedly carry out filing treatment at 200° C. or more. Instead, pressurization treatment can realize fixing among semiconductor particles or fixing to the substrate. Further, microwaves are usable to heat only the semiconductor without heating the substrate for firing treatment.

To efficiently inject electrons into a semiconductor layer using a sensitizing dye, a semiconductor layer formed via firing treatment can be plated using a chemical or electrochemical method.

(3) Adsorption Treatment of a Sensitizing Dye to a Semiconductor 5

In the sensitizing treatment for the semiconductor 5, a substrate provided with a photoelectric conversion layer (semiconductor layer) in which a semiconductor is formed in a layered manner is immersed in a solution in which a sensitizing dye is dissolved. The total carried amount of the sensitizing dye 4 in the photoelectric conversion layer 6 is preferably 0.01 to 100 mmol/m², more preferably 0.1 to 50 mmol/m², specifically preferably 0.5 to 20 mmol/m².

The sensitizing treatment can employ either of a method to use a single type of sensitizing dye and a method to use plural types of sensitizing dye. For example, when a photoelectric conversion element is used for a solar cell, to ensure a wider photoelectrically convertible wavelength range, a method in which a plurality of dyes differing in absorption wavelength are combined is preferably employed.

A solvent to dissolve a sensitizing dye is one to dissolve a sensitizing dye and on the other hand, to dissolve a semiconductor for reaction and an organic solvent is employable therefor. Such an organic solvent includes, for example, a nitrile solvent, an alcohol solvent, a ketone solvent, an ether solvent, and a halogen solvent. These solvents can be used alone or in combination of a plurality of types, including (a) the nitrile solvent acetonitrile, (b) the alcohol solvent: methanol, ethanol and n-propanol, (c) the ketone solvent: acetone and methyl ethyl ketone, (d) the ether solvent: diethyl ether, diisopropyl ether, tetrahydrofuran, and 1,4-dioxane, and (e) the halogen solvent: methylene chloride and 1,1,2-trichloroethane.

Of the above solvents, acetonitrile, an acetonitrile/methanol mixed solvent, methanol, ethanol, acetone, methyl ethyl ketone, tetrahydrofuran, and methylene chloride are preferable.

To allow a solution to deeply penetrate a semiconductor layer for adequate advance of adsorption to a semiconductor to sufficiently sensitize the semiconductor, the duration of immersion in a solution containing a sensitizing dye is, for example, preferably 3 hours to 48 hours, more preferably 4 hours to 24 hours at 25° C. Further, the solution can be heated if a contained sensitizing dye is not decomposed, and the solution temperature can be set, for example, at 25° C. to 80° C.

Via the following steps, a photoelectric conversion layer can be produced.

The dye-sensitized solar cell shown in FIG. 1 will be further described.

A substrate 1 is provided on the light incident direction side of the photoelectric conversion element 10 and formed of a material, exhibiting excellent optical transparency including glass such as soda glass or a transparent resin material from the viewpoint of providing the dye-sensitized solar cell with strength and of ensuring excellent photoelectric conversion efficiency. In the present invention, in the vicinity of the substrate 1, a UV absorbing layer 11 to absorb light of a wavelength of at most 380 nm is preferably provided so that light having passed through the UV absorbing layer 11 provided in the vicinity of the substrate 1 reaches the photoelectric conversion layer 6.

The optical transmittance of the substrate 1 is preferably at least 10%, more preferably at least 50%, specifically preferably 80% to 100%. Herein, the optical transmittance refers to a total light beam, transmittance in the visible light wavelength region determined using a method conforming to the test method of the total light beam transmittance of a transparent plastic material based on JIS K 7361-1 (corresponding to ISO 13468-1).

A substrate 1 usable in the present invention is appropriately selectable from well-known substrates, including a transparent inorganic material such as quartz or glass and the following well-known transparent resin materials.

Specific examples of the transparent resin materials include, for example, polyethylene terephthalate (PET), polyethylene naphthalate (PEN), polyphenylene sulfide (PPS), polyimide (PI), polycarbonate (PC), polystyrene (PS), polypropylene (PP), polybutylene terephthalate (PBT), trimethylene terephthalate, polybutylene naphthalate, polyamideimide, cycloolefin polymers, and styrene-butadiene copolymers. Of the above transparent resin materials, polyethylene terephthalate (PET), polyethylene naphthalate (PEN), polyphenylene sulfide (FPS), and polyimide (PI) are available on the market as those having flexibility, being preferable to produce a flexible dye-sensitized solar cell.

The thickness of the substrate 1 can be appropriately set based on the material and the intended use, and in the case of being constructed of a hard material like a transparent inorganic material such as glass, its average thickness is preferably 0.1 mm to 1.5 mm, more preferably 0.8 mm to 1.2 mm. Further, also in the case of use of a transparent resin material, the same average thickness as for the transparent inorganic material may be set However, when a flexible transparent resin material is used, its average thickness is preferably 0.5 μm to 150 μm, more preferably 10 μm to 75 μm.

Then, the first electrode 2 is arranged between the substrate 1 and the photoelectric conversion layer 6, and to efficiently feed light to the photoelectric conversion layer 6, those preferably having a light arrival rate of at least 80%, more preferably at least 90%, are used.

The first electrode 2 is formed of a metal material or a metal oxide. Specific examples of the metal material include, for example, platinum, gold, silver, copper, and aluminum. Silver is preferable since those worked into a shape easily exhibiting optical transparency are being supplied in large amounts. For example, a large number of grid patterns firms having openings and films in which fine particles or nanowires are dispersed are being supplied. Further, specific examples of the metal oxide include, for example, SnO₂, ZnO, CdO, a CTO-based oxide, In₂O₃, and CdIn₂O₄O. Those in which one type or at least 2 types of atom selected from Sn, Sb, F, and Al are doped in any of the metal oxides are preferably used. Of these, conductive metal oxides such as those referred to as ITO in which Sn is doped in In₂O₃, those in which Sb is doped in SnO₂, and those referred to as FTO in which F is doped in SnO₂ are preferable. From the viewpoint of heat resistance, FTO is specifically preferable. Incidentally, the above CTO-based metal oxide includes, for example, CdSnO₃, Cd₂SnO₄, and CdSnO₄.

Further, the first electrode 1 may be provided on the substrate 1. Those in which a first electrode 2 is provided on a substrate are referred to as conductive substrates. The thickness of such a conductive substrate is preferably set at 0.1 mm to 5 mm. The surface resistance of the conductive substrate is preferably at most 50Ω/cm², more preferably at most 10Ω/cm².

Next, the second electrode 8 will be described. The second electrode 8 is formed, in a layered (flat plate-like) manner, adjacent to the positive hole transport layer 7 and the average thickness thereof is appropriately set based on the material and the intended use, being not specifically limited, The second electrode 8 can be formed using a well-known conductive material or semi-conductive material. The conductive material includes, for example, ionically conductive materials, metals such as aluminum, nickel, cobalt, platinum, silver, gold, copper, molybdenum, titanium, and tantalum, alloys containing these, and carbon materials such as graphite. Further, the semi-conductive material includes, for example, p-type semiconductor materials such as triphenyl diamine (monomer and polymer), polyaniline, polypyrrole, polythiophene, and phthalocyanine compounds (e.g., copper phthalocyanine), or derivatives thereof. These conductive materials and semi-conductive materials may be used alone or in combination of at least 2 types thereof to form a second electrode 8.

The photoelectric conversion element 10 shown in FIG. 1 has a barrier layer 3 between the first electrode 2 and the photoelectric conversion layer 5, and the barrier layer 3 prevents short-circuit occurrence. When a barrier layer 3 is provided, the thickness thereof is, for example, about 0.01 μm to 10 μm. The barrier layer is formal using a metal oxide such as titanium oxide or zinc oxide.

One example of the production method of the dye-sensitized solar cell according to tie present invention will now be described. The dye-sensitized solar cell according to the present invention can be produced, for example, based on the following steps [1] to [6]. The production method of the dye-sensitized solar cell according to the present invention Is not limited to those in which production is carried out based on the following steps. Production can be carried out based on other well-known methods. Incidentally, in the present invention, a dye-sensitized solar cell is preferably produced via heating treatment to be described in step [6].

[1] Formation of a First Electrode

A substrate made of glass having optical transparency or of a resin having excellent heat resistance, in which both are uniform in thickness, is prepared and then a first electrode is formed on the substrate using a well-known film forming apparatus such as a pulse laser vapor deposition method. Herein, organic materials having excellent heat resistance used for the substrate include, for example, a polyethylene naphthalate (PEN) resin and a polyimide resin.

[2] Formation of a Photoelectric Conversion Layer

In the present invention, by the above-mentioned method, it is possible to form the photoelectric conversion layer 6 which employs the compound represented, by a general formula (2) for the sensitizing dye.

[3] Formation of a Positive Hole Transport Layer

In the present invention by the above-mentioned method, it is possible to form the positive hole transport layer 7 which contains a conductive polymer as a positive hole transport substance, and the formed positive hole transport layer 7 is formed so as to permeate the photoelectric conversion layer 6.

[4] Formation of the Second Electrode

The second electrode is formed in the top surface of the positive hole transport layer. For example, the second electrode can be formed from the second electrode material composed of gold and the like by use of well-known methods, such as vacuum deposition method, spattering method, and printing method.

Incidentally, a treatment temperature at the time of performance of the heat-treatment is desirably 60° C. or more and 150° C. or less, and more desirably in a temperature range of 70° C. or more and 120° C. or less.

It is possible to produce the photoelectric conversion element according to the present invention via the above processes.

### EXAMPLES

Hereafter, the present invention will be explained in detail with reference to examples. However, the present invention should not be limited only to the following example. In the following description, the terra “part” represents “parts by weight”.
1. Production of “Photoelectric conversion elements 1 to 43 and Comparative photoelectric conversion elements 1 to 10”
1-1. Production of “Photoelectric Conversion Element 1”

With the following procedures, “Photoelectric conversion element 1” having a configuration shown in FIG. 1 was produced.

### (1) Preparation of a Substrate

A soda glass substrate available on the market having dimensions of 30 mm long×35 mm wide×2.5 mm thick was prepared and then the substrate was immersed in a washing liquid of 85° C. composed of a mixture liquid of sulfuric acid and hydrogen peroxide solution, followed by washing, thereby cleaning the surface.

### (2) Formation of a First Electrode and a Barrier Layer

By use of a film forming apparatus employing a known vapor deposition method, on the soda glass substrate, a first electrode composed of FIX) (fluorine-doped tin oxide) was formed so as to have a length of 30 mm, a width of 35 mm, a thickness of 1 μm, and a sheet resistance of 20Ω/□, Onto the substrate on which the first electrode had been formed, a solution in which 1.2 ml of tetrakis isopropoxy titanium and 0.8 ml of acetylacetone were dissolved in 18 ml of ethanol was dipped, followed by film formation via a spin coating method and heating at 450° C. for 8 minutes, whereby a titanium oxide-made barrier layer with a thickness of 40 nm was formed on the first electrode.

### (3) Formation of a Photoelectric Conversion Layer

Then, on the top surface of the barrier layer and the first electrode composed of the FTO thin film, a photoelectric conversion layer composed of titanium oxide was formed in accordance with the following procedures.

Namely, first, an anatase-type titanium dioxide paste (average primary particle size: 18 nm (microscopic observation average), ethyl cellulose dispersion) was coated on the soda glass substrate on which the barrier layer and the first electrode had been formed, via a screen printing method such that a coated area became 25 mm². After coating, the coated substrate was subjected to firing treatment at 200° C. for 10 minutes and then at 500° C. for 15 minutes, thereby forming a titanium dioxide thin film (photoelectric conversion layer) with a thickness of 2.5 μm. The titanium dioxide thin film had a porous structure with pores.

Next, the compound “A-4” being one of the compounds represented by Formula (2) and the compound “(4)-1” being one of the compounds represented by Formula (4) both serving as sensitizing dye were dissolved in a mixture solvent (acetonitrile: t-butyl alcohol=1:1), and the resulting solution was prepared such that the respective sensitizing dyes became 5×10⁻⁴ mol/liter. The above glass substrate on which the above titanium dioxide was coated and sintered, was immersed in the above solution for 3 hours at a room temperature so as to make the above sensitizing dyes to adsorb, thereby conducting sensitizing treatment. Thus, the photoelectric conversion layer was formed.

### (4) Formation of a Positive Hole Transport Layer

Next, the compound “(1)-1” (in the formula: a bromine atom Br was made to combine at Y) being one of the compounds to form a conductive polymer including a sulfur heterocyclic structure represented by Formula (1) as a main chain structure was added and dissolved in ethanol so as to prepare a first ethanol solution with the concentration of the compound being 1 weight % and a second ethanol solution with the concentration of the compound being 5 weight %. The first ethanol solution with the concentration of 1 weight % was dropped on the photoelectric conversion layer via a dropper, followed by drying with winds, and successively the second ethanol solution with the concentration of 5 weight % was dropped, followed by drying with winds. Thereafter, the resultant glass substrate was placed, in a dryer in which a temperature was set at 60° C., thereby performing thermal polymerization for 8 hours.

Next, the glass substrate having been subjected to the above heating treatment was immersed for 10 minutes in an acetonitrile solution attaining Li [(CF₃SO₂)₂N] in a ratio of 15×10⁻³ mol/liter and t-butyl pyridine in a ratio of 50×10⁻³ mol/liter. Mowed by natural drying. In this way, on the photoelectric conversion layer, formed was a positive hole transport layer containing the conductive polymer including the sulfur heterocyclic structure represented by Formula (1) formed by thermal polymerization of the compound “(1)-1” as a main chain structure.

### (5) Formation of a Second Electrode

Subsequently, on the positive hole transport layer, gold was deposited, with a thickness of 60 nm via a vacuum vapor deposition method, thereby forming a second electrode. With the above-mentioned procedures, “Photoelectric conversion element 1” with a structure shown in FIG. 1 was produced.

### 1-2. Production of “Photoelectric Conversion Elements 2 to 25”

### (1) Production of the “Photoelectric Conversion Elements 2 to 11”

“Photoelectric conversion elements 2 to 11” were produced in the same procedures as those in Production of “Photoelectric conversion element 1” except that the compound “A-4” used as one of the sensitizing dye at the tune of formation of the photoelectric conversion layer was changed to the respective compounds shown in Table 1 mentioned later.

### (2) Production of “Photoelectric Conversion Elements 12 to 25”

“Photoelectric conversion element 12” was produced in the same procedures as those in Production of “Photoelectric conversion element 1” except that the compound “A-4” used as one of the sensitizing dye at the time of formation of the photoelectric conversion layer was changed to the compound “B-8”. Further, “Photoelectric conversion elements 13 to 19” were produced in the same procedures as those in Production of “Photoelectric conversion element 12” except that the compound “(4)-1” used as one of the sensitizing dye at the time of formation of the photoelectric conversion layer was changed to the respective compounds shown in Table 1 mentioned later. Furthermore, “Photoelectric conversion elements 20 to 25” were produced in the same procedures as those in Production of “Photoelectric conversion elements 13, and 15 to 19” except that the compound “B-8” used as one of the sensitizing dye at the time of formation of the photoelectric conversion layer was changed to the compound “C-3”.

### 1-3. Production of “Photoelectric Conversion Elements 26 to 35”

### (1) Production of “Photoelectric Conversion Elements 26, 28, 31, and 32”

“Photoelectric conversion elements 26, 28, 31, and 32” were produced in the same procedures as those in Production of “Photoelectric conversion element 2” except that the compound “(1)-1” used at the time of formation of the conductive polymer represented by Formula (1) was changed to the compound “(1)-2”, the compound “(1)-5” the compound “(1)-28”, and the compound “(1)-29” respectively.

### (2) Production of “Photoelectric Conversion Elements 27, 29, and 34”

“Photoelectric conversion elements 27 and 29” were produced in the same procedures as those in Production of “Photoelectric conversion element 15” except that the impound “(1)-1” used at the time of formation of the conductive polymer represented by Formula (1) was changed to the compound “(1)-3” and the compound “(1)-6” respectively. Further, “Photoelectric conversion element 34” was produced in the same procedures as those in Production of “Photoelectric conversion element 15” except that the first ethanol solution with the concentration of 1 weight % and the second ethanol solution with the concentration of 5 weight % were prepared by use of the compound “(1)-1” and the compound “(1)-3” in combination with the same mol, which were used at the time of formation of the conductive polymer represented by Formula (1).

### (3) Production of “Photoelectric Conversion Elements 30, 33, and 35”

“Photoelectric conversion elements 30 and 33” were produced in the same procedures as those in Production of “Photoelectric conversion element 24” except that the compound “(1)-1” used at the time of formation of the conductive polymer represented by Formula (1) was changed to the compound “(1)-3” and the compound “(1)-22” respectively. Further, “Photoelectric conversion element 35” was produced in the same procedures as those in Production of “Photoelectric conversion element 24” except that the first ethanol solution with the concentration of 1 weight % and the second ethanol solution with the concentration of 5 weight % were prepared, by use of the compound “(1)-1” and the compound “(1)-5” in combination with the same mol, which were used at the time of formation of the conductive polymer represented by Formula (1).

### (4) Production of “Photoelectric Conversion Elements 36 to 38”

“Photoelectric conversion elements 36 to 38” were produced in the same procedures as those in Production of “Photoelectric conversion element 1” except that the anatase type titanium dioxide paste was pasted such that the thickness of the photoelectric conversion layer became 4, 10, and 16 μm respectively.

### 1-4. Production of “Photoelectric Conversion Element 39”

“Photoelectric conversion element 39” was produced in the same procedures as those in Production of “Photoelectric conversion element 31” except mat the positive hole transport layer was formed via a photopolymerization method by use of the compound “bis-EDOT (bis-ethylenedioxythiophene)” with the following structure in place of formation of the positive hole transport layer via the thermal polymerization method by use of the compound “(1)-1”.

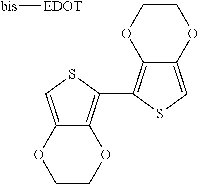

The formation of the positive hole transport layer via the photopolymerization method by use of the compound “bis-EDOT” was conducted in the following procedures. First, the photoelectric conversion layer formed by use of the sensitizing dyes “A-4” and “(4)-3” was immersed into the acetonitrile solution (electric field polymerization solution) containing the following compounds.

| “bis-EDOT” | 1 × 10⁻³ | mol/liter |
|---|---|---|
| Li[(CF₃SO₂)₂N] | 0.1 | mol/liter |

A semiconductor electrode was used as an acting electrode, a platinum wire was used as an opposite electrode, Ag/Ag+ (AgNO3: 0.01 mol) was used as a reference electrode, and a holding voltage was set to −0.16 V. Then, while mediating light from the photoelectric conversion layer side, the above voltage was kept for 30 minutes, whereby a positive hole transport layer was formed on the surface of the photoelectric conversion layer. At this time, the light Irradiating conditions were made as follows. A xenon lamp was used as the light source, the light intensity was set to 22 mW/cm², and the wavelength of 430 nm or less was cut off.

Subsequently, the glass substrate was immersed for 10 minutes in an acetonitrile solution containing Li[(CF₃SO₂)₂N] in a ratio of 15×10⁻³ mol/liter and t-butyl pyridine in a ratio of 50×10⁻³ mol/liter, followed by natural drying, whereby the conductive polymer was produced via the photopolymerization method so as to form the positive hole transport layer. Other procedures were made the same with those in the above, thereby producing “Photoelectric conversion element 39”.

### 1-5. Production of “Comparative Photoelectric Conversion Elements 1 to 10”

### (1) Production of “Comparative Photoelectric Conversion Elements 1 to 6”

“Comparative photoelectric conversion element 1” was produced in the same procedures as those in Production of “Photoelectric conversion element 2” except that the compound “A-4” was not added into the mixture solvent (acetonitrile:t-butyl alcohol=1:1) used for the formation of a photoelectric conversion layer and only the compound “(4)-3” was added and prepared so as to make a concentration to be 1×10⁻³ mol/liter. Similarly, “Comparative photoelectric conversion elements 2 to 6” were produced in the same procedures as those in Production of “Photoelectric conversion elements 6 and 8 to 11” except that the compound “A-4” was not added into the mixture solvent (acetonitrile: t-butyl alcohol=1:1) used for the formation of a photoelectric conversion layer and only the compounds shown in Table 1 were added and prepared so as to make a concentration to be 1×10⁻³ mol/liter

### (2) Production of “Comparative Photoelectric Conversion Element 7”

“Comparative photoelectric conversion element 7” was produced in the same procedures as those in Production of “Comparative photoelectric conversion element 1” except that the compound “G-4” was added into the mixture solvent (acetonitrile:t-butyl alcohol=1:1) used for the formation of a photoelectric conversion layer and prepared so as to make a concentration to be 1×10⁻¹ mol/liter. Here, the compound “G-4” had the following structure and was the compound “CAS Number 207347-46-4 ([RuL₂(NCS)₂]:2TBA L=2,2′-bipyridyl-4,4,-dicarboxylic acid TBA=tetra-n-butylammonium).

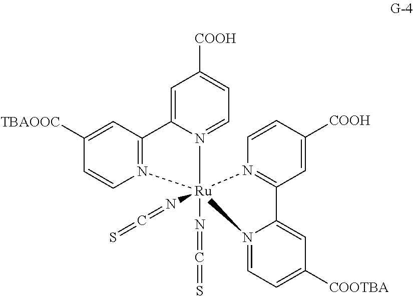

### (3) Production of “Comparative Photoelectric Conversion Elements 8 to 10”

“Comparative photoelectric conversion element 8” was produced in the same procedures as those in Production of “Comparative photoelectric conversion element 1” except that the positive, hole transport layer was formed in the following procedures. That is, “aromatic amine compound S2” shown below was used as a positive hole transport substance, and this compound was dissolved in tetrahydrofuran, thereby preparing a coating liquid for forming a positive hole transport layer. Next, ibis positive hole transport layer-forming coating liquid was coated on the top surface of the photoelectric conversion layer mentioned above via a spin coating method, followed by vacuum drying treatment for 10 minutes, thereby removing the tetrahydrofuran and forming a positive hole transport layer. Here, in the coating of the above positive hole transport layer-forming coating liquid, the rotation in the spin coating was set to 500 rpm.

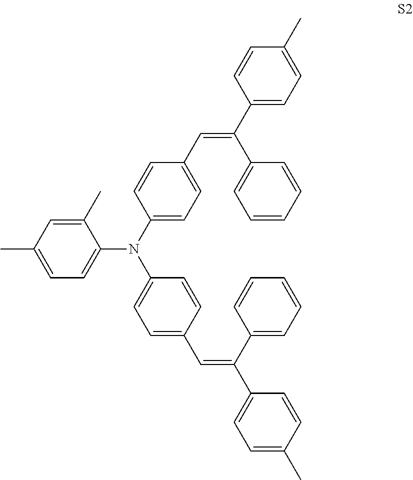

Further, “Comparative photoelectric conversion element 9” was produced in the same procedures as those in Production of “Comparative photoelectric conversion, element 8” except that the “aromatic amine compound S2” used at the time of preparation of the positive hole transport layer-forming coating liquid was changed to the “aromatic amine compound S22” shown below, Furthermore, “Comparative photoelectric conversion element 10” was produced in the same procedures as those in Production of “Comparative photoelectric conversion element 8” except that the “aromatic amine compound S2” used at the time of preparation of the positive hole transport layer-forming coating liquid was changed to the “aromatic amine compound S23” shown below. Here, “compound S23” is called the compound “2,2′,7,7′-tetrakis (N,N-di-p-methoxy phenylamine) 9,9′-spirobifluorene.

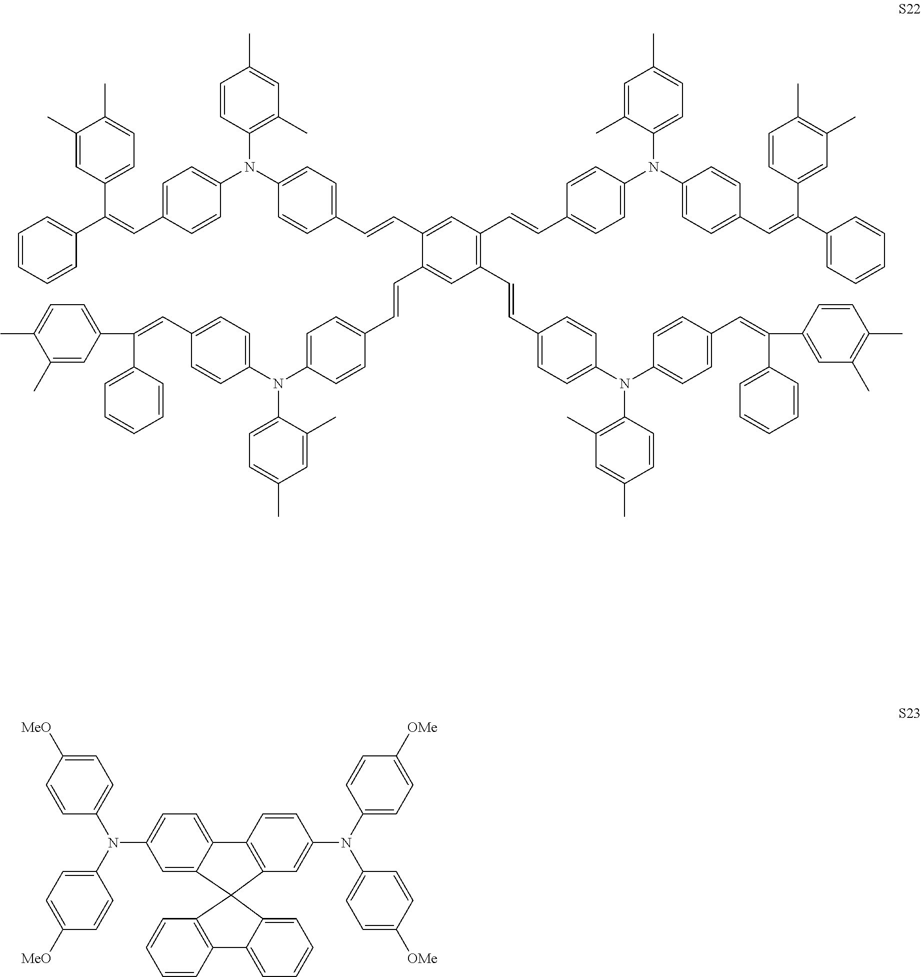

With the above-mentioned procedures, “Photoelectric conversion elements 1 to 39 and Comparative photoelectric conversion elements 1 to 10” were produced. Herein, the compounds for forming the positive hole transport layer and the sensitizing dyes both used at the time of production of the above “Photoelectric conversion elements 1 to 39 and Comparative photoelectric conversion elements 1 to 10” are shown in the following Table 1 and Table 2.

TABLE 1

| Photo- | | | | Photo- |
|---|---|---|---|---|
| electric | Compound | Compound | Compound | electric |
| conversion | to form a | No. of | No. of | conversion |
| element | polymer of | Formula | Formula | layer thick- |
| No. | Formula (1) | (2) or (3) | (4) to (9) | ness (μm) |
| 1 | (1)-1(Y═Br) | A-4 | (4)-1(M═Zn) | 8 |
| 2 | (1)-1(Y═Br) | A-4 | (4)-3(M═Zn) | 8 |
| 3 | (1)-1(Y═Br) | A-4 | (4)-6(M═2H) | 8 |
| 4 | (1)-1(Y═Br) | A-4 | (4)-11(M═Ti) | 8 |
| 5 | (1)-1(Y═Br) | A-4 | (5)-1(M═Zn) | 8 |
| 6 | (1)-1(Y═Br) | A-4 | (5)-6(M═Zn) | 8 |
| 7 | (1)-1(Y═Br) | A-4 | (5)-15(M═Ga) | 8 |
| 8 | (1)-1(Y═Br) | A-4 | (6)-4 | 8 |
| 9 | (1)-1(Y═Br) | A-4 | (7)-4 | 8 |
| 10 | (1)-1(Y═Br) | A-4 | (8)-2 | 8 |
| 11 | (1)-1(Y═Br) | A-4 | (9)-2 | 8 |
| 12 | (1)-1(Y═Br) | B-8 | (4)-1(M═Zn) | 8 |
| 13 | (1)-1(Y═Br) | B-8 | (4)-3(M═Zn) | 8 |
| 14 | (1)-1(Y═Br) | B-8 | (5)-1(M═Zn) | 8 |
| 15 | (1)-1(Y═Br) | B-8 | (5)-6(M═Zn) | 8 |
| 16 | (1)-1(Y═Br) | B-8 | (6)-4 | 8 |
| 17 | (1)-1(Y═Br) | B-8 | (7)-4 | 8 |
| 18 | (1)-1(Y═Br) | B-8 | (8)-2 | 8 |
| 19 | (1)-1(Y═Br) | B-8 | (9)-2 | 8 |
| 20 | (1)-1(Y═Br) | C-3 | (4)-3(M═Zn) | 8 |
| 21 | (1)-1(Y═Br) | C-3 | (5)-6(M═Zn) | 8 |
| 22 | (1)-1(Y═Br) | C-3 | (6)-4 | 8 |
| 23 | (1)-1(Y═Br) | C-3 | (7)-4 | 8 |
| 24 | (1)-1(Y═Br) | C-3 | (8)-2 | 8 |
| 25 | (1)-1(Y═Br) | C-3 | (9)-2 | 8 |
| 26 | (1)-2(Y═Br) | A-4 | (4)-3(M═Zn) | 8 |
| 27 | (1)-3(Y═Br) | B-8 | (5)-6(M═Zn) | 8 |
| 28 | (1)-5(Y═Br) | A-4 | (4)-3(M═Zn) | 8 |
| 29 | (1)-6(Y═Br) | B-8 | (5)-6(M═Zn) | 8 |
| 30 | (1)-3(Y═Br) | C-3 | (8)-2 | 8 |
| 31 | (1)-28(Y═Br) | A-4 | (4)-3(M═Zn) | 8 |
| 32 | (1)-29(Y═Br) | A-4 | (4)-3(M═Zn) | 8 |
| 33 | (1)-22(Y═Br) | C-3 | (8)-2 | 8 |
| 34 | (1)-1/ | B-8 | (5)-6(M═Zn) | 8 |
| | (1)-2(Y═Br) | | | |
| 35 | (1)-1/ | C-3 | (4)-3(M═Zn) | 8 |
| | (1)-5(Y═Br) | | | |
| 36 | (1)-1(Y═Br) | A-4 | (4)-3(M═Zn) | 4 |

In Photoelectric conversion element Nos. 34 and 35, each compound was used in an equivalent mole (1/1)

TABLE 2

| Photo- | | | | Photo- |
|---|---|---|---|---|
| electric | Compound | Compound | Compound | electric |
| conversion | to form a | No. of | No. of | conversion |
| element | polymer of | Formula | Formula | layer thick- |
| No. | Formula (1) | (2) or (3) | (4) to (9) | ness (μm) |
| 37 | (1)-1(Y═Br) | A-4 | (4)-3(M═Zn) | 10 |
| 38 | (1)-1(Y═Br) | A-4 | (4)-3(M═Zn) | 16 |
| 39 | bis-EDOT | A-4 | (4)-3(M═Zn) | 8 |
| 40 | (1)-1(Y═Br) | A-4 | (4)-3(M═Zn) | 8 |
| 41 | (1)-1(Y═Br) | A-4 | (4)-3(M═Zn) | 8 |
| 42 | (1)-1(Y═Br) | A-4 | (4)-3(M═Zn) | 8 |
| 43 | (1)-1(Y═Br) | A-4 | (4)-3(M═Zn) | 8 |
| 44 | (1)-1(Y═Br) | A-4 | (4)-3(M═Zn) | 8 |
| 45 | (1)-1(Y═Br) | A-4 | (4)-1(M═Zn) | 8 |
| 46 | (1)-1(Y═Br) | A-4 | (4)-1(M═Zn) | 8 |
| Compar- | (1)-1(Y═Br) | — | (4)-3(M═Zn) | 8 |
| ative | | | | |
| exam- | | | | |
| ple 1 | | | | |
| Compar- | (1)-1(Y═Br) | — | (5)-6(M═Zn) | 8 |
| ative | | | | |
| exam- | | | | |
| ple 2 | | | | |
| Compar- | (1)-1(Y═Br) | — | (6)-4 | 8 |
| ative | | | | |
| exam- | | | | |
| ple 3 | | | | |
| Compar- | (1)-1(Y═Br) | — | (7)-4 | 8 |
| ative | | | | |
| exam- | | | | |
| ple 4 | | | | |
| Compar- | (1)-1(Y═Br) | — | (8)-2 | 8 |
| ative | | | | |
| exam- | | | | |
| ple 5 | | | | |
| Compar- | (1)-1(Y═Br) | — | (9)-2 | 8 |
| ative | | | | |
| exam- | | | | |
| ple 6 | | | | |
| Compar- | (1)-1(Y═Br) | — | G-4 | 8 |
| ative | | | | |
| exam- | | | | |
| ple 7 | | | | |
| Compar- | S2 | A-4 | (4)-3(M═Zn) | 8 |
| ative | | | | |
| exam- | | | | |
| ple 8 | | | | |
| Compar- | S22 | A-4 | (4)-3(M═Zn) | 8 |
| ative | | | | |
| exam- | | | | |
| ple 9 | | | | |
| Compar- | S23 | A-4 | (4)-3(M═Zn) | 8 |
| ative | | | | |
| exam- | | | | |
| ple 10 | | | | |
| Compar- | (1)-1(Y═Br) | A-4 | — | 8 |
| ative | | | | |
| exam- | | | | |
| ple 11 | | | | |

bis-EDOT (Y═H): ethylenedioxythiophene
1-6. Production of “Photoelectric conversion elements 40 to 43”

“Photoelectric conversion elements 40 to 43” were produced in the same procedures as those In Production of “Photoelectric conversion element 2” except that the treatment temperature in the thermal polymerization at the time of formation of the positive hole transport layer was changed to 45° C., 50° C., 80° C., and 85° C.

### 1-7. Heat-Treatment for “Photoelectric Conversion Elements 1 to 43 and Comparative Photoelectric Conversion Elements 1 to 10”

In this example, in order to evaluate the stability maintaining performance of the photoelectric conversion efficiency, “Photoelectric conversion elements 1 to 43 and Comparative photoelectric conversion elements 1 to 10” produced in the above procedures were subjected to heat treatment by being put in an oven, in which the temperature was heated to 85° C., and kept for 5 hours without management. Here, the heat treatment was conducted In the condition that the inside of the oven was male a dark place.

### 1-8. Production of “Photoelectric Conversion Elements 44 to 46”

“Photoelectric conversion elements 44” was produced in the same procedures as those in Production of “Photoelectric conversion element 2” except that 1×10⁻⁴ mol/liter of the compound “A-4” being one of the compounds represented by Formula (2) and 4×10⁻⁴¹ mol/liter of the compound “(4)-3” being one of the compounds represented by Formula (4) both serving as the sensitizing dye were dissolved in a mixture solvent (acetonitrile:t-butyl alcohol=1:1).

“Photoelectric conversion elements 45” was produced in the same procedures as those in Production of “Photoelectric conversion element 2” except that 4×10⁻⁴ mol/liter of the compound “A-4” being one of the compounds represented by Formula (2) and 1×10⁻⁴ mol/liter of the compound “(4)-3” being one of toe compounds represented by Formula (4) both serving as toe sensitizing dye were dissolved in a mixture solvent (acetonitrile:t-butyl alcohol=1:1).

“Photoelectric conversion elements 46” was produced in the same procedures as those in Production of “Photoelectric conversion element 2” except that 4.7×10⁻⁴ mol/liter of the compound “A-4” being one of the compounds represented by Formula (2) and 0.3×10⁻⁴ mol/liter of toe compound “(4)-3” being one of the compounds represented by Formula (4) both serving as the sensitizing dye were dissolved in a mixture solvent (acetonitrile:t-butyl alcohol=1:1).

### 1-9. Production of “Comparative Photoelectric Conversion Element 11”

“Comparative photoelectric conversion element 11” was produced in the same procedures as those in Production of “Photoelectric conversion element 2” except that toe compound “(4)-3” was not added into toe mixture solvent (acetonitrile:t-butyl alcohol=1:1) used for the formation of a photoelectric conversion layer and only the compound “A-4” was added and prepared so as to make a concentration to be 1×10⁻³ mol/liter.

### 2. Evaluation Test

In this example, the stability maintaining performance of the photoelectric conversion efficiency of each of “Photoelectric conversion elements 1 to 43 and Comparative photoelectric conversion elements 1 to 10” produced in the above procedures were evaluated in the following procedures. First, before perforating heat treatment for 5 hours by the oven in which the temperature was heated to 85° C., the photoelectric conversion efficiency η of each of the “Photoelectric conversion elements” was measures and calculated by the following methods. Next, after perforating the above heat treatment, the photoelectric conversion efficiency η′ of each of the “Photoelectric conversion elements” was measures again and calculated. In this way, the decreasing ratio of the photoelectric conversion efficiency η between before and alter the heating treat-merit at 85° C. for 5 hours was calculated for evaluation.

Here, evaluation by use of “Photoelectric conversion elements 1 to 43” having the constitution specified by the present invention was made into “Examples 1 to 43”, and evaluation by use of “Comparative photoelectric conversion elements 1 to 10” not having the constitution specified by the present invention was made into “Comparative examples 1 to 10.”

Moreover, in Table 3 and Table 4 both mentioned later, open voltage, short circuit current density, shape coefficient, and photoelectric conversion efficiency each before the heat treatment at 85° C. for 5 hours, photoelectric conversion efficiency after the heat treatment and photoelectric conversion efficiency before and after the heat treatment are shown for each of the “Photoelectric conversion elements”.

The photoelectric conversion efficiencies η and η′ of each of the “Photoelectric conversion elements” are measured and calculated via the following procedures. Namely, pseudo-sunlight of an irradiation intensity of 100 mW/cm2 formed using commercially available solar simulator “WXS-85-H (produced by Wacom Electric Co., Ltd.)” is irradiated to each of the “Photoelectric conversion elements” at room temperature (at 20° C.). The pseudo-sunlight is formed by allowing xenon lamp tight to pass through an AM filter (AM 1.5) using the solar simulator.

Then, the current-voltage characteristics of each of the “Photoelectric conversion elements” during irradiation of the pseudo-sunlight are measured using a commercially available I-V tester to calculate form factor FF from short-circuit current density Jsc and open voltage Voc, as well as a current-voltage characteristic graph. These values are substituted into a calculation expression described later to calculate the photoelectric conversion efficiency η.

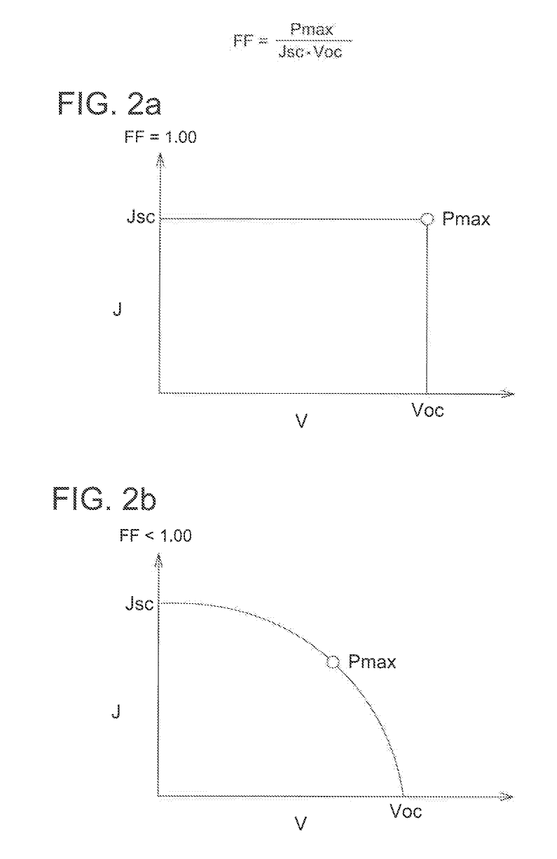

The open voltage Voc refers to a voltage value when a voltage is loaded to a dye-sensitized solar cell and then the state where no current flows is created. The short-circuit current density Jsc refers to the value of current per cm² flowing in the state where no voltage is loaded to the dye-sensitized solar cell. Further, the form factor FF is a value represented by the numerical value of the locus shown in a current-voltage characteristic graph obtained when photoelectric conversion efficiency is measured to be described below, being a value obtained by dividing irradiation intensity Po by the product of short-circuit current density Jsc and open voltage Voc. FIG. 2a and FIG. 2b show the calculation expression of form factor FF and examples of the locus of a current-voltage characteristic graph when form factor FF is 1.00 and less than 1.00.

Further, photoelectric conversion efficiency η is calculated by the following expression. Namely, when the irradiation intensity and the short-circuit current density of each dye-sensitized solar cell are designated as Po (100 mW/cm²) and Jsc (mA/cm²), respectively, and then the open voltage and the form factor are designated as Voc (V) and FF, respectively, the photoelectric conversion efficiency η is calculated by the following expression.

η(%)=[(Jsc×Voc×FF)/Po]×100

The photoelectric conversion efficiency η′ after heating treatment is also calculated by the above expression.

Incidentally, in this evaluation, pseudo-sunlight of an irradiation intensity Po of 100 mW/cm² is irradiated using the above solar simulator.

Further, the ratio (the ratio between before and after beating) of the photoelectric conversion efficiency between before and after the heat treatment shown in Table 3 and Table 4 is defined by the equation:

ratio between before and after heating=photoelectric conversion efficiency after heat treatment/photoelectric conversion efficiency before heat treatment

In Table 3 and Table 4, open, voltage, short circuit current density, shape coefficient, and photoelectric conversion efficiency each before the heat treatment at 85° C. for 5 hours, photoelectric conversion efficiency after the heat treatment, and photoelectric conversion efficiency before and after the heat treatment are shown for each of the “Photoelectric conversion elements”, and the value of the ratio of the photoelectric conversion efficiency being 0.60 or more was deemed as acceptable.

TABLE 3

| | | | | | Photoelectric conversion | | |
|---|---|---|---|---|---|---|---|
| | | | Short | | efficiency (%) | | |
| | | | circuit | | | | Ratio |
| | Photoelectric | Open | current | | Before | | between |
| | conversion | voltage | density | Shape | heat | After heat | before |
| | element No. | (mV) | (mA/cm²) | coefficient | treatment | treatment | and after |
| Example 1 | 1 | 825 | 4.26 | 0.58 | 2.04 | 1.78 | 0.87 |
| Example 2 | 2 | 814 | 4.22 | 0.59 | 2.03 | 1.75 | 0.86 |
| Example 3 | 3 | 840 | 4.18 | 0.55 | 1.93 | 1.49 | 0.77 |
| Example 4 | 4 | 830 | 4.02 | 0.57 | 1.90 | 1.43 | 0.75 |
| Example 5 | 5 | 819 | 4.25 | 0.59 | 2.05 | 1.74 | 0.85 |
| Example 6 | 6 | 828 | 4.45 | 0.56 | 2.06 | 1.71 | 0.83 |
| Example 7 | 7 | 830 | 4.18 | 0.55 | 1.91 | 1.45 | 0.76 |
| Example 8 | 8 | 833 | 4.23 | 0.55 | 1.94 | 1.69 | 0.87 |
| Example 9 | 9 | 819 | 4.00 | 0.58 | 1.90 | 1.43 | 0.75 |
| Example 10 | 10 | 823 | 4.20 | 0.57 | 1.97 | 1.67 | 0.85 |
| Example 11 | 11 | 833 | 4.03 | 0.56 | 1.88 | 1.45 | 0.77 |
| Example 12 | 12 | 823 | 4.22 | 0.59 | 2.05 | 1.76 | 0.86 |
| Example 13 | 13 | 823 | 4.23 | 0.58 | 2.02 | 1.72 | 0.85 |
| Example 14 | 14 | 815 | 4.22 | 0.59 | 2.03 | 1.68 | 0.83 |
| Example 15 | 15 | 828 | 4.40 | 0.56 | 2.04 | 1.71 | 0.84 |
| Example 16 | 16 | 830 | 4.23 | 0.55 | 1.93 | 1.64 | 0.85 |
| Example 17 | 17 | 821 | 3.95 | 0.58 | 1.88 | 1.43 | 0.76 |
| Example 18 | 18 | 822 | 4.16 | 0.57 | 1.95 | 1.64 | 0.84 |
| Example 19 | 19 | 827 | 4.04 | 0.56 | 1.87 | 1.40 | 0.75 |
| Example 20 | 20 | 817 | 4.19 | 0.59 | 2.02 | 1.72 | 0.85 |
| Example 21 | 21 | 824 | 4.42 | 0.56 | 2.04 | 1.71 | 0.84 |
| Example 22 | 22 | 831 | 4.22 | 0.55 | 1.93 | 1.60 | 0.85 |
| Example 23 | 23 | 812 | 3.99 | 0.58 | 1.88 | 1.43 | 0.76 |
| Example 24 | 24 | 823 | 4.18 | 0.57 | 1.96 | 1.65 | 0.84 |
| Example 25 | 25 | 824 | 4.01 | 0.56 | 1.85 | 1.41 | 0.76 |
| Example 26 | 26 | 817 | 4.13 | 0.59 | 1.99 | 1.73 | 0.87 |
| Example 27 | 27 | 831 | 4.40 | 0.56 | 2.05 | 1.72 | 0.84 |
| Example 28 | 28 | 815 | 4.16 | 0.59 | 2.00 | 1.72 | 0.86 |
| Example 29 | 29 | 835 | 4.28 | 0.56 | 2.07 | 1.66 | 0.80 |
| Example 30 | 30 | 820 | 4.09 | 0.57 | 1.91 | 1.53 | 0.85 |
| Example 31 | 31 | 821 | 4.23 | 0.59 | 2.05 | 1.80 | 0.88 |
| Example 32 | 32 | 825 | 4.23 | 0.59 | 2.06 | 1.87 | 0.91 |
| Example 33 | 33 | 820 | 4.17 | 0.57 | 1.95 | 1.68 | 0.86 |
| Example 34 | 34 | 836 | 4.38 | 0.56 | 2.05 | 1.76 | 0.86 |
| Example 35 | 35 | 820 | 4.15 | 0.59 | 2.01 | 1.73 | 0.86 |
| Example 36 | 36 | 818 | 3.73 | 0.59 | 1.80 | 1.39 | 0.77 |

TABLE 4

| | | | | | Photoelectric conversion | | |
|---|---|---|---|---|---|---|---|
| | | | Short | | efficiency (%) | | |
| | | | circuit | | | | Ratio |
| | Photoelectric | Open | current | | Before | | between |
| | conversion | voltage | density | Shape | heat | After heat | before |
| | element No. | (mV) | (mA/cm²) | coefficient | treatment | treatment | and after |
| Example 37 | 37 | 815 | 4.20 | 0.59 | 2.02 | 1.70 | 0.84 |
| Example 38 | 38 | 816 | 3.80 | 0.59 | 1.83 | 1.32 | 0.72 |
| Example 39 | 39 | 750 | 4.02 | 0.61 | 1.84 | 1.29 | 0.70 |
| Example 40 | 40 | 760 | 4.24 | 0.59 | 1.90 | 1.25 | 0.66 |
| Example 41 | 41 | 785 | 4.19 | 0.59 | 1.94 | 1.38 | 0.71 |
| Example 42 | 42 | 818 | 4.23 | 0.59 | 2.04 | 1.77 | 0.87 |
| Example 43 | 43 | 820 | 4.20 | 0.59 | 2.03 | 1.79 | 0.88 |
| Example 44 | 44 | 805 | 4.00 | 0.51 | 1.64 | 1.14 | 0.69 |
| Example 45 | 45 | 820 | 4.35 | 0.60 | 2.14 | 1.80 | 0.84 |
| Example 46 | 46 | 813 | 3.98 | 0.52 | 1.68 | 1.1 | 0.65 |
| Comparative | Comparative 1 | 668 | 5.05 | 0.48 | 1.62 | 0.58 | 0.36 |
| example 1 | | | | | | | |
| Comparative | Comparative 2 | 673 | 5.73 | 0.43 | 1.66 | 0.58 | 0.35 |
| example 2 | | | | | | | |
| Comparative | Comparative 3 | 660 | 5.50 | 0.44 | 1.60 | 0.50 | 0.31 |
| example 3 | | | | | | | |
| Comparative | Comparative 4 | 655 | 5.57 | 0.43 | 1.57 | 0.57 | 0.36 |
| example 4 | | | | | | | |
| Comparative | Comparative 5 | 662 | 5.79 | 0.42 | 1.61 | 0.55 | 0.34 |
| example 5 | | | | | | | |
| Comparative | Comparative 6 | 654 | 5.51 | 0.43 | 1.55 | 0.51 | 0.33 |
| example 6 | | | | | | | |
| Comparative | Comparative 7 | 684 | 5.29 | 0.45 | 1.63 | 0.55 | 0.38 |
| example 7 | | | | | | | |
| Comparative | Comparative 8 | 806 | 4.16 | 0.59 | 1.98 | 0.77 | 0.36 |
| example 8 | | | | | | | |
| Comparative | Comparative 9 | 803 | 4.16 | 0.59 | 1.97 | 0.81 | 0.41 |
| example 9 | | | | | | | |
| Comparative | Comparative | 802 | 4.12 | 0.59 | 1.95 | 0.68 | 0.35 |
| example 10 | 10 | | | | | | |
| Comparative | Comparative | 794 | 4.01 | 0.57 | 1.81 | 0.77 | 0.42 |
| example 11 | 11 | | | | | | |

As shown, in Table 3 and Table 4, in Examples 1 to 43 with evaluation of the “Photoelectric conversion elements 1 to 46” which employed the conductive polymer represented by Formula (1) for the hole transport material and employed the compound represented by Formula (2) and any one of the compounds represented by Formulas (4) to (9) for the sensitizing dye, any one Example exhibits a photoelectric conversion efficiency ratio before and after the heat treatment being 0.60 or more. That is, it turns out that the photoelectric conversion efficiency can be maintained stably. In contrast, in “Comparative examples 1 to 11” which did not have the constitution of the present invention, the photoelectric conversion efficiency decreased after the heat treatment, and it turned out that the photoelectric conversion efficiency cannot be maintained stable.

What is claimed is:

1. A photoelectric conversion element, comprising:
a substrate, a first electrode, a photoelectric conversion layer including semiconductors and sensitizing dyes, a positive hole transport layer including a solid positive hole transport substance, and a second electrode,
wherein the solid positive hole transport substance contains a conductive polymer with a structure represented by the following Formula (1), and
wherein the sensitizing dyes includes a compound with a structure represented by the following Formula (2) and at least one of compounds with respective structures represented by the following Formulas (4) to (9), 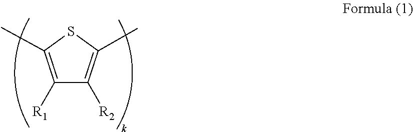
wherein each of R₁ and R₂ represents a hydrogen atom, or a substituted or unsubstituted alkyl group, alkoxy group, alkenyl group, or aryl group, R₁ and R₂ may be identical to each other, or may be different from each other, R₁ and R₂ may link to each other so as to form a ring structure, and k represents a natural number; 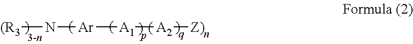
wherein n represents an integer of 1 or more and 3 or less, Ar represents an aromatic group, R₃ represents a hydrogen atom, a halogen atom, a substituted or unsubstituted alkyl group, alkoxy group, alkenyl group, alkynyl group, aryl group, amino group, cyano group, or heterocycle group, and when n is 1, two R₃s may be different from each other, and R₃ may link to other substituent group so as to form a ring structure,
wherein each of A₁ and A₂ is a single bond, divalent saturated, or unsaturated hydrocarbon group, or a substituted or unsubstituted alkylene group, allylene group or heterocycle group, each of p and q is an integer of 0 or more and 6 or less, and Z represents an organic group attaining at least one hydroxy group or acidic group, and
wherein when n is 2 or more, a plurality of A₁, A₂, and Z may be different from each other; 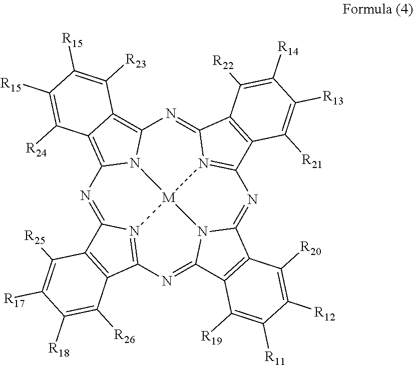
wherein each of R₁₁ to R₂₆ represents independently a hydrogen atom, a halogen atom, or a substituted or unsubstituted alkyl group, alkoxy group, aryl group, or phenoxy group, an acidic group is included in at least one position on R₁₁ to R₂₆, and M represents two hydrogen atoms or a divalent, trivalent, or tetravalent metal atom that may include a substituent group; 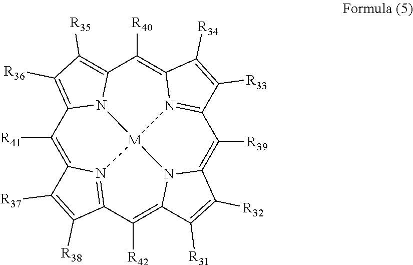
wherein each of R₃₁ to R₄₂ represents independently a hydrogen atom, a halogen atom, or a substituted or unsubstituted alkyl group, alkenyl group, alkynyl group, aryl group, amino group, heterocycle group, or group forming a ring-shaped structure or ring-fused structure directly or via other bonded atom, an acidic group is included in at least one position on R₃₁ to R₄₂, and M represents two hydrogen atoms or a divalent, trivalent, or tetravalent metal atom that may include a substituent group; 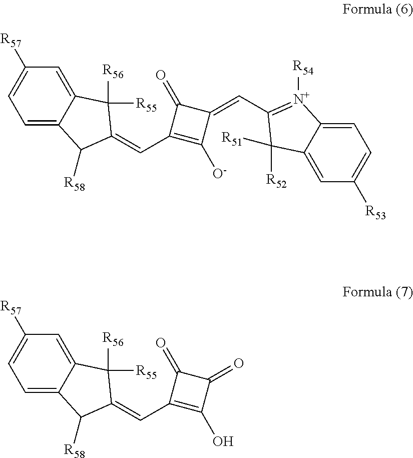
wherein each of R₅₃ and R₅₄ in Formula (6), or each of R₅₇ and R₅₈ in both Formulas (6) and (7) represents independently a hydrogen atom, a halogen atom, or a substituted or unsubstituted alkyl group, alkenyl group, alkynyl group, aryl group, or heterocycle group, and an acidic group is included in at least one position on the above section, and
wherein each of R₅₁ and R₅₂ in Formula (6), or each of R₅₅ and R₅₆ in both Formulas (6) and (7) represents an alkyl group with the same number of carbons or the different number of carbons, an aryl group, or an alkyl group-substituted aryl group; and 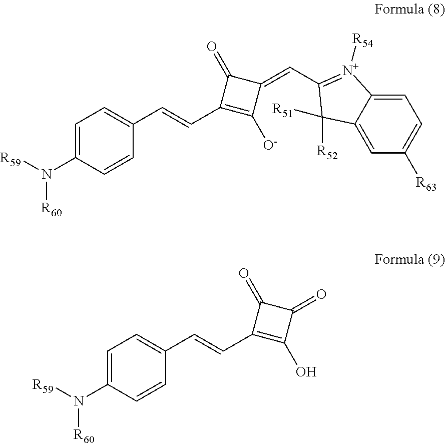
wherein Each of R₅₁, R₅₂, R₅₃, and R₅₄ in Formula (8) represents independently a hydrogen atom, a halogen atom, or a substituted or unsubstituted alkyl group, alkenyl group, alkynyl group, aryl group, or heterocycle group, and an acidic group is included on R₅₃, each of R₅₉ and R₆₀ in both Formulas (8) and (9) represents independently a substituted or unsubstituted alkyl group, alkenyl group, alkynyl group, aryl group, or heterocycle group, and R₅₉ and R₆₀ may link to each other so as to form a ring-shape structure.

2. The photoelectric conversion element described in claim 1, wherein the compound represented by Formula (2) is a compound represented by Formula (3), 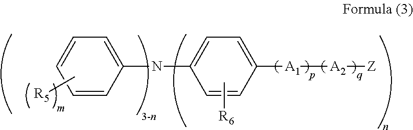
wherein m represents an integer of 1 or more and 5 or less, n represents an integer of 1 or 2, each of R₅ and R₆ represents a hydrogen atom, a halogen atom, a substituted or unsubstituted alkyl group, alkoxy group, alkenyl group, alkynyl group, aryl group, amino group, cyano group, or heterocycle group, and R₅ and R₆ may link to each other so as to form a ring structure, and
wherein each of A₁ and A₂ represents a heterocycle group containing a sulfur atom, each of p and q is an integer of 0 or more and 6 or less, Z represents an organic group containing at least one hydroxy group or acidic group, and when m is 2, A₁, A₂, and Z maybe different from each other.

3. The photoelectric conversion element described in claim 2, wherein in the compound represented by Formula (3), at least one of R₅, A₁, and A₂ includes a straight chain, alkyl structure with six or more carbon atoms.

4. The photoelectric conversion element described in claim 2, wherein in the compound represented by Formula (3), n is 2.

5. The photoelectric conversion element described, in claim 1, wherein the compound with the structure represented by Formula (2) and at least one of the compounds with the respective structures represented by Formulas (4) to (9) are included with a ratio of 1:10 to 10:1.

6. The photoelectric conversion element described in claim 1, wherein the sensitizing dyes are held in the photoelectric conversion in a total held-amount of 0.01 to 100 millimole/m².

7. The photoelectric conversion element, described in claim 1, wherein the conducive polymer with the structure represented by Formula (1) is a copolymer produced by at least too kinds of polymerizable monomers.

8. The photoelectric conversion element described in claim 1, wherein the photoelectric conversion layer including the sensitizing dye has a thickness of 10 μm or less.

9. The photoelectric conversion element described in claim 1, wherein the positive hole transport layer is a polymer layer formed by thermal polymerization of the conductive polymer with the structure represented by Formula (1).

10. The photoelectric conversion element described in claim 9, wherein a processing temperature in the thermal polymerization is 50° C. or more and 82° C. or less.

11. The photoelectric conversion element described in claim 1, further comprising:
a barrier layer disposed between the first electrode and the photoelectric conversion layer.
